(19) United States
(12) Patent Application Publication
(10) Pub. No.: US 2024/0127982 A1
(43) Pub. Date: Apr. 18, 2024

(54) INFORMATION PROCESSING APPARATUS AND CONTROL METHOD OF INFORMATION PROCESSING APPARATUS

(71) Applicants: NATIONAL INSTITUTE OF ADVANCED INDUSTRIAL SCIENCE AND TECHNOLOGY, Tokyo (JP); TOKYO UNIVERSITY OF SCIENCE FOUNDATION, Tokyo (JP); TOYOTA PHYSICAL AND CHEMICAL RESEARCH INSTITUTE, Nagakute-shi, Aichi (JP); NATIONAL UNIVERSITY CORPORATION TOTTORI UNIVERSITY, Tottori-shi, Tottori (JP); NAGASE & CO., LTD., Osaka-shi, Osaka (JP)

(72) Inventors: Hiroyuki AKINAGA, Tsukuba-shi (JP); Hisashi SHIMA, Tsukuba-shi (JP); Yasuhisa NAITOH, Tsukuba-shi (JP); Hiroshi SATOU, Tsukuba-shi (JP); Dan SATOU, Tsukuba-shi (JP); Takuma MATSUO, Tsukuba-shi (JP); Kentaro KINOSHITA, Tokyo (JP); Toshiyuki ITOH, Nagakute-shi (JP); Toshiki NOKAMI, Tottori-shi (JP); Masakazu KOBAYASHI, Tokyo (JP)

(73) Assignees: NATIONAL INSTITUTE OF ADVANCED INDUSTRIAL SCIENCE AND TECHNOLOGY, Tokyo (JP); TOKYO UNIVERSITY OF SCIENCE FOUNDATION, Tokyo (JP); TOYOTA PHYSICAL AND CHEMICAL RESEARCH INSTITUTE, Nagakute-shi, Aichi (JP); NATIONAL UNIVERSITY CORPORATION TOTTORI UNIVERSITY, Tottori-shi, Tottori (JP); NAGASE & CO., LTD., Osaka-shi, Osaka (JP)

(21) Appl. No.: 18/274,971

(22) PCT Filed: Jan. 27, 2022
(86) PCT No.: PCT/JP2022/003186

§ 371 Date: Jul. 28, 2023

(30) Foreign Application Priority Data
Jan. 29, 2021 (JP) 2021-013179
Aug. 25, 2021 (JP) 2021-137167

(51) Int. Cl. H01B 7/00

(52) U.S. Cl. CPC H01B 7/0027

(57) ABSTRACT

An information processing apparatus includes a converting portion having a plurality of electrical conductors to be arranged in mutual separation and a medium arranged so as to mutually connect the plurality of electrical conductors, wherein the converting portion is the information processing apparatus to convert an input signal to an output signal. The medium includes the electrolyte and is configured to be capable of controlling an electrical conductivity of an electrically conductive path mutually electrically connecting the plurality of electrical conductors, and the medium is selected such that the electrical conductivity of the electrically conductive path changes over time with the input signal not being present.

### TECHNICAL FIELD

The present disclosure relates to an information processing apparatus and a control method of an information processing apparatus.

### BACKGROUND ART

Techniques are being developed to apply an electric field to an electrolyte such as an ionic liquid to generate an electrically conductive path and disrupt the generated electrically conductive path (see Patent documents 1 to 2 and Non-patent documents 1 to 5, for example). Patent documents 1 to 2 and Non-patent documents 1 to 5 disclose memory devices and switching devices utilizing such characteristics of the electrically conductive path. In these memory devices and switching devices, the electrically conductive path is utilized with electrical characteristics such as electrical conductivity being maintained. This allows the electrically conductive path to perform memory functions and switching functions by utilizing the electrical characteristics of the electrically conductive path.

### PRIOR ART DOCUMENT

### Patent Document

Patent Document 1: JP 6195155 B
Patent Document 2: JP 6631986 B

### Non-Patent Document

Non-patent Document 1: Harada, A.; Yamaoka, H.; Ogata, R.; Watanabe, K.; Kinoshita, K.; Kishida, S.; Nokami, T.; Itoh, T. J. Mater. Chem. C, 2015, 3, 6966-6969.
Non-patent Document 2: Harada, A.; Yamaoka, H.; Watanabe, K.; Kinoshita, K.; Kishida, S.; Fukaya, Y.; Nokami, T.; Itoh, T. Chem. Lett., 2015, 44, 1578-1580.
Non-patent Document 3: Harada, A.; Yamaoka, H.; Tojo, S.; Watanabe, K.; Sakaguchi, A.; Kinoshita, K.; Kishida, S.; Fukaya, Y.; Matsumoto, K.; Hagiwara, R.; Sakaguchi, H.; Nokami, T.; Itoh, T. J. Mater. Chem. C, 2016, 4, 7215-7222.
Non-patent Document 4: Kinoshita, K.; Sakaguchi, A.; Harada, A.; Yamaoka, H.; Kishida, S.; Fukaya, Y.; Nokami, T.; Itoh, T. Jpn. J. Appl. Phys. 2017, 56, 04CE13.
Non-patent Document 5: Yamaoka, H.; Yamashita, T.; Harada, A.; Sakaguchi, A.; Kinoshita, K.; Kishida, S.; Hayase, S.; Nokami, T.; Itoh, T. Chem. Lett. 2017, 46, 1832-1835.

### SUMMARY OF THE INVENTION

### Problem to be Solved by the Invention

As described above, an electrically conductive path formed in an electrolyte has conventionally been utilized with electrical characteristics thereof being maintained, but the utilizability in the other utilization modes has not been clarified. It is believed that the electrical characteristics of the electrically conductive path be further clarified to find a new use for the electrically conductive path.

An object of the present disclosure is to provide an information processing apparatus and a control method of an information processing apparatus that utilize an electrical characteristic newly found in an electrically conductive path to be formed in an electrolyte.

### Means to Solve the Problem

An information processing apparatus according to one embodiment of the present disclosure includes a converting portion comprising a plurality of electrical conductors to be arranged in separation with each other and a medium to be arranged so as to mutually connect the plurality of electrical conductors, which converting portion is an information processing apparatus to convert an input signal to an output signal, wherein the medium contains an electrolyte that can form an electrically conductive path mutually electrically connecting the plurality of electrical conductors and is configured to be capable of controlling an electrical conductivity of the electrically conductive path based on the input signal, and the medium is selected such that the electrical conductivity of the electrically conductive path changes over time with the input signal not being present.

A control method of an information processing apparatus according to one embodiment of the present disclosure is a control method of an information processing apparatus including a converting portion comprising a plurality of electrical conductors to be arranged in separation with each other and a medium to be arranged so as to mutually connect the plurality of electrical conductors, in which information processing apparatus the converting portion is to convert an input signal to an output signal, wherein the medium contains an electrolyte that can form an electrically conductive path mutually electrically connecting the plurality of electrical conductors, the method including the step of controlling the admittance of the electrically conductive path by selecting the medium such that the admittance of the electrically conductive path is increased based on the input signal and the admittance of the electrically conductive path is decreased over time with the input signal not being present.

A control method of an information processing apparatus according to one embodiment of the present disclosure is a control method of an information processing apparatus including a converting portion comprising a plurality of electrical conductors to be arranged in separation with each other and a medium to be arranged so as to mutually connect the plurality of electrical conductors, in which information processing apparatus the converting portion is to convert an input signal to an output signal, wherein the medium contains an electrolyte that can form an electrically conductive path mutually electrically connecting the plurality of electrical conductors, the method including the step of controlling the impedance of the electrically conductive path by selecting the medium such that the impedance of the electrically conductive path is increased based on the input signal and the impedance of the electrically conductive path is decreased over time with the input signal not being present.

### Effects of the Invention

One embodiment of the present disclosure makes it possible to provide an information processing apparatus and a control method of an information processing apparatus that utilize an electrical characteristic newly found in an electrically conductive path to be formed in an electrolyte.

### BRIEF DESCRIPTION OF THE DRAWINGS

FIG. 1 is a block diagram conceptually showing an information processing apparatus according to a first embodiment of the present disclosure.

FIG. 2 is a plan view schematically showing the information processing apparatus according to the first embodiment of the present disclosure.

FIG. 3A is a plan photograph before applying a voltage, the plan photograph showing the information processing apparatus according to a first example of the present disclosure.

FIG. 3B is a plan photograph after applying a voltage, the plan photograph showing the information processing apparatus according to the first example of the present disclosure.

FIG. 3C is a plan photograph when a reverse voltage is applied after applying a voltage, the plan photograph showing the information processing apparatus according to the first example of the present disclosure.

FIG. 4A is a graph showing how dimensions of an electrically conductive path according to a second example of the present disclosure decrease over time.

FIG. 4B is a graph showing how dimensions of the electrically conductive path according to the second example of the present disclosure increase over time.

FIG. 5A is a graph showing how the electrical conductivity (admittance) of the electrically conductive path according to a third example of the present disclosure decreases over time.

FIG. 5B is a graph showing how the electrical conductivity (admittance) of the electrically conductive path according to the third example of the present disclosure decreases greater than the change over time of the electrically conductive path in FIG. 5A.

FIG. 6A is a flowchart showing one example of a control method of the information processing apparatus according to the first embodiment of the present disclosure.

FIG. 6B is a flowchart showing a first variation of the control method of the information processing apparatus according to the first embodiment of the present disclosure.

FIG. 6C is a flowchart showing a second variation of the control method of the information processing apparatus according to the first embodiment of the present disclosure.

FIG. 6D is a flowchart showing a third variation of the control method of the information processing apparatus according to the first embodiment of the present disclosure.

FIG. 7 is a perspective view schematically showing the information processing apparatus according to a second embodiment of the present disclosure.

FIG. 8 is a perspective view schematically showing the information processing apparatus according to a third embodiment of the present disclosure.

FIG. 9 is a perspective view schematically showing the information processing apparatus according to a fourth embodiment of the present disclosure.

FIG. 10 is a cross-sectional view schematically showing the information processing apparatus according to the fourth embodiment of the present disclosure.

FIG. 11 is a cross-sectional view schematically showing the information processing apparatus according to a first variation of the fourth embodiment of the present disclosure.

FIG. 12 is a cross-sectional view schematically showing the information processing apparatus according to a second variation of the fourth embodiment of the present disclosure.

FIG. 13 is a cross-sectional view schematically showing the information processing apparatus according to a third variation of the fourth embodiment of the present disclosure.

FIG. 14A is a photograph taken in plan view by an optical microscope of the information processing apparatus according to a fourth example of the present disclosure.

FIG. 14B is a magnified photograph taken in plan view by the optical microscope of a region A1 in FIG. 11A after inputting an input signal.

FIG. 15A is a graph showing the correlation between an input signal and an output signal using the information processing apparatus according to a fifth example of the present disclosure.

FIG. 15B is a graph showing the correlation between the input signal and the output signal using the information processing apparatus according to a sixth example of the present disclosure.

FIG. 15C is a graph showing the correlation between the input signal and the output signal using the information processing apparatus according to a seventh example of the present disclosure.

FIG. 16A is a graph showing the correlation between the input signal and the output signal using the information processing apparatus according to the fifth example of the present disclosure.

FIG. 16B is a graph showing the correlation between the input signal and the output signal using the information processing apparatus according to the sixth example of the present disclosure.

FIG. 16C is a graph showing the correlation between the input signal and the output signal using the information processing apparatus according to the seventh example of the present disclosure.

FIG. 17A is a graph schematically showing one example of the timing of the input signal and the output signal.

FIG. 17B is a graph schematically showing another example of the timing of the input signal and the output signal.

FIG. 18A is a graph showing the input signal using the information processing apparatus according to an eighth example of the present disclosure.

FIG. 18B is a graph showing the output signal and virtual nodes (first to twenty-first virtual nodes) using the information processing apparatus according to the eighth example of the present disclosure.

FIG. 19A is a graph showing the output signal in the first virtual node using the information processing apparatus according to the eighth example of the present disclosure.

FIG. 19B is a graph showing the output signal in the second virtual node using the information processing apparatus according to the eighth example of the present disclosure.

FIG. 19C is a graph showing the output signal in the twenty-first virtual node using the information processing apparatus according to the eighth example of the present disclosure.

FIG. 20A is a plan view schematically showing the information processing apparatus according to a fifth embodiment of the present disclosure.

FIG. 20B is a plan view schematically showing a variation of the information processing apparatus according to the fifth embodiment of the present disclosure.

FIG. 21 is a photograph by the optical microscope, the photograph showing in plan view a specific example of the information processing apparatus according to the fifth embodiment of the present disclosure.

FIG. 22 is a photograph by the optical microscope, the photograph showing in plan view the information processing apparatus according to ninth and tenth examples of the present disclosure.

FIG. 23 is a graph showing the correlation between the input signal and the output signal using the information processing apparatus according to the ninth and tenth examples of the present disclosure.

FIG. 24 is a schematic view showing a measurement apparatus used in measurement of the input signal and the output signal in eleventh to thirteenth examples of the present disclosure.

FIG. 25A is a graph showing the correlation between the input signal and the output signal in the eleventh example of the present disclosure.

FIG. 25B is a graph showing the correlation between the input signal and the output signal in the twelfth example of the present disclosure.

FIG. 25C is a graph showing the correlation between the input signal and the output signal in the thirteenth example of the present disclosure.

FIG. 26 is a graph showing a polarization characteristic of a working electrode in the eleventh to thirteenth examples of the present disclosure.

FIG. 27A is an SEM photograph showing deposition of silver (Ag) ions and copper (Cu) ions present in the medium.

FIG. 27B is an elemental mapping using Auger electron microscopy, the elemental mapping corresponding to the photograph in FIG. 26B.

FIG. 28 is a schematic view showing an overview of the information processing apparatus according to a fourteenth example of the present disclosure.

FIG. 29A is a graph showing an external input in the information processing apparatus according to the fourteenth example of the present disclosure.

FIG. 29B is a graph showing an input signal in the information processing apparatus according to the fourteenth embodiment of the present disclosure.

FIG. 29C is a graph showing an output signal in the information processing apparatus according to the fourteenth embodiment of the present disclosure.

FIG. 29D is a graph showing determined results of the information processing apparatus according to the fourteenth embodiment of the present disclosure.

FIG. 30 is a graph showing the correlation between the input signal and the output signal in the fourteenth example of the present disclosure.

FIG. 31 is a graph showing the virtual nodes (first to 100^{th} virtual nodes) in the fourteenth example of the present disclosure.

FIG. 32 is a graph showing, in a superimposed manner, the output signals from the virtual nodes (the first to 100^{th} virtual nodes) in the fourteenth example of the present disclosure.

FIG. 33A is a graph showing results of the output signal for each of the virtual nodes in the fourteenth example of the present disclosure.

FIG. 33B is a graph showing, for each of the virtual nodes, results of a short-term memory test for a time step one previous in the fourteenth example of the present disclosure.

FIG. 33C is a graph showing, for each of the virtual nodes, results of the short-term memory test for a time step two previous in the fourteenth example of the present disclosure.

FIG. 34A is a graph showing determined results of the information processing apparatus using the results of the short-term memory test for the time step two previous in the fourteenth example of the present disclosure.

FIG. 34B is a graph showing the determined results of the information processing apparatus using the results of the short-term memory test for the time step one previous in a variation of the fourteenth example of the present disclosure.

FIG. 34C is a graph showing the determined results of the information processing apparatus using the results of the short-term memory test for the time step one previous in a variation of the fourteenth example of the present disclosure.

FIG. 35 is a graph showing noise load data used in the fourteen example of the present disclosure.

FIG. 36 is a circuit diagram schematically showing the information processing apparatus according to a sixth embodiment of the present disclosure, wherein (a) is a schematic circuit diagram in a case that an asymmetric device is connected to the output side and (b) is a schematic circuit diagram in a case that an asymmetric device is connected to the output side.

FIG. 37 is a graph showing a current-voltage characteristic in fifteenth to seventeenth examples of the present disclosure, wherein (a) is a graph related to the fifteenth example, (b) is a graph related to the sixteenth example, and (c) is a graph related to the seventeenth example.

FIG. 38 is a graph showing an external input and an external output in the fifteenth to seventeenth examples of the present disclosure, wherein (a) is a graph related to the fifteenth example, (b) is a graph related to the sixteenth example, and (c) is a graph related to the seventeenth example.

FIG. 39 is a graph showing the correlation between the external input and the external output in the fifteenth to seventeenth examples of the present disclosure.

### EMBODIMENT FOR CARRYING OUT THE INVENTION

The present inventors have found that the electrical conductivity of an electrically conductive path that is generated or disrupts in an electrolyte such as an ionic liquid changes over time without carrying out any special control after control for generation or disruption under predetermined conditions. The present inventors have found that such a characteristic can be used to utilize the electrically conductive path in an information processing apparatus. Below, with reference to the attached drawings, such an information processing apparatus will be described as specific embodiments. Besides, the embodiments shown below are merely exemplary, so that the information processing apparatus of the present disclosure is not to be limited to the embodiments below. Besides, in the present specification, an expression “A shape” and expressions similar thereto refer to not only a complete A shape, but also to such a shape as one that visually suggests the A shape (a generally A shape), including a shape in which the corners of the A shape are chamfered.

[Information Processing Apparatus According to First Embodiment of the Present Disclosure]

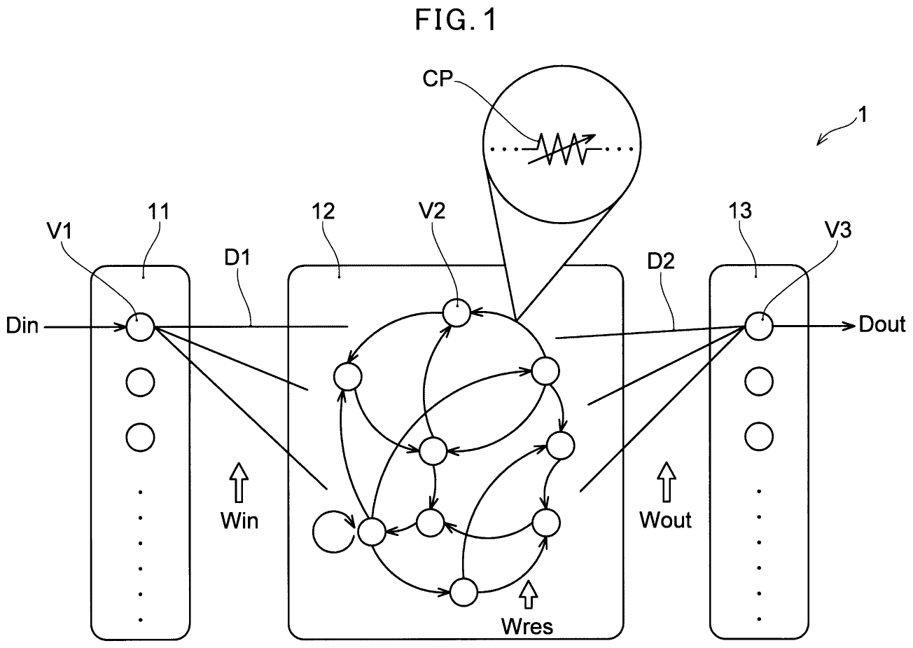

FIG. 1 conceptually shows an information processing apparatus 1 according to a first embodiment of the present disclosure. While the use of the information processing apparatus 1 is not particularly limited, in the present embodiment, as shown in FIG. 1, the information processing apparatus 1 functions as a neural network apparatus or a neuromorphic apparatus to mimick human brain nerve cells to process an input signal. More specifically, the information processing apparatus 1 functions as a reservoir computing apparatus to hold input signals in time series to carry out signal processing.

In the present embodiment, as shown in FIG. 1, the information processing apparatus 1 comprises an input portion 11 to transmit an input signal D1, a converting portion 12 to convert the input signal D1 to an output signal D2, and an output portion 13 to receive the output signal D2. Based on an external input Din, the input portion 11 generates the input signal D1 to be input to the converting portion 12, and transmits it to the converting portion 12. Specifically, the input portion 11 comprises one or a plurality of input nodes V1, and the one or the plurality of input nodes V1 is to transmit the input signal D1 to a converting node V2 of the converting portion 12, which converting node V2 is to be described below. For example, in a case that the input portion 11 comprises a sensor to sense a stimulus external to the information processing apparatus 1, the input portion 11 can use, as the input signal D1, a sensor output, or a conversion signal in which the sensor output is converted to a predetermined format. Moreover, in a case that the input portion 11 is connected to another electrical apparatus, the input portion 11 can use an output from the other electrical apparatus as the input signal D1 as it is, or can use, as the input signal D1, a converted signal in which the output from the other electrical apparatus is converted to a predetermined format. Furthermore, the input portion 11 can use, as an input signal, data that pseudo-changes over time (below, data that changes over time is also called “time-series data”), in which data a grayscale value (corresponding to the shade of color displayed by a pixel. Each of pixels can have an independent grayscale value such as R (red), G (green), B (blue), and the like) included in image data is made to correspond to a voltage. Besides, the input portion 11 can give a predetermined weight Win to the input signal D1.

The converting portion 12 generates the output signal D2 from the input signal D1 to be received from the input portion 11 and transmits it to the output portion 13. Specifically, the converting portion 12 comprises the converting node V2 in a plurality, and the input signal D1 from the input node V1 is input to a part or all of the plurality of converting nodes V2. For example, a weight Wres is given to a signal to be exchanged between the converting nodes V2 such that it changes over time, and this is transmitted to an output node V3 of the output portion 13 to be described below. In the present embodiment, as described below, the above-mentioned weight Wres is generated by a change in the electrical conductivity (a change in the admittance. The impedance, which is an inverse of the admittance, also similarly changes over time. In the present specification, an expression “a change in the electrical conductivity” and expressions similar thereto are to refer to both a change in the admittance and a change in the impedance.) over time of an electrically conductive path CP electrically connecting between the converting nodes V2. In this way, based on the input signal D1, the converting portion 12 can obtain the output signal D2 that changes over time. Besides, the change in the electrical conductivity can be a change in the real part of the admittance and/or the impedance, can be a change in the imaginary part of the admittance and/or the impedance, or can be a change in both the real and imaginary parts of the admittance and/or the impedance.

Based on the output signal D2 to be received from the converting portion 12, the output portion 13 generates an external output Dout that is an output of the information processing apparatus 1 with respect to the external input Din. Specifically, the output portion 13 comprises the output node V3 in one or a plurality, which output node V3 receives the output signal D2 from the converting node V2. For example, the output portion 13 has a multiplication/addition operation circuit, and gives a predetermined weight Wout to the output signal D2 to be received from the converting node V2 by the output node V3 to carry out a predetermined arithmetic operation such as a multiplication/addition operation to generate the external output Dout. The output portion 13 compares the external output Dout with a supervisory signal (not shown) and, based on the compared results, changes the weight Wout to be given to the output signal D2 using a linear regression method, for example. The output portion 13 determines the weight Wout using a minimum square method and the like. In this process, the information processing apparatus 1 learns on determination of the weight Wout. In this way, the information processing apparatus 1 can learn on data related to the external input Din.

In this way, in the present embodiment, learning by the information processing apparatus 1 is carried out only for determination of the weight Wout by the output portion 13. Therefore, power consumed in the process of learning is consumed by one portion of the information processing apparatus 1 (specifically, only the output portion 13 to determine primarily the weight Wout), making it possible to reduce consumed power of the information processing apparatus 1 as a whole.

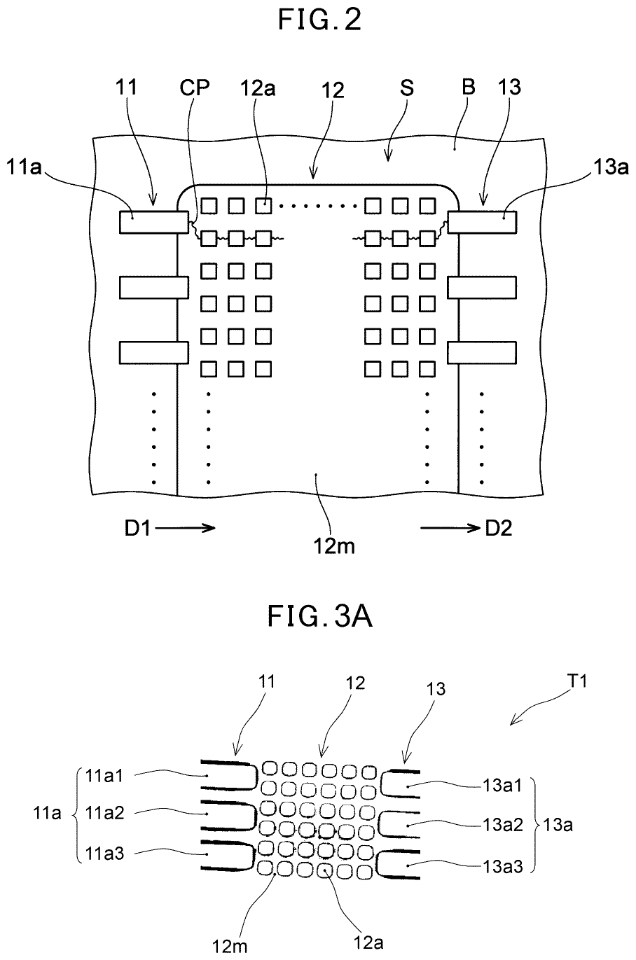

FIG. 2 schematically shows the configuration of the information processing apparatus 1 according to the present embodiment. In the present embodiment, the information processing apparatus 1 comprises a substrate B having a flat surface S, on which flat surface S of the substrate B at least a part of the information processing apparatus 1 is formed. The substrate B is not particularly limited as long as a surface thereof is insulating or semi-insulating. The substrate B can be composed of, for example, an insulating substrate such as ceramics, a semiconductor wafer such as a monocrystalline silicon (Si), a metal core substrate in which an insulating coating such as SiO₂ is applied on a surface of a conductive base material such as copper (Cu) and the like. The substrate B can be a relay substrate (an interposer) comprised by a known semiconductor package (for example, the relay substrate is composed of an LTCC (low temperature co-fired ceramics) and the like). In this case, the information processing apparatus 1 is provided as a semiconductor package, the converting portion 12 is, for example, arranged at the inner part of the semiconductor package (for example, a concave portion (a cavity) to be provided in the relay substrate), and at least parts of the input portion 11 and the output portion 13 (specifically, an input terminal 11a and an output terminal 13a to be described below) are, for example, composed of an external connecting terminal connecting the inner part and the outer part of the semiconductor package (specifically, a lead, a solder ball, and the like).

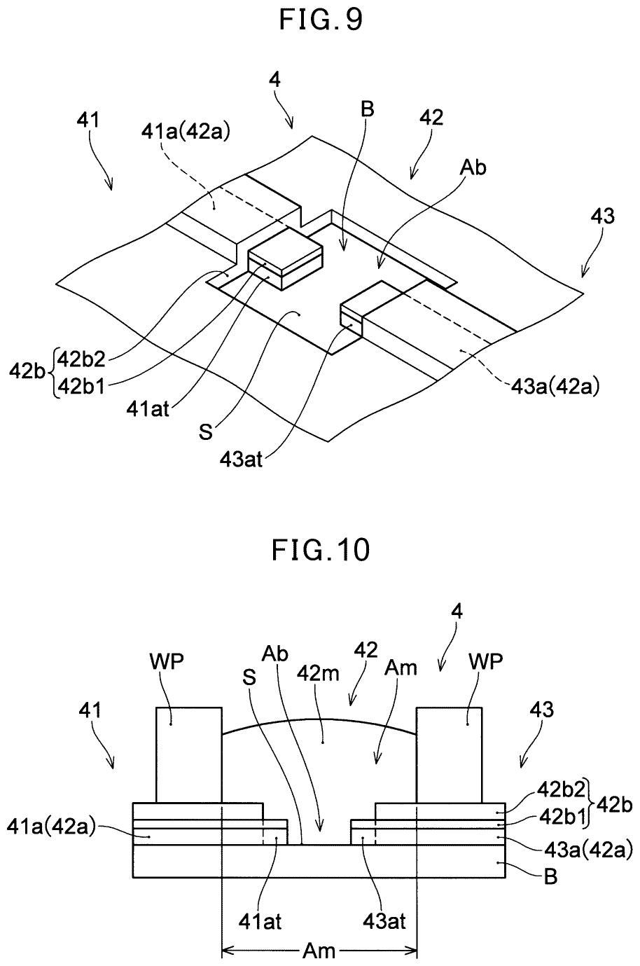

In the present embodiment, the input portion 11 comprises the input terminal 11a, separately from an electrical conductor 12a of the converting portion 12, as the above-described input node V1 (see FIG. 1). However, the input terminal 11a can be incorporated into the converting portion 12 as the electrical conductor 12a of the converting portion 12 (see FIGS. 9 and 10, for example). Moreover, as shown in a fourth embodiment to be described below, a part of the input terminal 11a (for example, at least substantially the entire surface of the input terminal 11a (top surface) opposite to the surface facing the substrate B) can be coated with an insulator (for example, the insulator is composed of silicon oxide (SiO₂)). While the arrangement of the input terminal 11a is not particularly limited, in FIG. 2, the input terminal 11a is arranged on one side of the converting portion 12 (one side of a rectangle in FIG. 2) so as to be separated from the electrical conductor 12a of the converting portion 12 to be described below on the surface S of the substrate B. More specifically, the input terminal 11a is arranged in a plurality so as to be along one side of the converting portion 12. However, there can be the one input terminal 11a, or the input terminal 11a can be arranged on a plurality of sides of the converting portion 12 (a plurality of sides of a rectangle in FIG. 2). While the constituting components and the layer configuration of the input terminal 11a are not particularly limited, in the present embodiment, the input terminal 11a is composed of the same components as those of the electrical conductor 12a of the converting portion 12 to be described below (specifically, platinum (Pt)), and has the same layer configuration as that of the electrical conductor 12a. In this case, the input terminal 11a can be formed at the same time as the electrical conductor 12a using a known semiconductor manufacturing process to carry out microfabrication by combining vapor deposition or sputtering with photolithography. However, the input terminal 11a can be composed of components different from those of the electrical conductor 12a, and can have a layer configuration different from that of the electrical conductor 12a. The input terminal 11a can be composed of an electrically conductive non-metallic material such as carbon (C).

The converting portion 12 comprises the electrical conductor 12a in a plurality, which plurality of electrical conductors 12a are to be arranged in separation with each other, and a medium 12m to be arranged so as to mutually connect the plurality of electrical conductors 12a. The medium 12m contains an electrolyte to generate the electrically conductive path CP electrically connecting between the electrically conductors 12a, and the medium 12m is to be the starting point of generation of the electrically conductive path CP. Besides, the electrically conductive path CP can also be generated between the electrical conductors 12a other than between the most proximate electrical conductors 12a.

The electrical conductor 12a functions as the above-described converting node V2 (see FIG. 1). While the arrangement of the electrical conductor 12a is not particularly limited, in FIG. 2, the electrical conductor 12a is arranged in a grid pattern on the surface S of the substrate B so as to be sandwiched between the input terminal 11a, and the output terminal 13a to be described below. However, the electrical conductor 12a can be arranged linearly, or can be arranged randomly, and not regularly, such as in a grid or linear pattern. Moreover, the electrical conductor 12a can include the input terminal 11a of the input portion 11 and the output terminal 13a of the output portion 13, or can be composed of only the input terminal 11a and the output terminal 13a (see FIGS. 9 and 10, for example). Furthermore, as shown in the fourth embodiment to be described below, a part of the electrical conductor 12a (for example, substantially the entire surface of the electrical conductor 12a (top surface) opposite to the surface facing the substrate B) can be coated with an insulator (for example, the insulator is composed of silicon oxide (SiO₂)). While the constituting components of the electrical conductor 12a are not particularly limited, in the present embodiment, a metal constituting the electrical conductor 12a is selected so as to have a higher electrode potential with respect to the medium 12m than that of a metal constituting ions contained in the medium 12m (so as to typically have a smaller ionization tendency). Specifically, the electrical conductor 12a is composed of a precious metal such as platinum (Pt), which has a higher electrode potential than that of the metal constituting the ions contained in the medium 12m, such as copper (Cu) or silver (Ag). The electrical conductor 12a can have a base layer composed of a precious metal such as platinum (Pt) and, on the surface of the base layer, an adhesion layer composed of a metal having a high electron supplying ability, such as tantalum (Ta), molybdenum (Mo), and the like. In this case, the dissolution and deposition reaction (the redox reaction) of the electrically conductive path CP is accelerated or delayed, making it possible to change the degree of change over time of the electrical conductivity of the electrically conductive path CP to be described below. However, the metal constituting the electrical conductor 12a can be selected to have a lower electrode potential with respect to the medium 12m than that of the metal constituting the ions contained in the medium 12m. Moreover, the electrical conductor 12a can be composed of the same metal as the metal constituting the ions contained in the medium 12m, or can be composed of an electrically conductive non-metallic material such as carbon (C), or an electrically conductive organic material.

The medium 12m contains an electrolyte that can form the electrically conductive path CP mutually electrically connecting the plurality of electrical conductors 12a. Here, the “electrolyte” in the present specification refers to a substance in which contained ions can be moved by a voltage applied. The electrolyte can be a colloid in which a dispersant is (colloidal particles are) dispersed in a dispersing medium, or a solution in which a solute is (ions are) dissolved in a solvent. In a case of the colloid, the dispersing medium can be a solid, but is suitably a liquid. The electrolyte is suitably a solution in which the ions are dissolved and more suitably an ionic liquid in which the ions are dissolved. The electrolyte can also be an ion gel in which ion pairs are contained in a polymer gel. Here, in the present specification, the “ionic liquid” is a concept including not only the so-called ionic liquid (salt being present in liquid state at room temperature) itself, but also solvate and mixed ionic liquids. Here, “solvation” refers to a state in which solvent molecules surround solute molecules or ions to form one molecular group in a solution. Moreover, “the solvate ionic liquid” refers to an ionic liquid having such solvation. Furthermore, “the mixed ionic liquid” refers to an ionic liquid in which a plurality of arbitrary ionic liquids, such as a plurality of ionic liquids and/or solvate ionic liquids, are mixed. The mixed ionic liquid has an advantage that the viscosity thereof can be adjusted by mixing, for example, a solvate ionic liquid and an ionic liquid having a smaller viscosity (viscosity coefficient) than that of the above-mentioned solvate ionic liquid (below called “a low-viscosity ionic liquid”).

The medium 12m is configured to be capable of controlling, based on the input signal D1, the admittance of the electrically conductive path CP. In other words, the medium 12m is configured to be capable of controlling, based on the input signal D1, the impedance of the electrically conductive path CP mutually electrically connecting the plurality of electrical conductors 12a. Specifically, the medium 12m is configured to be capable of controlling, in accordance with the input signal D1, the electrical conductivity (admittance/impedance) of the electrically conductive path CP by dissolving the electrically conducting path CP into the electrolyte or depositing the electrically conductive path CP from the electrolyte. Moreover, the medium 12m is selected, with no external stimuli with respect to the converting portion 12 being present, such that the electrical conductivity of the electrically conductive path CP changes over time. Specifically, the medium 12m is selected, with no input signal D1 being present, such that the electrical conductivity (admittance/impedance) of the electrically conductive path CP changes over time by the electrically conducting path CP naturally dissolving into the electrolyte or the electrically conductive path CP naturally depositing from the electrolyte. Below, a suitable example of an electrolyte of such a medium 12m will be described with the above-described ionic liquids as examples.

While the ionic liquid itself is not particularly limited, it is composed of 1-Butyl-3-methylimidazolium ([Bmim]) bis (trifluoromethyl) sulfonylamide ([TFSA]) and the like. While the mixed ionic liquid itself is not particularly limited, it is composed of 1-Butyl-3-methylimidazolium bis (trifluoromethyl) sulfonylamide ([Bmim] [TFSA]) and the like.

Besides, “TFSA” is also abbreviated as [Tf₂N], and is also often denoted, in reagent catalogs and documents, as “bis(trifluoromethylsulfonyl)imide” ([TFSI]). However, in the specification, [TFSA] will be used in accordance with the IUPAC nomenclature.

The solvent of the solvate ionic liquid is not particularly limited as long as it has such a characteristic as to surround solute molecules or ions. The solvent of the solvate ionic liquid is composed of, for example, at least one type of solvent and the like to be selected from the group consisting of:

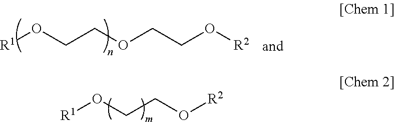

(where n is the number of ethyleneoxy groups being 1 or 2; m is the number of methylene groups, which is an integer being any one of 1 to 3; each of R₁, R₂ can be the same or different; R₁ denotes an alkyl group whose number of carbons is between 1 and 6, an alkenyl group whose number of carbons is between 2 and 6, an alkylnyl group whose number of carbons is between 2 and 6, a trimethysilyl group, a triethysilyl group, or a t-butyldimethylsilyl group; R₂ denotes an alkyl group whose number of carbons is between 1 and 16, an alkenyl group whose number of carbons is between 2 and 6, an alkylnyl group whose number of carbons is between 2 and 6, a trimethysilyl group, a triethysilyl group, or a t-butyldimethylsilyl group; and the alkenyl group can contain therein an ether functional group, a thioether functional group). The solvent of the solvate ionic liquid is not limited to one type, so that a plurality of species of solvents can be mixed.

While cations to be dissolved in an ionic liquid are not particularly limited, in the present embodiment, they are composed of copper (Cu) ions or silver (Ag) ions. However, the cations to be dissolved in the ionic liquid are not particularly limited, so that they can be composed of, for example, precious metal ions such as gold (Au) ions, palladium (Pd) ions, rhodium (Rh) ions, ruthenium (Ru) ions, platinum (Pt) ions, metal ions such as cobalt (Co) ions, nickel (Ni) ions, and lanthanoid metal ions such as Europium (Eu) ions. The cations to be dissolved in the ionic liquid are not limited to one type, so that a plurality of species of metal ions can be dissolved in the ionic liquid.

Anions to be dissolved in the ionic liquid are not particularly limited as long as they become liquid when they are solvated. The anions to be dissolved in the ionic liquid are composed of, for example, bis(trifluoromethyisulfonyl) amide (N(SO₂CF₃)₂⁻:TFSA), bis(fluorosulfonyl)amide (N(SO₂F)₂⁻:FSA). However, the anions are not limited to the above-described anions, so that they can be composed of AlCl₄⁻, BF₄⁻, PF₆⁻, SbF₆⁻, MeSO₃⁻, CF₃SO₃⁻, NO₃⁻, CF₃COO⁻, RCOO⁻, RSO₄⁻, RCH(NH₂)COO⁻, SO₄²⁻, ClO₄⁻, (HF)_{2,3}F⁻, (Here, R denotes H, an alkyl group, or an alkyloxy group). The anions to be dissolved in the ionic liquid are not limited to one type, so that a plurality of species of anions can be dissolved in the ionic liquid.

The low-viscosity ionic liquid is not particularly limited as long as it has a smaller viscosity (viscosity coefficient) than that of the solvate ionic liquid. The low-viscosity ionic liquid is composed of, for example, at least one species to be selected from the group consisting of:

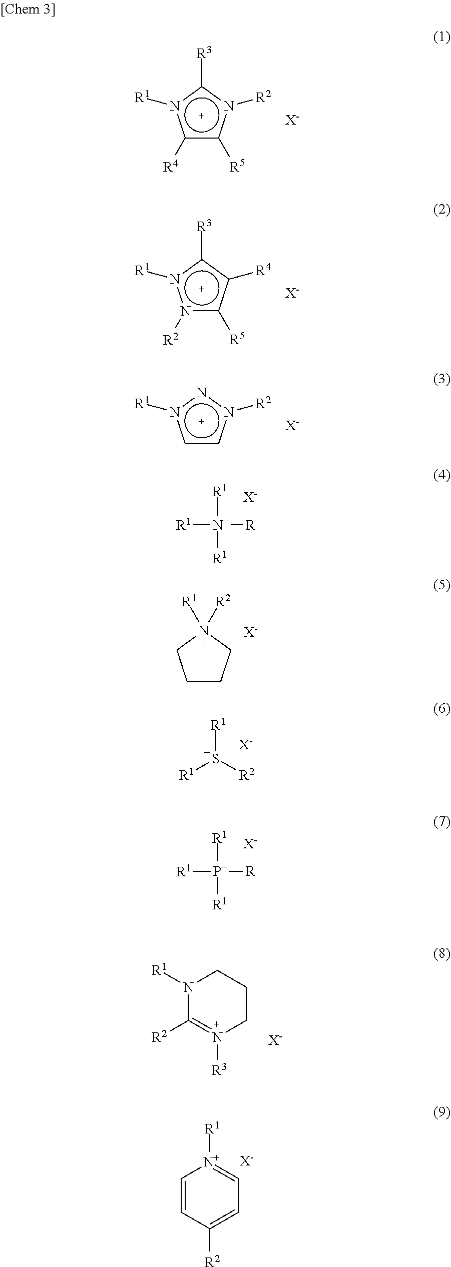

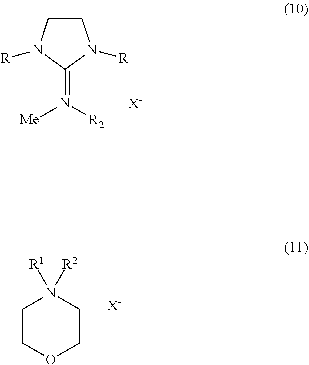

(where, or denoting an alkyl group whose number of carbons is between 1 and 6, R¹ can be the same or different in the above-mentioned respective chemical formulas, and denotes an alkyl group whose number of carbons is between 1 and 6, or an alkenyl group whose number of carbons is between 2 and 6; R² can be the same or different in the above-mentioned respective chemical formulas, and denotes a hydrogen atom, an alkyl group whose number of carbons is between 1 and 16, an alkenyl group whose number of carbons is between 2 and 6, or an alkoxy group. The alkyl group can contain therein an ether functional group, a thioether functional group. R³ can be the same or different in the above-mentioned respective chemical formulas, and denotes a hydrogen atom, a phenyl group, a methyl group, or an isopropyl group. R⁴ or R⁵ can be the same or different in the above-mentioned respective chemical formulas, and denotes a hydrogen atom, a phenyl group, a methyl group, or an isopropyl group. n in chemical formula (5) denotes the number of methylene units, where n=1 or 2. In chemical formula (8), R¹ and R² can have carbon chains connected mutually, in which case they denote a trimethylene group, a tetramethylene group, a pentamethylene group, a hexamethylene group, or a heptamethylene group. In chemical formula (9), R² can contain heteroatoms such as, for example, an alkyl group such as a methyl group and an ethyl group, and a dimethylamino group. Anions (X) in the ionic liquid denote AlCl₄⁻, BF₄⁻, PF₆⁻, SbF₆⁻, N(SO₂CF₃)₂⁻, N(SO₂F)₂⁻, N(CN)₂⁻, MeSO₃⁻, MeSO₄⁻, CF₃SO₃⁻, NO₃⁻, CF₃COO⁻, RCOO⁻, RSO₄⁻, RCH(NH₂)COO⁻, SO₄²⁻, ClO₄⁻, Me₂PO₄⁻, (HF)_{2,3}F⁻ (Here, R denotes H, an alkyl group, or an alkyloxy group.) The low-viscosity ionic liquid can be composed of one type of low-viscosity ionic liquid, or can be composed of a plurality of types of low-viscosity ionic liquids.

While cations and anions to be dissolved in the low-viscosity ionic liquid are not particularly limited, they can contain, for example, other than the above-mentioned cations and anions and anions, a dicationic ionic liquid as in chemical formula (12) and chemical formula (13), which are exemplified in [Chem 4], and, then, in a case of imidazolium salt shown in chemical formula (12), it can be a symmetrical salt in which R¹ and R³ are coincident, or an asymmetrical salt in which R¹ and R³ are different. R² in —CH₂—R²—CH₂— linking the two cations can be 0, or, in other words, an ethylene chain. Moreover, one or more ether oxygen can be contained in R². In the quaternary ammonium salts shown in chemical formula (14), all of R¹ to R⁹ can be compounds of the same symmetry or those of several different asymmetries, R⁶ in —CH₂—R⁶—CH₂— linking the two cations can be 0, or, in other words, an ethylene chain, and one or more ether oxygen can be contained in R⁶. Anions (X) of an ionic liquid are composed of at least one species to be selected from the group consisting of; AlCl₄⁻, BF₄⁻, PF₆⁻, SbF₆⁻, N(SO₂CF₃)₂⁻, N(SO₂F)₂⁻, N(CN)₂⁻, MeSO₃⁻, MeSO₄⁻, CF₃SO₃⁻, NO₃⁻, CF₃COO⁻, RCOO⁻, RSO₄⁻, RCH(NH₂)COO⁻, SO₄²⁻, ClO₄⁻, Me₂PO₄⁻, (HF)_{2,3}F⁻. (Here, R denotes H, an alkyl group, or an alkyloxy group). The following may be in contained.

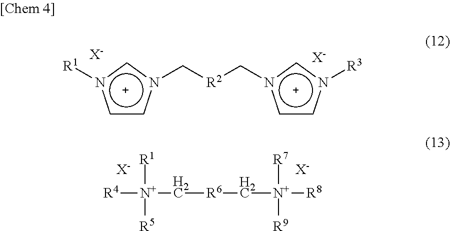

Moreover, each of the cations and anions to be dissolved in the low-viscosity ionic liquid can contain at least one of cations and anions exemplified in [Chem 5].

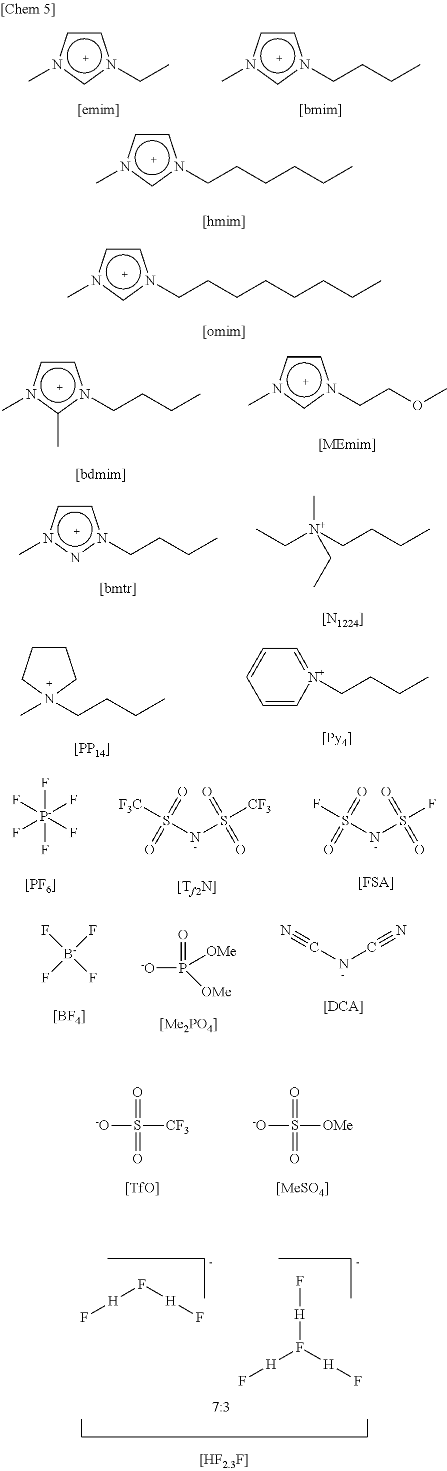

Each of the cations and anions to be dissolved in the low-viscosity ionic liquid can contain one type of the above-described ions or can contain a plurality of types thereof.

While cations to be dissolved in a mixed ionic liquid are not particularly limited, in the present embodiment, they are composed of copper (Cu) ions or silver (Ag) ions. However, the cations to be dissolved in the ionic liquid are not particularly limited, so that they can be composed of, for example, precious metal ions such as gold (Au) ions, palladium (Pd) ions, rhodium (Rh) ions, ruthenium (Ru) ions, platinum (Pt) ions, metal ions such as cobalt (Co) ions, nickel (Ni) ions, and lanthanoid metal ions such as Europium (Eu) ions. The cations to be dissolved in the ionic liquid are not limited to one type, so that a plurality of species of metal ions can be dissolved in the ionic liquid.

While anions to be dissolved in the mixed ionic liquid are not particularly limited, they are composed of, for example, bis(trifluoromethylsulfonyl) amide (N(SO₂CF₃)₂⁻:TFSA), bis(fluorosulfonyl)amide (N(SO₂F)₂⁻:FSA). However, the anions to be dissolved in the mixed ionic liquid can be composed of anion species that become liquid when they are solvated with metal ions, so that they can be composed of AlCl₄⁻, BF₄⁻, PF₆⁻, SbF₆⁻, MeSO₃⁻, CF₃SO₃⁻, NO₃⁻, CF₃COO⁻, RCOO⁻, RSO₄⁻, RCH(NH₂)COO⁻, SO₄²⁻, ClO₄⁻, (HF)_{2,3}F⁻. (Here, R denotes H, an alkyl group, or an alkyloxy group). The anions to be dissolved in the mixed ionic liquid are not limited to one type, so that a plurality of species of anions can be dissolved in the mixed ionic liquid.

The degree of change over time of the electrical conductivity of the electrically conductive path CP can be changed appropriately in accordance with a response characteristic required for the information processing apparatus 1. For example, the degree of change over time of the electrical conductivity can be adjusted in accordance with the selection of the medium 12m (specifically, the type of ionic liquid, the type of ions (cations and anions) contained in the ionic liquid, and the ion concentration). Moreover, the degree of change over time of the electrical conductivity of the electrically conductive path CP can also be adjusted in accordance with the constituting components and the layer configuration of the electric conductor 12a. Adjusting the change over time of the electrical conductivity of the electrically conductive path CP is to be described below.

In a case that the admittance of the electrically conductive path CP decreases over time by changing the degree of change over time of the electrical conductivity of the electrically conductive path CP as described above, it is preferable to set, for example, an 80% attenuation time of the admittance of the electrically conductive path CP to be within a range of 10⁻⁶ sec to 10⁷ sec in the initial period of attenuation. Here, in the present specification, the “80% attenuation time” refers to the time required for a certain physical amount to reach an 80% value from a value when attenuation is started, while the “initial period of attenuation” refers to the time within a predetermined time range from a point in time at which a certain physical amount starts attenuation. Moreover, in the present specification, in a case that a complex admittance Y is denoted as Y=G+jB (G: conductance, B: susceptance), “the 80% attenuation time of admittance” refers to the time required for a magnitude √(G²+B²) of the complex admittance to reach an 80% value from a value when attenuation is started. This allows a good consistency between the speed of change over time of the electrical conductivity and the processing speed of an electronic device such as a silicon (Si)-based one, making it suitable to use the information processing apparatus 1 in conjunction with an existing electronic device. The change over time of the electrical conductivity being faster than the above makes it difficult to complete an arithmetic operation of the electronic device, and the like before the change over time is completed. Moreover, the change over time of the electrical conductivity being too slow makes it difficult for the change of the electrical conductivity during processing of the electronic device to be manifested. Therefore, the 80% attenuation time of admittance of the electrically conductive path CP is more preferably set to be within a range of 10⁻⁶ sec to 1 sec in the initial period of attenuation, and is further preferably set to be within a range of 10⁻⁶ sec to 1 sec in the initial period of attenuation. Similarly, in a case that the impedance of the electrically conductive path CP decreases over time, the 80% attenuation time of impedance of the electrically conductive path CP is preferably set to be within a range of 10⁻⁶ sec to 10⁷ sec in the initial period of attenuation. Here, in the specification, in a case that a complex impedance Z is denoted as Z=R+jX (R: resistance, X: reactance), “the 80% attenuation time of impedance” refers to the time required for a magnitude √(R²+X²) of the complex impedance to reach an 80% value from a value when attenuation is started. The 80% attenuation time of impedance of the electrically conductive path CP is more preferably set to be within a range of 10⁻⁶ sec to 1 sec in the initial period of attenuation, and is further preferably set to be within a range of 10⁻⁶ sec to 10⁻³ sec in the initial period of attenuation.

In the present embodiment, the output portion 13 comprises the output terminal 13a, separately from the electrical conductor 12a of the converting portion 12, as the above-described output node V3 (see FIG. 1). However, the output terminal 13a can be incorporated into the converting portion 12 as the electrical conductor 12a of the converting portion 12 (see FIGS. 9 and 10, for example). Moreover, as shown in the fourth embodiment to be described below, a part of the output terminal 13a (for example, at least substantially the entire surface of the output terminal 13a (top surface) opposite to the surface facing the substrate B) can be coated with an insulator (for example, the insulator is composed of silicon oxide (SiO₂)). While the arrangement of the output terminal 13a is not particularly limited, in FIG. 2, the output terminal 13a is arranged on the other side of the converting portion 12 (the other side of a rectangle on the side opposite to the input terminal 11a in FIG. 2) so as to be separated from the electrical conductor 12a on the surface S of the substrate B. More specifically, the output terminal 13a is arranged in a plurality so as to be along the other side of the converting portion 12. There can be the one output terminal 13a, or the output terminal 13a can be arranged on a plurality of sides with respect to the converting portion 12 (a plurality of sides of a rectangle in FIG. 2). While the constituting components and the layer configuration of the output terminal 13a are not particularly limited, in the present embodiment, the output terminal 13a is composed of the same components as those of the electrical conductor 12a (specifically, platinum (Pt)), and has the same layer configuration as that of the electrical conductor 12a. In this case, the output terminal 13a can be formed at the same time as the electrical conductor 12a using a known semiconductor manufacturing process to carry out microfabrication by combining vapor deposition or sputtering with photolithography. However, the output terminal 13a can be composed of components different from those of the electrical conductor 12a, and can have a layer configuration different from that of the electrical conductor 12a of the converting portion 12. The output terminal 13a can be composed of an electrically conductive non-metallic material such as carbon (C). Moreover, in a case that a part of any of the input terminal 11a, the electrical conductor 12a, and the output terminal 13a is to be covered with insulators, by forming all of the insulators with the same component (for example, silicon oxide (SiO₂)), these insulators can be formed at the same time using a known semiconductor manufacturing process. However, only a part of any of the input terminal 11a, the electrical conductor 12a, and the output terminal 13a can be covered with insulators. Moreover, the insulators to cover the input terminal 11a, the electrical conductor 12a, and the output terminal 13a can be composed of mutually different components or layer configurations.

### First Example

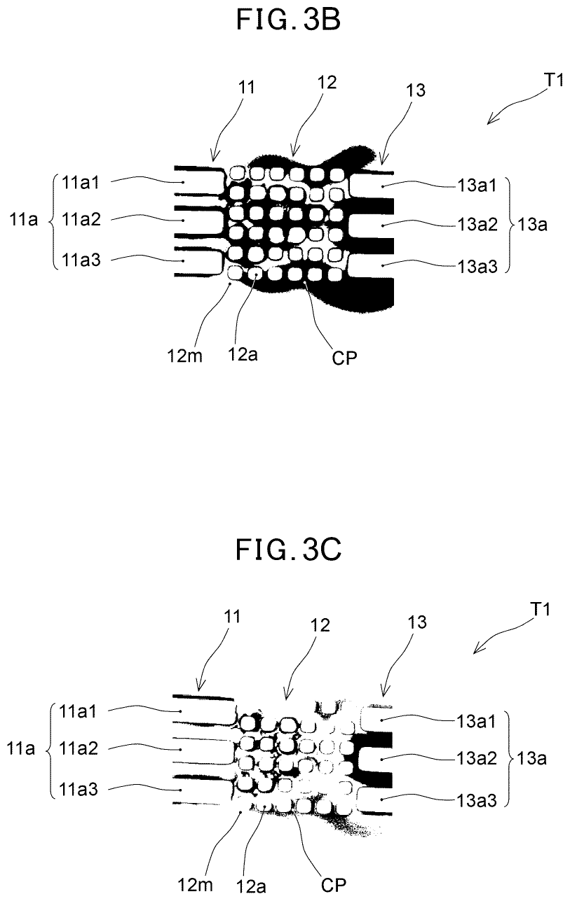

The present inventors have prepared a sample T1 shown in FIG. 3A to confirm whether generation and disruption of the electrically conductive path CP can be controlled in a specific example of the present embodiment as described above. Here, an SiO₂/Si substrate was adopted as the substrate B, in which SiO₂/Si substrate silicon oxide (SiO₂) was formed on the surface of a monocrystalline silicon (Si). A thin film of platinum (Pt) was formed on the surface S of this substrate B as the input terminal 11a of the input portion 11, the electrical conductor 12a of the converting portion 12, and the output terminal 13a of the output portion 13, and the medium 12m of the converting portion 12 was dropped thereon. A platinum (Pt) pattern in a grid of 6 rows and 6 columns was arranged as the electrical conductor 12a (L/S=2 μm), platinum (Pt) patterns 11a1 to 11a3 in columns were arranged as the input terminal 11a so as to line up on one side of the converting portion 12 (A line width of the input terminal 11a was 4 μm), and platinum (Pt) patterns 13a1 to 13a3 in columns were arranged as the output terminal 13a so as to line up on the other side of the converting portion 12 opposing the input terminal 11a. (A line width of the output terminal 13a was 4 μm. An interval between the input terminal 11a and the output terminal 13a was 26 μm.) As the medium 12m, a solvate ionic liquid was selected, which solvate ionic liquid was adjusted so that Cu (II) (TFSA)₂: triglyme (G3)=1:1. When, for the above-described sample T1, a voltage of 0V (GND) was applied to the input terminal 11a2, and no voltage was applied to the input terminals 11a1 and 11a3 (the input terminals 11a1 and 11a3 were left floating) with a voltage of +5V being applied to the output terminal 13a2 and no voltage being applied to the output terminals 13a1, 13a3 (the output terminals 13a1, 13a3 were left floating; corresponding to the input signal D1 of “010”, for example), as shown in FIG. 3B, generation of the electrically conductive path CP was observed between the electrical conductors 12a (similarly also between the input terminal 11a1 to 11a3 and the electrical conductor 12a, and between the electrical conductor 12a and the output terminal 13a1 to 13a3). Thereafter, when a voltage of 0V (GND) was applied to the input terminal 11a2, and no voltage was applied to the input terminals 11a1, 11a3 (the input terminals 11a1, 11a3 were left floating) with a voltage of −5V being applied to the output terminal 13a2, and no voltage being applied to the output terminals 13a1 and 13a3 (the output terminals 13a1 and 13a3 were left floating), as shown in FIG. 3C, disruption of the electrically conductive path CP was observed between the electrical conductors 12a (similarly also between the input terminal 11a1 to 11a3 and the electrical conductor 12a, and between the electrical conductor 12a and the output terminal 13a1 to 13a3). In this way, it was confirmed that the conversion portion 12 in the sample T1 could be controlled, in accordance with the input signal D1, such that the electrically conductive path CP is generated and the generated electrically conductive path CP disrupts. Besides, the present inventors confirm that, when an electrically conductive path generated using a medium having the same components as the constituting components of the above-described medium 12m and an electrical conductor having the same components as the constituting components of the above-described electrical conductor 12a are left with no voltage being applied thereto, it completely disrupts.

### Second Example

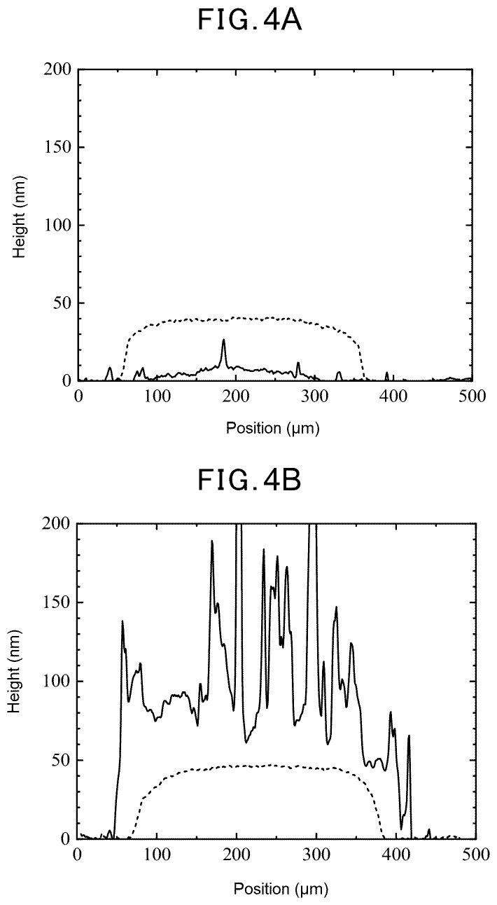

To confirm whether the electrical conductivity (admittance/impedance) of the electrically conductive path CP changes over time, the present inventors formed, by sputtering, on the surface S of the substrate B composed of an SiO₂/Si substrate, the electrically conductive path CP composed of a thin film of Cu and prepared a sample T2 in which was dropped the medium 12m composed of an ionic liquid in which Cu (II) (TFSA)₂ was dissolved in [Bmim][TFSA] at a concentration of 0.4 mol/L. Thereafter, the sample T2 was left in the atmosphere for 60 minutes to check change over time of the electrically conductive path CP (see FIG. 4A). As shown in FIG. 4A, it is seen that, being left for 60 minutes, the electrically conductive path CP dissolves in the medium 12m, and the thickness thereof decreases from approximately 40 nm (see dashed line) to less than or equal to 10 nm (see solid line). Moreover, the present inventors formed, by sputtering, on the surface S of the substrate B composed of an SiO₂/Si substrate, the electrically conductive path CP composed of a thin film of Cu and prepared a sample T3 in which was dropped the medium 12m composed of an ionic liquid in which Ag (TFSA) was dissolved in [Bmim][TFSA] at a concentration of 0.4 mol/L. Thereafter, the sample T3 was left in the atmosphere for 60 minutes to check change over time of the electrically conductive path CP (see FIG. 4B). As shown in FIG. 4B, it is seen that, being left for 60 minutes, the electrically conductive path CP deposits from the medium 12m, and the thickness thereof increases from approximately nm (see dashed line) to more than or equal to 70 nm (see solid line). In this way, it was confirmed that the thickness of the electrically conductive path CP changed over time. The electrical conductivity (admittance/impedance) of the electrically conducting path CP is also expected to change due to the above-mentioned change in the thickness of electrically conductive path CP.

### Third Example

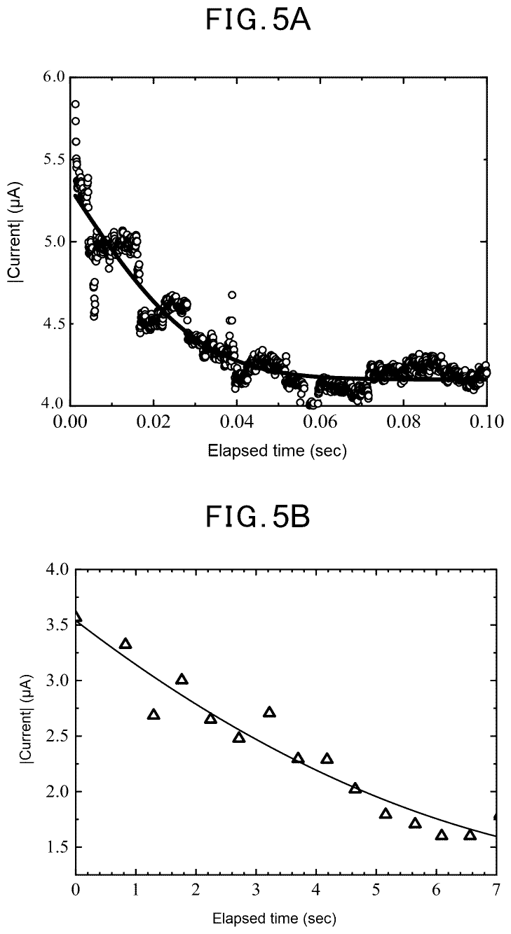

To confirm whether the degree of change over time of the electrical conductivity (admittance/impedance) of the electrically conductive path CP can be adjusted, the present inventors prepared a sample T4 (see FIG. 5A) in which was sandwiched between a copper (Cu) electrode and a platinum (Pt) electrode on a flat plate an ionic liquid in which Cu (I) (TFSA) prepared by electrolysis was dissolved in [Bmim] [TFSA] and a sample T5 (see FIG. 5B) in which was sandwiched between a copper (Cu) electrode and a platinum (Pt) electrode on a flat plate an ionic liquid in which Cu (II) (TFSA)₂ was dissolved in [Bmim] [TFSA] at a concentration of 0.4 mol/L. In the sample T4, as a set voltage to generate the electrically conductive path CP, a voltage of +0.6 V was applied between the electrodes for 1 msec and a voltage of −100 mV as a read signal (here, a read voltage) to measure the electrical conductivity of the electrically conductive path CP was applied between the electrodes for 100 msec. In the sample T5, as a set voltage, a voltage of +1.3 V was applied between the electrodes for 50 μsec and a voltage of −20 mV was applied between the electrodes for 100 msec as a read signal. As shown in FIGS. 5A and 5B, the 80% attenuation time of current is approximately 0.1 sec (approximately 0.1 sec after application of the set voltage) in the sample T4, while the 80% attenuation time of current is approximately 2 sec (approximately 2 sec after application of the set voltage) in the sample T5. In this way, it was confirmed that, in accordance with the type of ions (here, cations) of the medium 12m, the degree of change over time of the electrical conductivity of the electrically conductive path CP could be adjusted.

[Control Method of Information Processing Apparatus According to First Embodiment of the Present Disclosure]

Next, with reference to the attached drawings, a control method of the information processing apparatus 1 as described above will be described. Besides, the embodiments shown below are merely exemplary, so that the control method of the information processing apparatus of the present disclosure is not to be limited to the embodiments below.

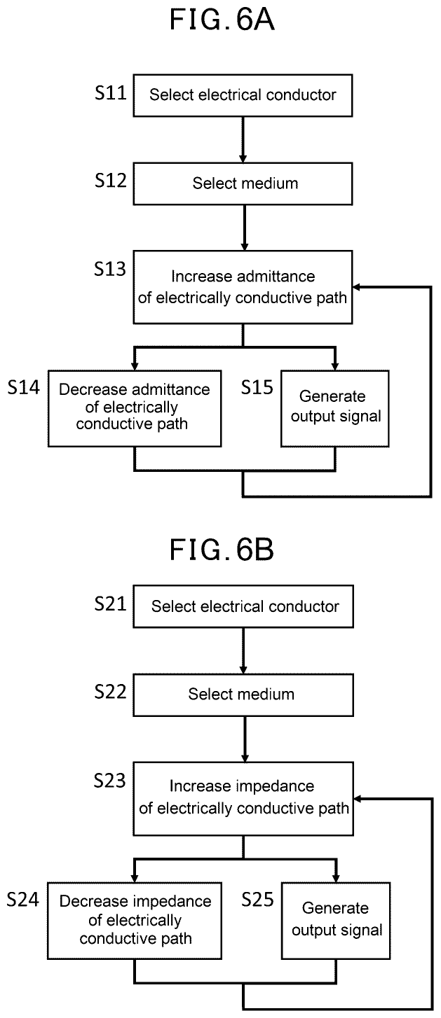

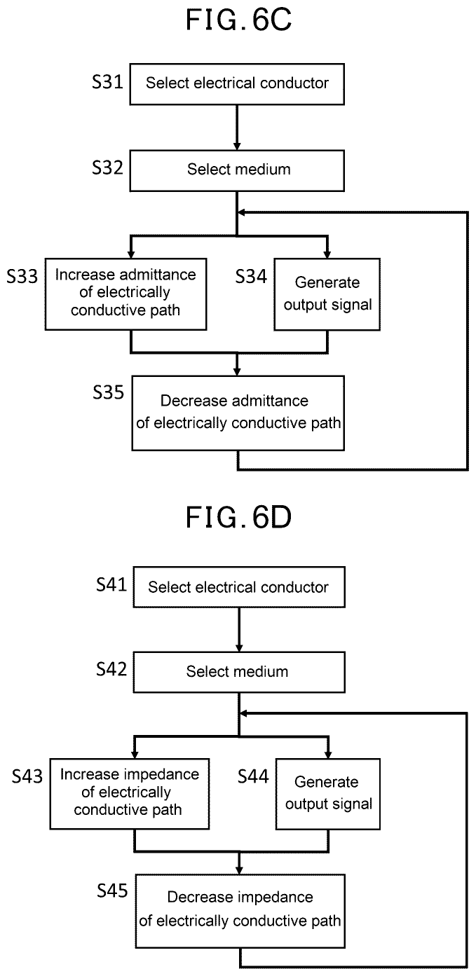

FIG. 6A is a flowchart showing one example of a control method of the information processing apparatus according to the first embodiment of the present disclosure. In the present embodiment, the admittance of the electrically conductive path CP is controlled by selecting the medium 12m so as to increase the admittance of the electrically conductive path CP based on the input signal D1 and to decrease over time the admittance of the electrically conductive path CP with the input signal D1 not being present. Specifically, the control method of the information processing apparatus according to the present embodiment includes step (see step S11 of FIG. 6A) of selecting the electrical conductor 12a (see FIG. 2), step (see step S12 of FIG. 6A) of selecting the medium 12m (see FIG. 2), step of increasing the admittance of the electrically conductive path CP (see step S13 of FIG. 6A), and step of decreasing the admittance of the electrically conductive path CP (see step S14 of FIG. 6A). These steps S11 to S14 are carried out to control the admittance (in other words, the impedance) of the electrically conductive path CP in the medium 12m. Besides, in the present embodiment, in parallel with step S14 of decreasing the admittance of the electrically conductive path CP, step of generating the output signal D2 in accordance with a decrease in the admittance of the electrically conductive path CP (see step S15 of FIG. 6A) is carried out to obtain the output signal D2 that changes over time. Below, with reference to FIGS. 2 and 6A, a control method of an information processing apparatus according to the present embodiment will be described.

(Step S11 of Selecting Electrical Conductor)

In step S11, specifically, constituting components of the electrical conductor 12a, and the like are selected. While constituting components of the electrical conductor 12a are not particularly limited, in the present embodiment, the electrical conductor 12a is selected such that it is composed of a metal having a higher electrode potential with respect to the medium 12m than that of a metal constituting the ions dissolved in the medium 12m to be selected in step S12. In this way, in step S14 to be described below, the electrical conductor 12a being dissolved in the medium 12m is suppressed. In the present embodiment, as such an electrical conductor 12a, platinum (Pt) is selected. In step S11, the layer configuration and the like of the electrical conductor 12a can further be selected. For example, in a case that a metal having a high electron supplying ability is contained in the electrical conductor 12a, the degree of change over time of the electrical conductivity can be changed in step S14. In this way, the degree of change over time of the electrical conductivity of the electrically conductive path CP can be adjusted by not only selecting the medium 12m in step S12, but also selecting the electrical conductor 12a in step S11.

(Step S12 of Selecting Medium)

In step S12, specifically, the medium 12m is selected from an ionic liquid, and, more specifically, at least one of the type of ionic liquid, the type of ions (cations and anions) contained in the ionic liquid, and the ion concentration. For example, in a case that an electrode potential of a metal constituting the cations is low, in step S14, the degree of change over time of the electrical conductivity of the electrically conductive path CP increases, whereas in a case that the electrode potential of the metal constituting the cations is high, in step S14, the degree of change over time of the electrical conductivity of the electrically conductive path CP decreases. Here, we compare a case in which Cu (copper) is dissolved as monovalent cations and a case in which it is dissolved as divalent cations in the medium 12m. In this case, the electrode potential of Cu relative to Cu (II) is lower than the electrode potential of Cu relative to Cu (I), so that the degree of change over time of the electrical conductivity is greater in a case that Cu (II) is dissolved in the medium 12m. In step S14, to decrease the admittance of the electrically conductive path CP over time with the input signal D1 not being present, for example, the medium 12m can be selected such the metal constituting ions (specifically, cations) dissolved in the medium 12m has a lower electrode potential relative to the medium 12m than a metal constituting the electrical conductor 12a. In the present embodiment, platinum (Pt) is selected as a constituting component of the electrical conductor 12a as described above, so that copper (Cu) ions (Cu (I) or CU (II)) or silver (Ag) ions are selected as ions to be dissolved in the medium 12m as such.

(Step S13 of Increasing Admittance of Electrically Conductive Path)

In step S13, specifically, the input signal D1 generated in the input portion 11 is input to the converting portion 12. At this time, depositing the electrically conductive path CP from the medium in accordance with the input signal D1 causes the electrically conductive path CP to be generated between the electrical conductors 12a, thereby increasing the admittance of the electrically conductive path CP. Generating of the electrically conductive path CP can be carried out without the electrically conductive path CP being present between the electrical conductors 12a or with the electrically conductive path CP being present between the electrical conductors 12a. Moreover, in a case that an existing electrically conductive path CP is present before carrying out step S13, the deposited components of the electrically conductive path CP can be the same as or different from the constituting components of the existing electrically conductive path CP. In the present embodiment, silver (Ag) or copper (Cu) dissolved as ions in the medium 12m is deposited between the electrical conductors 12a composed of platinum (Pt) (and on the surface of the electrical conductor 12a) and an electrically conductive path CP that did not exist is newly generated, or dimensions of the electrically conductive path increase to result in an increase in the admittance of the electrically conductive path CP. In step S13, the intensity of the input signal D1 (specifically, the voltage of the input signal D1) can be further adjusted. Specifically, the intensity of the input signal D1 is adjusted by amplifying or attenuating the input signal D1 in the input portion 11. For example, in a case that change over time of the input signal D1 is quick, the degree of change over time of the electrically conductive path CP can be increased, while in a case that change over time of the input signal D1 is slow, the degree of change over time of the electrically conductive path CP can be decreased.

(Step S14 of Decreasing Admittance of Electrically Conductive Path)

In step S14, specifically, dissolving the electrically conductive path CP in the medium causes the electrically conductive path CP to disrupt. In the present embodiment, the medium 12m is selected in step S12 such that the electrically conductive path CP dissolves in the medium 12m even with the input signal D1 not being present. In other words, in the present embodiment, the electrically conductive path CP naturally dissolves in the medium 12m even with no external stimuli being present with respect to the converting portion 12. The above-described steps S13 and S14 can be repeated to reversibly generate the electrically conductive path CP and cause the electrically conductive path CP to disrupt. Here, in step S14, as described above, with the input signal D1 not being present, the 80% attenuation time of admittance of the electrically conductive path CP is preferably set to be within a range of 10⁻⁶ sec to 10⁷ sec in the initial period of attenuation, is more preferably set to be within a range of 10⁻⁶ sec to 1 sec in the initial period of attenuation, and is further preferably set to be within a range of 10⁻⁶ sec to 10⁻³ sec in the initial period of attenuation. This allows a good consistency of the processing speed of an electronic device such as a silicon (Si)-based one, with respect to change over time of the electrical conductivity, making it suitable to use the information processing apparatus 1 in conjunction with an existing electronic device. As described above, the degree of decrease in the admittance of the electrically conductive path CP can be adjusted also by constituting components of the electrical conductor 12a, and the like, besides the medium 12m (specifically, the type of ionic liquid, and the type and concentration of ions dissolved in the ionic liquid).

(Step S15 of Generating Output Signal)

In step S15, specifically, to read the electrical conductivity (admittance/impedance) of the converting portion 12, a predetermined read signal (read voltage in the present embodiment) is applied to the converting portion 12 to cause the output signal D2 to be generated as a current that changes over time in accordance with change over time of the electrical conductivity of the electrically conductive path CP. The read signal is not particularly limited as long as it can read the electrical conductivity of the electrically conductive path CP, so that it can be a continuous signal of a constant intensity, can be a pulse signal, or can be a signal of the same polarity with respect to the input signal D1 or can be a signal of the reverse polarity with respect thereto. In the present embodiment, the read signal is a pulse signal composed of a pulse voltage having an absolute value considerably smaller than that of the input signal D1 (specifically, one to three orders of magnitude smaller in absolute value than that of the input signal). Therefore, the electrical conductivity of the electrically conductive path CP hardly changes with application of the read signal. Moreover, in the present embodiment, the read signal is a signal of the reverse polarity with respect to the input signal D1. Therefore, contrary to the electrically conductive path CP that is generated in step S13 and that disrupts in step S14 to be carried out in parallel with step S15, the electrically conductive path CP is not generated, but rather disrupts, so that the electrical conductivity of the electrically conductive path CP continues to change over time in step S15. Besides, in step S15, the absolute value of the read signal can be increased relative to the input signal D1 to actively carry out generation or disruption of the electrically conductive path CP. In a case that the read signal is of the same polarity with respect to the input signal D1, the electrically conductive path CP is generated by application of the read signal, so that disruption of the electrically conductive path CP in step S14 is suppressed, causing the degree of change over time of the electrically conductive path CP to decrease. In a case that the read signal is of the reverse polarity with respect to the input signal D1, the electrically conductive path CP disrupts by application of the read signal, so that disruption of the electrically conductive path CP in step S14 is accelerated, causing the degree of change over time of the electrically conductive path CP to increase. In this way, the degree of change over time of the conductivity of the electrically conductive path CP can be adjusted by not only selecting of the medium 12m in step S12, but also adjusting of the read signal in step S15.

[First Variation of Control Method of Information Processing Apparatus According to First Embodiment of the Present Disclosure]

In the control method shown in FIG. 6A, the admittance of the electrically conductive path CP is controlled by selecting the medium 12m so as to increase the admittance of the electrically conductive path CP based on the input signal D1 and to decrease over time the admittance of the electrically conductive path CP with the input signal D1 not being present. In other words, the information processing apparatus 1 is controlled so as to cause the electrically conductive path CP to disrupt after generating the electrically conductive path CP. However, the information processing apparatus 1 can be controlled to generate the electrically conductive path CP after causing the electrically conductive path CP to disrupt. In this case, the impedance of the electrically conductive path CP is controlled by selecting the medium 12m so as to increase the impedance of the electrically conductive path CP based on the input signal D1 and to decrease over time the impedance of the electrically conductive path CP with the input signal D1 not being present. Specifically, in the present variation, as shown in FIG. 6B, the control method of the information processing apparatus 1 includes step of selecting the electrical conductor 12a (see step S21 of FIG. 6B), step of selecting the medium 12m (see step S22 of FIG. 6B), step of increasing the impedance of the electrically conductive path CP (see step S23 of FIG. 6B), and step of decreasing the impedance of the electrically conductive path CP (see step S24 of FIG. 6B). In the present variation, in parallel with step S24 of decreasing the impedance of the electrically conductive path CP, step of generating the output signal D2 in accordance with a decrease in the impedance of the electrically conductive path CP (see step S25 of FIG. 6B) is carried out to obtain the output signal D2 that changes over time.

In the present variation, in step S22, for the impedance of the electrically conductive path CP to decrease over time (in other words, for the admittance of the electrically conductive path CP to increase over time), a metal constituting ions contained in the medium 12m is selected so as to have a higher electrode potential with respect to the medium 12m than that of a metal constituting the electrical conductor 12a (so as to typically have a smaller ionization tendency). For example, as the metal constituting the ions contained in the medium 12m, silver (Ag) is selected in step S22, and, in step S21, as the metal constituting the electrical conductor 12a, copper (Cu), which has a lower electrode potential with respect to the medium 12m than that of silver (Ag), is selected. Besides, in the same manner as in the above-described embodiment, the degree of decrease in the impedance of the electrically conductive path CP can be adjusted also by the type of ionic liquid, the type of anions contained in the ionic liquid, the ion concentration, and the like, besides the type of cations contained in the ionic liquid.

In the present variation, in step S23, the input signal D1 generated in the input portion 11 is input to the converting portion 12. At this time, dissolving, in the medium 12m, the electrically conductive path CP deposited in accordance with the input signal D1 causes the electrically conductive path CP to disrupt, thereby increasing the impedance of the electrically conductive path CP. In a case that the electrically conductive path CP is not present before carrying out step S23, for example, to generate the electrically conductive path CP, a set voltage of the reverse polarity with respect to the input signal D1 is applied to the converting portion 12 to cause the electrically conductive path CP to disrupt in accordance with the input signal D1 after generating the electrically conductive path CP.

In the present variation, in step S24, depositing the electrically conductive path CP from the medium 12m causes the electrically conductive path CP to be generated. In the present variation, in step S22, the medium 12m is selected so that the electrically conductive path CP deposits from the medium 12m even with the input signal D1 not being present in step S24. In other words, in the present variation, the electrically conductive path CP naturally deposits from the medium 12m even with no external stimuli being present with respect to the converting portion 12. The above-described steps S23 and S24 are repeated to reversibly cause the electrically conductive path CP to disrupt. Here, in step S24, as described above, with no input signal D1 being present, the 80% attenuation time of impedance of the electrically conductive path CP is preferably set to be within a range of 10⁻⁶ sec to 10 7 sec in the initial period of attenuation, more preferably set to be within a range of 10⁻⁶ sec to 1 sec in the initial period of attenuation, and is further preferably set to be within a range of 10⁻⁶ sec to 10⁻³ sec in the initial period of attenuation. This allows a good consistency of the processing speed of an electronic device such as a silicon (Si)-based one, with respect to change over time of the electrical conductivity, making it suitable to use the information processing apparatus 1 in conjunction with an existing electronic device. As described above, the degree of decrease in the impedance of the electrically conductive path CP can also be adjusted by constituting components of the electrical conductor 12a, and the like, besides the medium 12m (specifically, the type of ionic liquid, and the type and concentration of ions dissolved in the ionic liquid).

In the present variation, in step S25, to read the electrical conductivity (admittance/impedance) of the converting portion 12, a predetermined read signal (read voltage in the present embodiment) is applied to the converting portion 12 to cause the output signal D2 to be generated as a current that changes over time in accordance with change over time of the electrical conductivity of the electrically conductive path CP. The read signal is not particularly limited as long as it can read the electrical conductivity of the electrically conductive path CP, so that it can be a continuous signal of a constant intensity, can be a pulse signal, or can be a signal of the same polarity with respect to the input signal D1 or can be a signal of the reverse polarity with respect thereto. In the present variation, the read signal is a pulse signal composed of a pulse voltage having an absolute value considerably smaller than that of the input signal D1 (specifically, one to three orders of magnitude smaller in absolute value than that of the input signal). Therefore, the electrical conductivity of the electrically conductive path CP hardly changes with application of the read signal. Moreover, in the present variation, the read signal is a signal of the reverse polarity with respect to the input signal D1. Therefore, contrary to the electrically conductive path CP that disrupts in step S23 and that is generated in step S24 to be carried out in parallel with step S25, the electrically conductive path CP does not disrupt, but rather is generated, so that the electrical conductivity of the electrically conductive path CP continues to change over time in step S25. Besides, in step S25, the absolute value of the read signal can be increased relative to the input signal D1 to actively carry out generation or disruption of the electrically conductive path CP. In a case that the read signal is of the same polarity with respect to the input signal D1, the electrically conductive path CP disrupts by application of the read signal, so that generation of the electrically conductive path CP in step S24 is suppressed, causing the degree of change over time of the electrically conductive path CP to decrease. Moreover, in a case that the read signal is of the reverse polarity with respect to the input signal D1, the electrically conductive path CP is generated by application of the read signal, so that generation of the electrically conductive path CP in step S24 is accelerated, causing the degree of change over time of the electrically conductive path CP to increase. In this way, the degree of change over time of the electrical conductivity of the electrically conductive path CP can be adjusted by not only the selection of the medium 12m in step S22, but also the adjustment of the read signal in step S25.

[Second Variation of Control Method of Information Processing Apparatus According to First Embodiment of the Present Disclosure]

In the control method shown in FIG. 6A, the output signal D2 is generated by reading the electrical conductivity (admittance/impedance) of the electrically conductive path CP with a read signal when the admittance of the electrically conductive path CP is increased based on the input signal D1 and the admittance of the electrically conductive path CP decreases over time with no input signal D1 being present. In other words, in the control method shown in FIG. 6A, the output signal D2 is output with a time interval from inputting of the input signal D1 (see FIG. 17A). However, the output signal D2 can be generated in accordance with an increase in the admittance of the electrically conductive path CP by the input signal D1. In other words, in the control method of the present variation, the output signal D2 can be output at the same time as inputting of the input signal D1 (see FIG. 17B). Specifically, in the present variation, as shown in FIG. 6C, the control method of the information processing apparatus 1 includes step of selecting the electrical conductor 12a (see step S31 of FIG. 6C), step of selecting the medium 12m (see step S32 of FIG. 6C), step of increasing the admittance of the electrically conductive path CP (see step S33 of FIG. 6C), and step of decreasing the admittance of the electrically conductive path CP (see step S35 of FIG. 6C), and, in parallel with step S33 of increasing the admittance of the electrically conductive path CP, step of generating the output signal D2 (see step S34 of FIG. 6C) is carried out to obtain the output signal D2 that changes over time. In this case, in step S33, an output (specifically, a current signal) generated by inputting of the input signal D1 (specifically, a voltage signal) into the converting portion 12 is to be the output signal D2 as is.

[Third Variation of Control Method of Information Processing Apparatus According to First Embodiment of the Present Disclosure]

In the control method shown in FIG. 6B, the output signal D2 is generated by reading the electrical conductivity (admittance/impedance) of the electrically conductive path CP with a read signal when the impedance of the electrically conductive path CP is increased based on the input signal D1 and the impedance of the electrically conductive path CP decreases over time with no input signal D1 being present. In other words, in the control method shown in FIGS. 6A and 6B, the output signal D2 is output with a time interval from inputting of the input signal D1 (see FIG. 17A). However, the output signal D2 can be generated in accordance with change in the impedance of the electrically conductive path CP by the input signal D1. In other words, in the control method of the present variation, the output signal D2 is output at the same time as inputting of the input signal D1 (see FIG. 17B). Specifically, in the present variation, as shown in FIG. 6D, the control method of the information processing apparatus 1 includes step of selecting the electrical conductor 12a (see step S41 of FIG. 6D), step of selecting the medium 12m (see step S42 of FIG. 6D), step of increasing the impedance of the electrically conductive path CP (see step S43 of FIG. 6D), and step of decreasing the impedance of the electrically conductive path CP (see step S45 of FIG. 6D), and, in parallel with step S43 of increasing the impedance of the electrically conductive path CP, step of generating the output signal D2 (see step S44 of FIG. 6D) is carried out to obtain the output signal D2 that changes over time. In this case, in step S43, an output (specifically, a current signal) generated by inputting of the input signal D1 (specifically, a voltage signal) into the converting portion 12 is to be the output signal D2 as is.

[The Other Variations of Control Method of Information Processing Apparatus According to First Embodiment of the Present Disclosure]

In FIGS. 6A and 6C, the output signal D2 is generated by either one of change in the admittance of the electrically conductive path CP with no input signal D1 being present and change in the admittance of the electrically conductive path CP by the input signal D1. However, the output signal D2 can be obtained in accordance with change in the admittance of the electrically conductive path CP by the input signal D1 after obtaining the output signal D2 in accordance with change in the admittance of the electrically conductive path CP with no input signal D1 being present (in other words, in FIG. 6A, “step of generating the output signal D2” in parallel with step S13 can be added, and, in FIG. 6C, “step of generating the output signal D2” in parallel with step S35 can be added.) Moreover, in FIGS. 6B and 6D, the output signal D2 is generated by either one of change in the impedance of the electrically conductive path CP with no input signal D1 being present and change in the impedance of the electrically conductive path CP by the input signal D1. However, the output signal D2 can be obtained in accordance with change in the impedance of the electrically conductive path CP by the input signal D1 after obtaining the output signal D2 in accordance with change in the impedance of the electrically conductive path CP with no input signal D1 being present. (In other words, in FIG. 6B, “step of generating the output signal D2” in parallel with step S23 can be added, and, in FIG. 6D, “step of generating the output signal D2” in parallel with step S45 can be added.)

As the output signal D2, both an output generated by inputting of the input signal D1 and an output generated by application of a read signal can be obtained at the same time. In other words, the output signal D2 can be obtained by applying a read signal to the converting portion 12 while inputting the input signal D1 into the converting portion 12. In a case that each of the input terminal 11a and the output terminal 13a is present in a plurality, for example, the input signal D1 is input from the plurality of input terminals 11a, the one output signal D2 is output from the one output terminal 13a of the plurality of output terminals 13a, and change in the one output signal D2 in a predetermined time interval is learned. However, the difference in the plurality of output signals D2 can be learned with the input signal D1 being input from the plurality of input terminals 11a and the plurality of output signals D2 being output from the plurality of output terminals 13a.

According to the information processing apparatus 1 and a control method of the information processing apparatus 1 according to the present embodiment, to be configured as described above, focusing on change over time in the electrical conductivity of the electrically conductive path CP to be formed in an electrolyte such as an ionic liquid, the electrically conductive path CP can be utilized as a promising core technology for the information processing apparatus 1 such as a neuromorphic apparatus, a reservoir computing apparatus, and the like. For example, in an information processing apparatus utilizing a tunnel magnetoresistance effect, which information processing apparatus is being proposed as the neuromorphic apparatus and the reservoir computing apparatus, the degree of change in a conversion layer (reservoir layer) is faster than that in the information processing apparatus according to the present embodiment, so that the consistency with the processing speed of an existing electronic device is not good. On the other hand, in the information processing apparatus 1 according to the present embodiment, the electrical conductivity (admittance/impedance) of the electrically conductive path CP can be changed over time within a range in which there is a good consistency with the processing speed of the existing electronic device (an 80% attenuation time of the admittance/impedance of the electrically conductive path CP is preferably within a range of 10⁻⁶ sec to 10 7 sec in the initial period of attenuation, more preferably within a range of 10⁻⁶ sec to 1 sec in the initial period of attenuation, and further preferably within a range of 10⁻⁶ sec to 10⁻³ sec in the initial period of attenuation). Therefore, the present embodiment makes it possible to obtain the information processing apparatus 1 suitable for use in conjunction with an existing electronic device.

According to the present embodiment, the degree of change over time of the electrical conductivity of the electrically conductive path CP can be adjusted by selecting the type of ionic liquid, the type and concentration of ions to be dissolved in the ionic liquid, and constituting components of the electrical conductor. This makes it possible to select adjustment of change over time of the electrical conductivity from a plurality of selections and also makes it possible to adjust the degree of change of the electrical conductivity in a wide range. Moreover, in the embodiment, the ion concentration in the ionic liquid itself changes over time, and the output signal D2 reflects the oxidizing species and concentration thereof that contribute to oxidization, and the reducing species and concentration thereof that contribute to reduction. In other words, the ionic liquid itself comprised by the converting portion 12 contains historical information, and the output signal reflects this historical information. This makes it possible to carry out information processing with a simpler structure compared to an information processing apparatus such as a general neural network apparatus, which information processing apparatus requires storage, and arithmetic operation of historical information.

In the present embodiment, the substrate B having the flat surface S is used and the converting portion 12 having a simple two-dimensional structure is formed on the surface S of the substrate B, making it easy to prepare the converting portion 12.

[Information Processing Apparatus and Control Method of Information Processing Apparatus According to Second Embodiment of the Present Disclosure]

Next, with reference to the attached drawings, an information processing apparatus and a control method of an information processing apparatus of the second embodiment of the present disclosure will be described. Those points described in the respective features of the first embodiment can also be similarly applied to the information processing apparatus and the control method of an information processing apparatus of the second embodiment. In the description below, the points described in the first embodiment will be omitted, so that primarily the differences will be described.

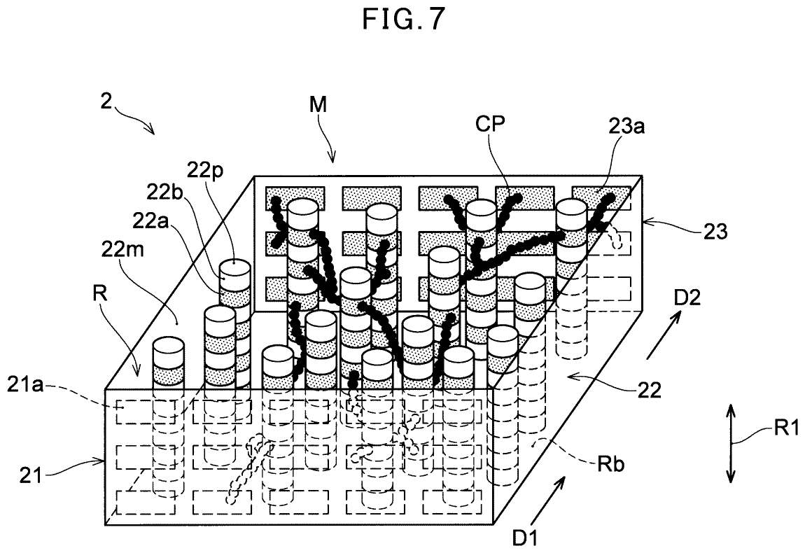

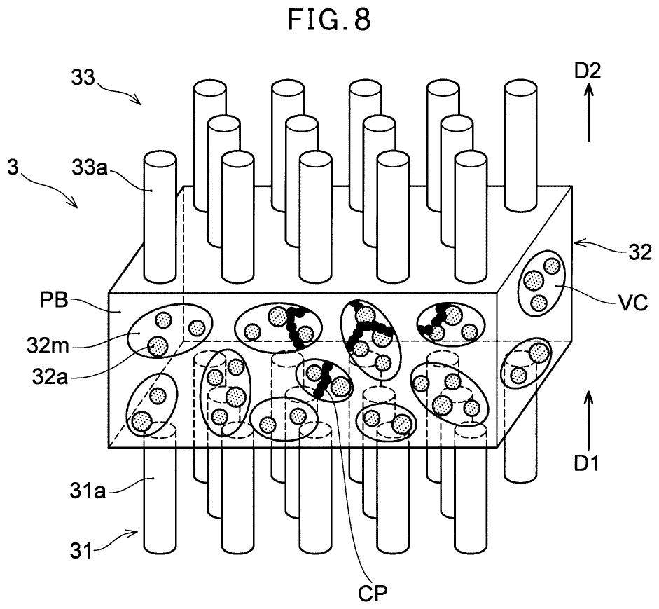

FIG. 7 schematically shows an information processing apparatus 2 according to the second embodiment of the present disclosure. As shown in FIG. 7, the information processing apparatus 2 according to the present embodiment comprises a base material M having a concave portion R, and at least a part of the information processing apparatus 2 is formed in an inner space of the concave portion R. While the shape of the concave portion R is not particularly limited, in the present embodiment, the concave portion R is recessed in a quadangular prism shape. However, the concave portion R can be recessed in a different shape such as a cylindrical shape. As long as the inner surface of the concave portion R has an insulating or semi-insulating property, the base material M is not particularly limited. For example, the base material M can be composed of an insulating substrate such as ceramics, a semiconductor wafer such as a monocrystalline silicon (Si), a metal core substrate in which an insulating coating such as SiO₂ is applied on a surface of a conductive base material such as copper (Cu).

As shown in FIG. 7, in the same manner as in the first embodiment, in correspondence with FIG. 1, the information processing apparatus 2 according to the present embodiment also has an input portion 21, converting portions 22, and an output portion 23, and can demonstrate the above-described functions shown in the conceptual diagram of FIG. 1.

Also in the present embodiment, in the same manner as in the first embodiment, as shown in FIG. 7, the input portion 21 has an input terminal 21a corresponding to the input node V1 (FIG. 1). In the present embodiment, the input terminal 21a is arranged on one side wall of the concave portion R so as to be separated from electrical conductors 22a of a converting portion 22 to be described below. More specifically, the input terminal 21a is arranged in a plurality in a grid pattern on one side wall of the concave portion R. However, there can be the one input terminal 21a, or the input terminal 21a can be arranged on a plurality of side walls. The constituting components and layer configuration of the input terminal 21a are similar to those in the first embodiment, so that explanations thereof will be omitted.

In the present embodiment, as shown in FIG. 7, the converting portion 22 is provided in the interior of the concave portion R. Also in the present embodiment, in the same manner as in the first embodiment, the converting portions 22 are arranged in separation with each other and comprise the plurality of electrical conductors 22a corresponding to the converting node V2 (FIG. 1) and a medium 22m to be arranged so as to mutually connect the plurality of electrical conductors 22a. In the present embodiment, the converting portion 22 comprises a columnar body 22p extending in an opening direction R1 of the concave portion R from the bottom of the concave portion R, and the columnar body 22p has a structure in which an electrical conductor 22a and an insulator 22b are alternately arranged. In this way, in the opening direction R1, the electrical conductors 22a are arranged in the columnar body 22p in separation with each other with the insulator 22b placed therebetween. The number of columnar bodies 22p can be one or a plurality, and, in a case that it is the plurality, the columnar bodies 22p can be arranged randomly in the interior of the concave portion R as in FIG. 7, or they can be arranged regularly, such as in a grid or linear pattern. The number of repetitions of the electrical conductor 22a and the insulator 22b of the columnar body 22p can be one or can be a plurality, and, in a case that it is the plurality, the intervals of the electrical conductors 22a and the intervals of the insulators 22b of the columnar body 22p can be equal intervals or can be different intervals. In a case that the intervals of the electrical conductors 22a and the intervals of the insulators 22b are equal intervals, these constituting components can be composed of known materials used in a semiconductor manufacturing process, in this case, a known semiconductor manufacturing process in which CVD (chemical vapor deposition), vapor deposition, or sputtering, and the like is combined with photolithography to carry out microfabrication can be used to easily prepare the converting portion 22.

The constituting components and layer configuration of the electrical conductor 22a are similar to those in the first embodiment, so that, here, explanations thereof will be omitted. Besides, in the same manner as the electrical conductor 12a in the first embodiment, the electrical conductor 22a can be composed of the same metal as a metal constituting ions contained in the medium 22m, or it can be composed of an electrically conductive non-metallic material such as carbon (C), or an electrically conductive organic material. The insulator 22b can be composed of known components such as silicon oxide (SiO₂), silicon nitride (Si₃N₄), silicon oxy-nitride (Si_{X+Y}O_{2X}N_{4/3Y} (X>0,Y>0)), and can be composed of a single layer thereof, or can be composed of a plurality of layers thereof by stacking in the opening direction R1.

Also in the present embodiment, as shown in FIG. 7, the medium 22m is configured to be capable of controlling, based on the input signal D1 (see FIG. 1), the electrical conductivity (admittance/impedance) of the electrically conductive path CP mutually electrically connecting the plurality of electrical conductors 22a. In the present embodiment, the medium 22m is filled in the interior of the concave portion R. The constituting components of the medium 22m are similar to those in the first embodiment, so that explanations thereof will be omitted here.

Also in the present embodiment, as shown in FIG. 7, the output portion 23 has an output terminal 23a corresponding to the output node V3 (FIG. 1). In the present embodiment, the output terminal 23a is arranged on the other side wall (a side wall on a side opposite to the input terminal 21a) of the concave portion R so as to be separated from the electrical conductor 22a. More specifically, the output terminal 23a is arranged in a plurality in a grid pattern on the other side wall of the concave portion R. However, there can be the one output terminal 23a, or the output terminal 23a can be arranged on a plurality of side walls. The constituting components and layer configuration of the output terminal 23a are similar to those in the first embodiment, so that the explanations thereof will be omitted here.

The control method of the information processing apparatus 2 according to the present embodiment to be configured as described above is similar to the control method of the information processing apparatus 1 according to the first embodiment, so that the explanations thereof will be omitted here.

According to the information processing apparatus 2 and the control method of the information processing apparatus 2 according to the present embodiment, in the same manner as in the first embodiment, the electrically conductive path CP in which the electrical conductivity changes over time can be utilized as a promising core technology for the information processing apparatus 2 such as a neuromorphic apparatus, a reservoir computing apparatus, and the like. Moreover, in the present embodiment, the converting portion 22 can be three-dimensionally formed in the interior of the concave portion R, making it possible to densely arrange the plurality of electrical conductors 22a. Therefore, downsizing of the information processing apparatus 2 can be achieved.

[Information Processing Apparatus and Control Method of Information Processing Apparatus According to Third Embodiment of the Present Disclosure]

Next, with reference to the attached drawings, an information processing apparatus and a control method of an information processing apparatus of the third embodiment of the present disclosure will be described. Those points described in the respective features of the above-described embodiments can also be similarly applied to the information processing apparatus and the control method of an information processing apparatus of the third embodiment. In the description below, the points described in the above-described embodiments thereof will be omitted, so that primarily the differences will be described.

FIG. 8 schematically shows an information processing apparatus 3 according to a third embodiment of the present disclosure. As shown in FIG. 8, the information processing apparatus 3 according to the present embodiment comprises a porous body PB having a large number of vacancies VC mutually connected, and at least a part of the information processing apparatus 2 is formed in the porous body PB. The constituting component of the porous body PB is not limited as long as it has an insulating or semi-insulating property. The porous body PB can be composed of a known low-k material such as fluorine (F)-doped silicon oxide (F—SiO₂) and carbon (C)-doped silicon oxide (C—SiO₂), for example. While the shape of the porous body PB is not particularly limited, in the present embodiment, the porous body PB has a rectangular parallelopiped shape. However, the porous body PB can have a different shape such as a cylindrical shape.

As shown in FIG. 8, in correspondence with FIG. 1, the information processing apparatus 3 according to the present embodiment also has an input portion 31, converting portions 32, and an output portion 33, and can demonstrate the above-described functions shown in the conceptual diagram of FIG. 1.

Also in the present embodiment, as shown in FIG. 8, the input portion 31 has an input terminal 31a corresponding to the input node V1 (FIG. 1). In the present embodiment, the input terminal 31a is arranged on one side wall of the porous body PB so as to be separated from an electrical conductor 22a of the converting portion 32 to be described below. More specifically, the input terminal 31a is arranged in a plurality in a grid pattern on one side wall of the porous body PB. However, there can be the one input terminal 31a, or the input terminal 31a can be arranged on a plurality of side walls. The constituting components and layer configuration of the input terminal 31a are similar to those in the first embodiment, so that explanations thereof will be omitted.

In the present embodiment, as shown in FIG. 8, the converting portion 32 is provided in the porous body PB. Also in the present embodiment, in the same manner as in the first embodiment, the converting portions 32 are arranged in separation with each other and comprise the plurality of electrical conductors 32a corresponding to the converting node V2 (FIG. 1) and a medium 32m to be arranged so as to mutually connect the plurality of electrical conductors 32a. In the present embodiment, the converting portion 32 has a particle shape and is dispersed in the medium 32. In this case, by permeating the medium 32m in the porous body PB so as to fill the vacancy VC, the electrical conductors 32a are arranged in a dispersed manner in the porous body PB so as to be in mutual separation. The constituting components and layer configuration of the electrical conductor 32a are similar to those in the first embodiment, so that explanations thereof will be omitted here. Besides, in the same manner as the electrical conductor 12a in the first embodiment, the electrical conductor 32a can be composed of the same metal as a metal constituting ions contained in the medium 32m, or it can be composed of an electrically conductive non-metallic material such as carbon (C), or an electrically conductive organic material.

Also in the present embodiment, as shown in FIG. 8, the medium 32m is configured to be capable of controlling, based on the input signal D1, the electrical conductivity (admittance/impedance) of the electrically conductive path CP mutually electrically connecting the plurality of electrical conductors 32a. In the present embodiment, as described above, the medium 32m is filled in the vacancy VC of the porous body PB. The constituting components of the medium 32m are similar to those in the first embodiment, so that explanations thereof will be omitted here.

Also in the present embodiment, as shown in FIG. 8, the output portion 33 has an output terminal 33a corresponding to the output node V3 (FIG. 1). In the present embodiment, the output terminal 33a is arranged on the other side wall (a side wall on a side opposite to the input terminal 31a) of the porous body PB so as to be separated from the electrical conductor 32a. More specifically, the output terminal 33a is arranged in a plurality in a grid pattern on the other side wall of the porous body PB. However, there can be the one output terminal 33a, or the output terminal 33a can be arranged on a plurality of side walls. The constituting components and layer configuration of the output terminal 33a are similar to those in the first embodiment, so that the explanations thereof will be omitted here.

The control method of the information processing apparatus 3 according to the present embodiment to be configured as described above is similar to the control method of the information processing apparatus 1 according to the first embodiment, so that the explanations thereof will be omitted here.

According to the information processing apparatus 3 and the control method of the information processing apparatus 3 according to the present embodiment, in the same manner as in the above-described embodiments, the electrically conductive path CP in which the electrical conductivity changes over time can be utilized as a promising core technology for the information processing apparatus 3 such as a neuromorphic apparatus, a reservoir computing apparatus, and the like. Moreover, in the present embodiment, in the same manner as in the second embodiment, the converting portion 32 can be three-dimensionally formed in the porous body PB, making it possible to densely arrange the plurality of electrical conductors 32a. Therefore, downsizing of the information processing apparatus 3 can be achieved. Furthermore, in the present embodiment, by permeating the medium 32m so as to fill the vacancy VC of the porous body PB, the plurality of electrical conductors 32a can be arranged in a dispersed manner without carrying out any control in particular, making it possible to more easily prepare the converting portion 32.

[Information Processing Apparatus and Control Method of Information Processing Apparatus According to Fourth Embodiment of the Present Disclosure]

Next, with reference to the attached drawings, an information processing apparatus and a control method of an information processing apparatus of the fourth embodiment of the present disclosure will be described. Those points described in the respective features of the first embodiment can also be similarly applied to the information processing apparatus and the control method of an information processing apparatus of the fourth embodiment. In the description below, the points described in the first embodiment will be omitted, so that primarily the differences will be described.

FIGS. 9 and 10 schematically show an information processing apparatus 4 according to the fourth embodiment of the present disclosure. In the present embodiment, an insulator 42b is interposed in a part between electrical conductors 42a (In FIGS. 9 and 10, the electrical conductors 42a are composed of an input terminal 41a and an output terminal 43a) and a medium 42m (see FIG. 10). Besides, in the examples in FIGS. 9 and 10, a converting portion 42 incorporates therein, as the electrical conductors 42a, the input terminal 41a of an input portion 41 and the output terminal 43a of an output portion 43, while, as shown in FIG. 2 and the like, it can also have the electrical conductors 42a separately from the input terminal 41a and the output terminal 43a (see also FIG. 22). Arrangement of the electrical conductors 42a to be provided separately from the input terminal 41a and the output terminal 43a is not particularly limited as long as the electrical conductors 42a are within a wall partition WP to be described below. In the present embodiment, in the same manner as in the first embodiment, the information processing apparatus 4 comprises a substrate B having a flat surface S, and the input portion 41, the converting portion 42, and the outputting portion 43 are formed on the surface S of the substrate B. In the present embodiment, the converting portion 42 further comprises the wall partition WP (see FIG. 10) that houses the medium 42m in the interior thereof.

The insulator 42b is provided in a desired portion of the input terminal 41a and the output terminal 43a to cause a dissolution and deposition reaction (a redox reaction) between the input terminal 41a and the medium 42m and between the output terminal 43a and the medium 42m. In other words, in a portion in which the insulator 42b is interposed between the input terminal 41a and the medium 42m and between the output terminal 43a and the medium 42m, the input terminal 41a and the output terminal 43a do not come into contact with the medium 42m, respectively, so that the dissolution and deposition reaction (the redox reaction) is suppressed, while in a portion in which the input terminal 41a and the output terminal 43a come into contact with the medium 42m, respectively, without the insulator 42b being interposed, the dissolution and deposition reaction (the redox reaction) proceeds. In this way, in the converting portion 42, an electrically conductive path (not shown in FIGS. 9 and 10) is formed in a desired portion, so that the controllability of the converting portion 42, and, by extension, the controllability of the information processing apparatus 4 increases. In the present embodiment, the insulator 42b is provided so that mutually opposing tips 41at, 43at of the input terminal 41a and the output terminal 43a are exposed such that an electrically conductive path is generally formed in a shortest path in between portions in which the input terminal 41a and the output terminal 43a are in mutual proximity, respectively. More specifically, a first insulator 42b1 is provided on substantially the entire surface of the input terminal 41a and the output terminal 43a (top surface) opposite to the surface facing the substrate B so that the electrically conductive path being formed in a perpendicular direction with respect to the surface S of the substrate B is suppressed, while a second insulator 42b2 is provided so that a predetermined region Ab in the vicinity of the input terminal 41a and the output terminal 43a is exposed on the surface of the first insulator 42b1 and the surface S of the substrate B. However, the arrangement of the insulator 42b can be appropriately changed in accordance with a formed path of an electrically conductive path desired, a forming process of the insulator 42b, and the like.

A constituting material of the insulator 42b (the first insulator 42b1, the second insulator 42b2) is not particularly limited as long as an insulating property can be secured and a dissolution and deposition reaction between the input terminal 41a and the output terminal 43a, and the medium 42m can be suppressed. For example, the insulator 42b (the first insulator 42b1, the second insulator 42b2) can be composed of known components having an insulating property, such as silicon oxide (SiO₂), silicon nitride (Si₃N₄), silicon oxy-nitride (Si_{X+Y}O_{2X}N_{4/3Y})(X>0,Y>0).

The wall partition WP is provided on the surface S of the substrate B (more specifically, the surface of the insulator 42b (the second insulator 42b2)) and defines an area Am in which the medium 42m is arranged (see FIG. 10; below called a “medium arrangement area”). In the interior of the wall partition WP, the medium 42m is housed by dropping, for example. The shape of the wall partition WP is not particularly limited as long as it is a closed space in which the medium 42m does not move to the exterior thereof. While the wall partition WP is formed in a rectangular frame shape, for example, it can have a different shape that forms a closed space. In the present embodiment, the constituting material of the wall partition WP is a photoresist (can be a positive-type photoresist or a negative-type photoresist). However, the wall partition WP can be composed of the other known materials, such as silicon oxide (SiO₂), silicon nitride (Si₃N₄), silicon oxy-nitride (Si_{X+Y}O_{2X}N_{4/3Y})(X>0,Y>0)). While a forming method of the wall partition WP is not particularly limited, it can be changed appropriately in accordance with the material of the wall partition WP. For example, in a case that the constituting material of the wall partition WP is a photoresist, the wall partition WP can be formed in a desired shape through application of a liquid photoresist using spin-coating and curing or dissolution of the liquid photoresist using photolithography. Moreover, in a case that the wall partition WP is composed of silicon oxide (SiO₂) and the like, the wall partition WP can be formed in a desired shape through deposition of silicon oxide (SiO₂) and the like using CVD (chemical vapor deposition) and etching of silicon oxide (SiO₂) and the like using photolithography.

The constituting components and layer configuration of the input terminal 41a, the output terminal 43a, and the substrate B are similar to those in the first embodiment, so that the explanations thereof will be omitted here.

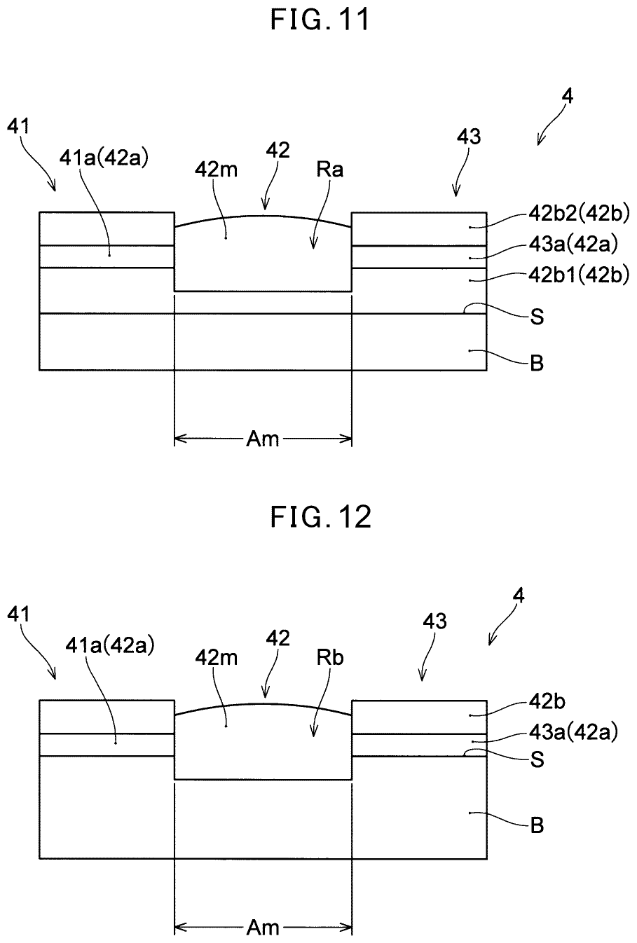

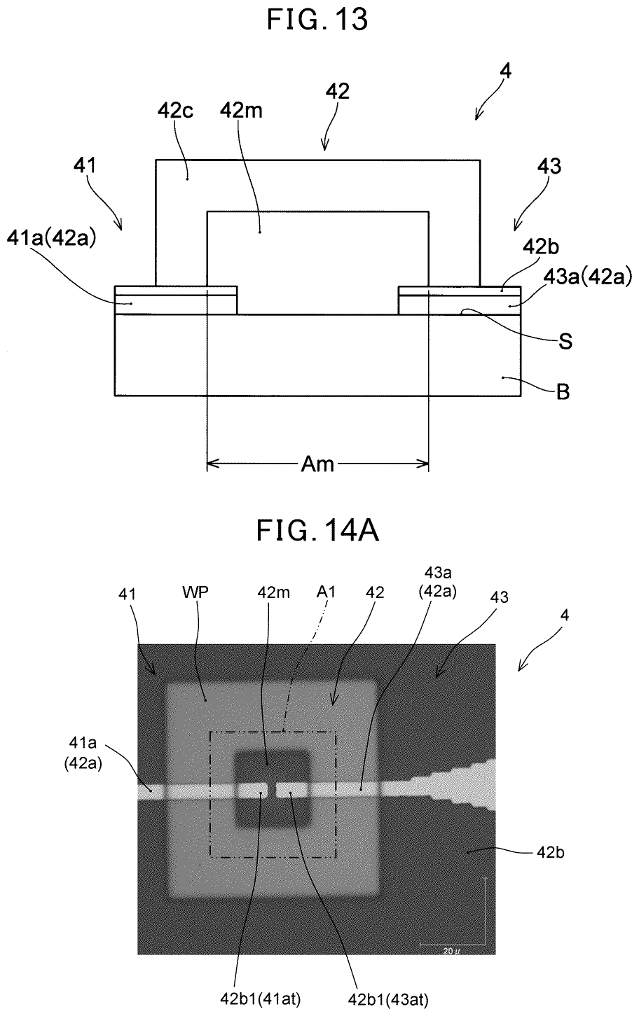

Besides, FIG. 10 defines the medium arrangement area Am with the wall partition WP, but the medium arrangement area Am can be defined as described below. FIGS. 11 to 13 show the information processing apparatus according to variations of the present embodiment. In a first variation shown in FIG. 11, the first insulator 42b1, the input terminal 41a and the output terminal 43a, and the second insulator 42b2 are successively formed on the surface S of the substrate B, and the concave portion Ra is provided from the surface of the second insulator 42b2 to the first insulator 42b1 in a direction perpendicular to the surface S of the substrate B. In the first variation, the medium arrangement area Am can be defined by the concave portion Ra. In the first variation, the first insulator 42b1 is interposed between the input terminal 41a and the output terminal 43a, and the substrate B, so that the substrate B can have an insulating property or can be electrically conductive. In a second variation shown in FIG. 12, the input terminal 41a and the output terminal 43a, and the insulator 42b are successively formed on the surface S of the substrate B, and a concave portion Rb is provided from the surface of the insulator 42b to the substrate B in a direction perpendicular to the surface S of the substrate B. Also in the second variation, the medium arrangement area Am can be defined by the concave portion Rb. In the second variation, the substrate B is in contact with the input terminal 41a and the output terminal 43a, so that at least the surface S of the substrate B has an insulating property. In a third variation shown in FIG. 13, the input terminal 41a and the output terminal 43a, and the insulator 42b are successively formed on a part of the surface S of the substrate B, and the medium 42m is provided in a predetermined region of the surface of the insulator 42b and the surface S of the substrate B, which predetermined region includes the tips 41at, 43at of the input terminal 41a and the output terminal 43a. By being covered with a covering body 42c, the medium 42m is sealed by the surface S of the substrate B. In the third variation, a medium arrangement region Am can be defined with the covering body 42c. Besides, while the covering body 42c is not particularly limited as long as it has an insulating property to prevent shorting between the input terminal 41a and the output terminal 43a, it is preferably composed of a material superior in moldability. Examples of such a material include, for example, an insulating gel material (for example, (poly (dimethylsiloxane): PDMS) and a resin (for example, a thermosetting resin such as a silicone resin). In the third variation, the substrate B is in contact with the input terminal 41a and the output terminal 43a, so that at least the surface S of the substrate B has an insulating property.

Besides, in the present embodiment, the input terminal 41a and the output terminal 43a do not have to be formed on the same plane. Moreover, in the present embodiment, the converting portion 42 can have an asymmetrical structure such as, for example, the shape of the input terminal 41a and the output terminal 43a being asymmetrical in plan view.

The control method of the information processing apparatus 4 according to the present embodiment to be configured as described above is similar to the control method of the information processing apparatus 1 according to the first embodiment, so that the explanations thereof will be omitted here.

According to the information processing apparatus 4 and the control method of the information processing apparatus 4 according to the present embodiment, in the same manner as in the above-described embodiments, an electrically conductive path in which the electrical conductivity changes over time can be utilized as a promising core technology for the information processing apparatus such as a neuromorphic apparatus, a reservoir computing apparatus, and the like. Moreover, in the present embodiment, the insulator 42b is interposed in a part between the electrical conductors 42a (In FIGS. 9 and 10, the input terminal 41 and the output terminal 43a), and the medium 42m, making it possible to cause a dissolution and deposition reaction (a redox reaction) only in a desired portion between the electrical conductors 42a and the medium 42m. This allows the controllability of the information processing apparatus 4 to improve.

### Fourth Example

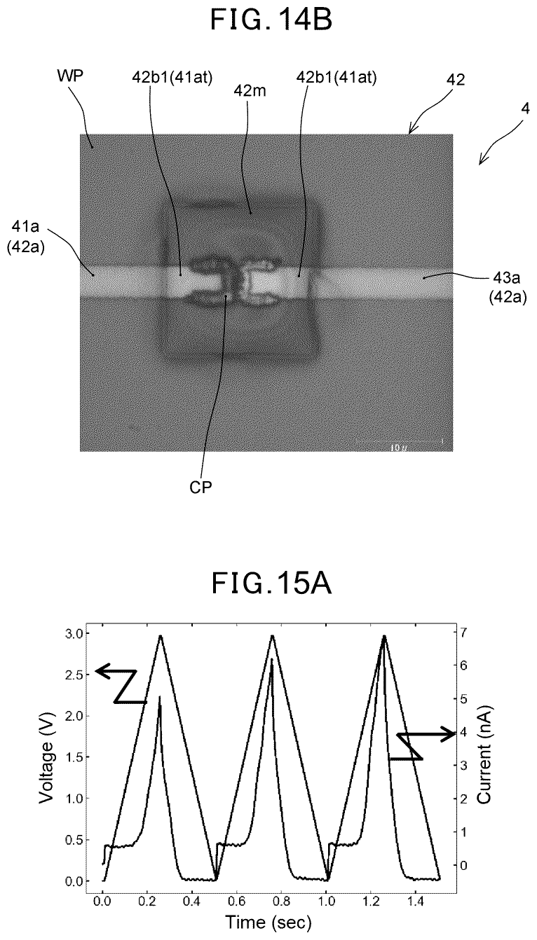

The present inventors have prepared the information processing apparatus 4 having a structure shown in FIGS. 9 and 10 to confirm formation of an electrically conductive path in the information processing apparatus 4 according to the fourth embodiment. A photograph by an optical microscope of the information processing apparatus 4 prepared is shown in FIG. 14A. Here, in the information processing apparatus 4 according to the present example, the substrate B (see FIGS. 9 and 10; cannot be visually recognized in FIG. 14A) is composed of monocrystalline silicon, the input terminal 41a and the output terminal 43a are spaced 2 μm apart and are composed of platinum (Pt), the first insulator 42b1 and the second insulator 42b2 are composed of silicon oxide (SiO₂), the wall partition WP is composed of a photoresist, and the medium 42m is composed of an ionic liquid in which Cu (II) (TFSA)₂ is dissolved in triglyme (G3) in a 1:1 ratio (below called “Cu (II)-G3”). Between the input terminal 41a and the output terminal 43a of the information processing apparatus 4, positive and negative voltages were alternately input between the input terminal 41a and the output terminal 43a as an input signal. A photograph by the optical microscope after inputting an input signal is shown in FIG. 14B. As shown in FIG. 14B, portions of the input terminal 41a and the output terminal 43a covered with the first insulator 42b1 and the second insulator 42b2 (in FIG. 14B, top surfaces of the tip 41at, 43at of the input terminal 41a and the output terminal 43a) are not deposited with metal (the electrically conductive path CP), and metal (the electrically conductive path CP) is deposited only from portions of the input terminal 41a and the output terminal 43a (in FIG. 14B, lateral surfaces of the tip 41at, 43at of the input terminal 41a and the output terminal 43a), which portions are exposed from the first insulator 42b1 and the second insulator 42b2. In this way, it was confirmed that the position at which the electrically conductive path is formed could be controlled by covering the first insulator 42b1 and the second insulator 42b2.

### Fifth to Seventh Examples

The present inventors have confirmed using the information processing apparatus 4 having a structure shown in FIGS. 9 and 10 to confirm that an output signal that changes over time could be obtained by causing the output signal to be output (see FIG. 17B) at the same time as inputting of the input signal as shown in the third variation of the first embodiment as described above (see fifth to seventh examples). Besides, in the fifth to seventh examples. a 2 bps (bit/s) triangular wave was used, which 2 bps (bit/s) triangular wave decreases a voltage between the input terminal 41a and the output terminal 43a to 0 V after increasing the voltage from 0 V to a maximum voltage in 0.5 sec as a set voltage to generate the electrically conductive path (below, an input signal to input the set voltage is shown as “1”). Moreover, a 2 bps (bit/s) triangular wave was used, which 2 bps (bit/s) triangular wave increases a voltage between the input terminal 41a and the output terminal 43a to 0 V after decreasing the voltage between the input terminal 41a and the output terminal 43a from 0 V to a minimum voltage in 0.5 sec as a reset voltage to cause an electrically conductive path to disrupt (below, an input signal to input the reset voltage is shown as “0”). Experimental conditions of the respective examples are as follows:

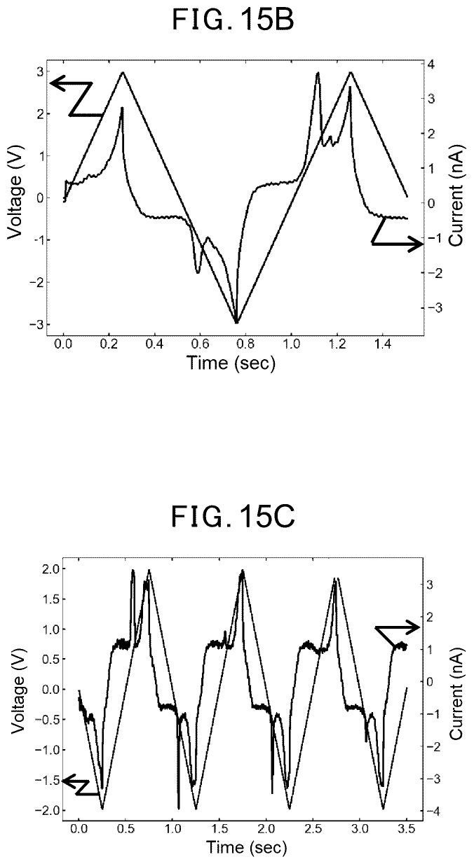

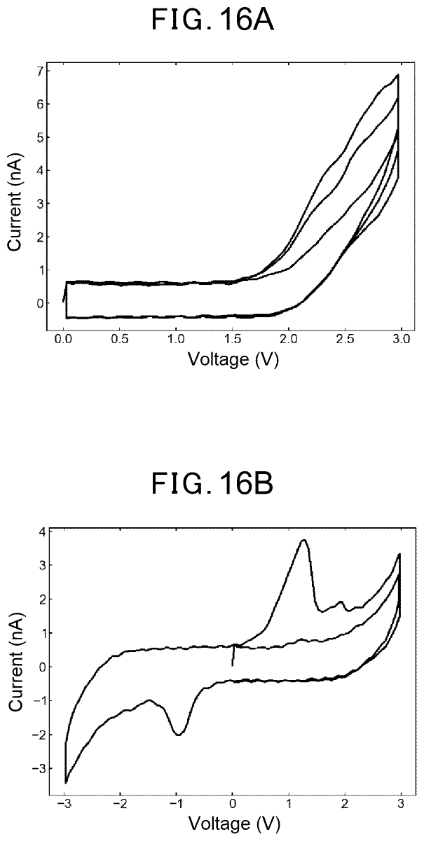

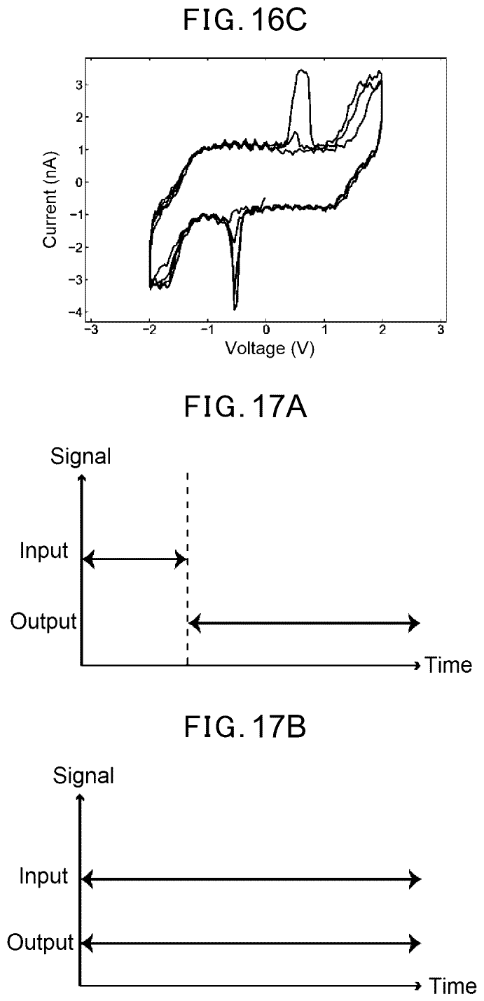

Fifth example: In the information processing apparatus 4 in the same manner as in the above-described fourth example, an input signal “111” was input (here, the maximum voltage was set to be 3V) between the input terminal 41a and the output terminal 43a, and outputting of an output signal was obtained at the same time as inputting of the input signal. Results of the output signal with respect to the input signal are shown in FIGS. 15A and 16A.

Sixth example: In the information processing apparatus 4 in the same manner as in the above-described fourth example, an input signal “101” was input (here, the maximum voltage was set to be 3V, and the minimum voltage was set to be−3V) between the input terminal 41a and the output terminal 43a, and outputting of an output signal was obtained at the same time as inputting of the input signal. Results of the output signal with respect to the input signal are shown in FIGS. 15B and 16B.

Seventh example: In the information processing apparatus 4 of the above-described fourth example, the medium 42m was changed to an ionic liquid in which Ag (TFSA) is dissolved in [Bmim] [TFSA] (below, called “Ag (TFSA)/[Bmim] [TFSA]”). To this information processing apparatus 4, an input signal “0101010” was input (here, the maximum voltage was set to be 2V, and the minimum voltage was set to be −2V) between the input terminal 41a and the output terminal 43a, and outputting of an output signal was obtained at the same time as inputting of the input signal. Results of the output signal with respect to the input signal are shown in FIGS. 15C and 16C.

As shown in FIGS. 15A to 15C, it is seen that the output signal that changes over time can be caused to be output at the same time as inputting of the input signal even when the types of medium adopted and input signal patterns are different. Moreover, as shown in FIGS. 16A and 16B (see also corresponding FIGS. 15A and 15B), it is seen that even in a case that the same “1” input signals are continuously input (fifth example) or in a case that the “0” input signal is input and the electrically conductive path is reset once (sixth example), the waveform of the output signal obtained is not the same, but changes over time. Furthermore, with reference to FIG. 16C (see also corresponding FIG. 15C), it is seen that this tendency is present not only in one specific medium (a medium in the fifth example), but also in another medium (a medium in the sixth example). From the above, it is expected that, even in a case that an arbitrary input signal is input to an arbitrary medium, an output signal that changes over time is obtained by causing an output to be output at the same time as inputting of the input signal.

In FIG. 15A, the maximum current increases in accordance with the number of times of inputting the “1” signal. Comparing third output signal waveforms in FIG. 15B of FIG. 15B, the output signal waveforms with respect to the input signal of “1” differ between a case in which one previous input signal is “1” (FIG. 15A) and a case in which one previous signal is “0”. In other words, historical information on whether the input signal is “0” or “1” is reflected in the output signal. In an information processing apparatus such as a neural network apparatus, in a case that carrying out information processing including the historical information is sought, it is necessary to carry out storage of and arithmetic operation on the historical information, so that the structure of the information processing apparatus becomes generally complex. In the present embodiment, the output signal itself contains the historical information, making it possible to carry out information processing with a simpler structure.

In a case that a mutually different plurality of output signals that change over time can be obtained from one input signal (below called “achieving higher dimensionality of data”), it is easier for the information processing apparatus to obtain a desired external output through learning and the like. Below, examples on achieving higher dimensionality of data by the information processing apparatus 4 according to the fourth embodiment will be described.

### Eighth Example

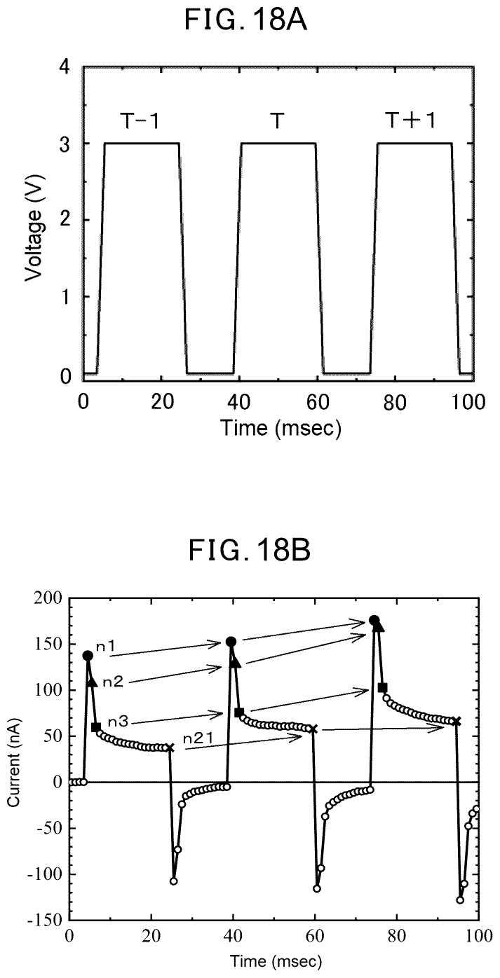

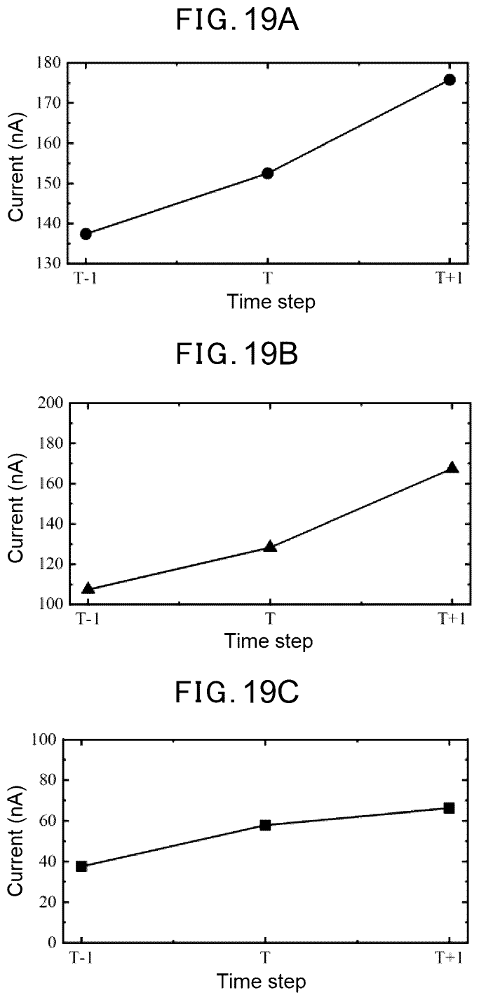

In the information processing apparatus 4 in the same manner as in the above-described fourth example, the inventors input an approximately 25 bps rectangular-wave RZ (return to zero) signal, which approximately 25 bps rectangular-wave RZ (return to zero) signal decreases a voltage between the input terminal 41a and the output terminal 43a to 0 V after increasing the voltage from 0 V to 3V in approximately 40 msec as an input signal (see FIG. 18A). Results of an output signal with respect to an input signal are shown in FIG. 18B. As shown in FIG. 18B, it is seen that, also in the present example, the output signal changes over time with respect to the input signal, which is a repetition of the same waveform. Then, the present inventors read a plurality of times (specifically, twenty-one (21) times. In FIG. 18B, each output signal reading is shown as n1 to n21) at equal intervals the output signal corresponding to the input signal in a period in which the input signal is maintained at 3V in one time step of the RZ (return to zero) signal (In FIG. 18A, three time steps (time steps “T−1” to “T+1”) are shown). Readings at the same reading time n1, n2, n21 in each of the time steps (“T−1” to “T+1”) are shown in FIGS. 19A to 19C.

As shown in FIGS. 19A to 19C, it was confirmed that, even in a case that the waveform of the RZ signal being the input signal did not change, time series data having a low or no similarity could be obtained by mutually varying the reading time n1, n2, n21 in the one time step of the input signal. In other words, in FIGS. 19A to 19C, assuming that each reading time n1 to n21 is one converting node V2 (see FIG. 1) (below, the reading at each reading time n1 to n21 is called “a virtual node”), time series data is obtained for each reading time n1 to n21. Adopting such a virtual node makes it possible to obtain a plurality of output signals being mutually different time series data sets in a so-called 1 input 1 output apparatus in which there is one input terminal 41a and one output terminal 43a, respectively.

[Information Processing Apparatus and Control Method of Information Processing Apparatus According to Fifth Embodiment of the Present Disclosure]

Next, with reference to the attached drawings, an information processing apparatus and a control method of an information processing apparatus of the fifth embodiment of the present disclosure will be described. Those points described in the respective features of the first embodiment can also be similarly applied to the information processing apparatus and the control method of an information processing apparatus of the fifth embodiment. In the description below, the points described in the first embodiment will be omitted, so that primarily the differences will be described.

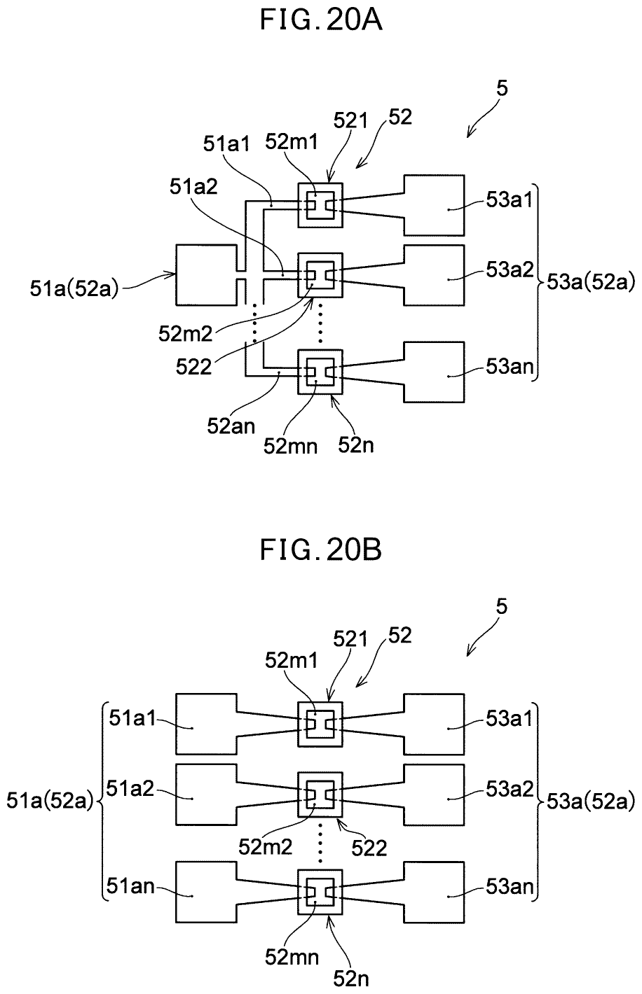

FIG. 20A schematically shows an information processing apparatus 5 according to a fifth embodiment of the present disclosure. In the present embodiment, a plurality of types of media are used to achieve higher dimensionality of data using a scheme different from the above-mentioned eighth example. Specifically, the information processing apparatus 5 includes a plurality of converting portions 521 to 52n as a converting portion 52, and a medium comprised by some converting portions of the plurality of converting portions 521 to 52n differs from a medium comprised by some other converting portions of the plurality of converting portions 521 to 52n. That “the medium” “differs” as recited here refers to either one of the type of solute (ions), the concentration of solute (ions), and the type of solvent (ionic liquid) being different and preferably refers to either one of the type of solute (ions) and the type of solvent (ionic liquid) being different. Besides, the term “medium differs” includes a case in which, in the operation process of the information processing apparatus 5, media 52m1 to 52mn that were initially the same are now mutually different as a result of a dissolution and deposition reaction and the like between the media 52m1 to 52mn, and electrical conductors 52a (In FIG. 20A, input terminals 51a1 to 51an and output terminals 53a1 to 53an). In the present embodiment, the respective media 52m1 to 52mn of the plurality of converting portions 521 to 52n are composed of mutually different media 52m1 to 52mn. However, some of the media 52m1 to 52mn of the plurality of converting portions 521 to 52n can be composed of the same medium. Besides, in the present embodiment, the configuration of each of the converting portions 521 to 52n is similar to that of the converting portion 42 described in the fourth embodiment other than the medium being different for each of the converting portions 521 to 52n, so that explanations thereof will be omitted.

In the present embodiment, as shown in FIG. 20A, an input terminal 51a that provides an input signal to the plurality of converting portions 521 to 52n is configured so as to provide the same input signal to the plurality of converting portions 521 to 52n. Specifically, the one input terminal 51a is branched, and the branched portions as a plurality of input terminals 51a1 to 51an are connected to the plurality of converting portions 521 to 52n, respectively. In the present embodiment, as shown in FIG. 20A, an output terminal 53a that provides output signals from the plurality of converting portions 521 to 52n is configured so as to separately provide the output signals from the plurality of converting portions 521 to 52n. Specifically, the plurality of independent separate output terminals 53a1 to 53an are connected to the plurality of converting portions 521 to 52n, respectively. However, as shown in FIG. 20B, the same input signal can be provided to the plurality of independent separate input terminals 51a1 to 51an, and the output signal can be separately provided from a plurality of independent separate output terminals 53a1 to 53an.

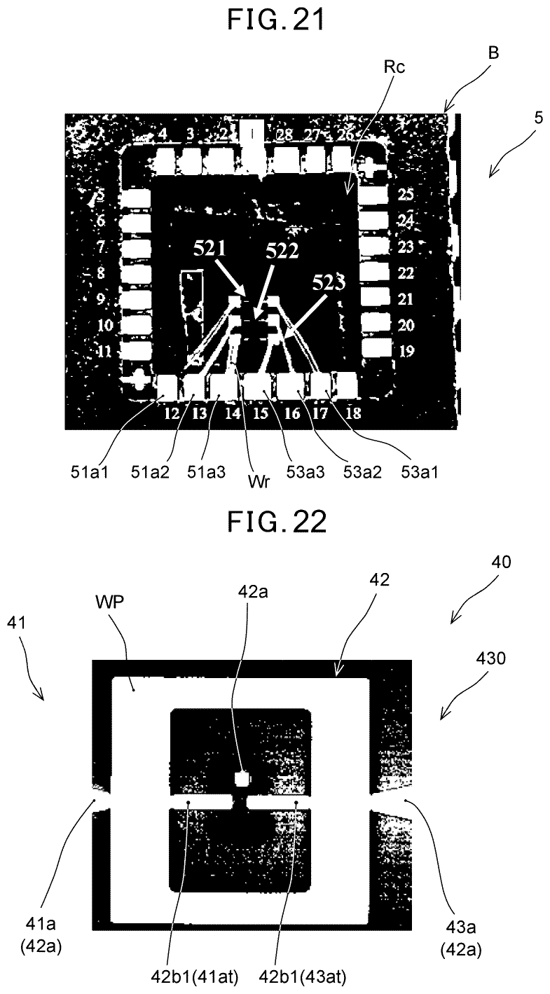

FIG. 21 shows a specific example of the information processing apparatus 5 according to the present embodiment. In the example of FIG. 21, a plurality of converting portions 521 to 523 (three in FIG. 21) are formed in a concave portion Rc (cavity) provided in a substrate B composed of a relay substrate (a ceramic substrate in FIG. 21) of a known semiconductor package (a so-called airtight sealed semiconductor package), and the plurality of converting portions 521 to 523 are electrically connected by an electrically conductive wire Wr to some (in FIG. 21, twelfth to seventeenth terminals) of a plurality of external connecting terminals (28 terminals in FIG. 21) provided in the substrate B, respectively, and the external connecting terminals connected by the electrically conductive wire Wr function as the input terminals 51a1 to 51a3 (twelfth to fourteenth terminals in FIG. 21) and the output terminals 53a1 to 53a3 (fifteenth to seventeenth terminals in FIG. 21). For example, the medium of the converting portions 521 to 53 can be varied by changing the medium for each of the converting portions 521 to 523, such as making the medium of the converting portion 521 to be Cu (II) (TFSA)₂/[Bmim] [TFSA] (an ionic liquid in which Cu (II) (TFSA)₂ is dissolved in [Bmim] [TFSA]), making the medium of the converting portion 522 to be Ag (TFSA)/[Bmim] [TFSA], and making the medium of the converting portion 523 to be Cu (II) (TFSA)₂+Ag (TFSA))/[Bmim] [TFSA] (an ionic liquid in which Cu (II) (TFSA)₂ and Ag (TFSA) are dissolved is dissolved in [Bmim] [TFSA]). In this way, the information processing apparatus 5 according to the present embodiment can also be formed using an existing semiconductor package.

The control method of the information processing apparatus 5 according to the present embodiment to be configured as described above is similar to the control method of the information processing apparatus 1 according to the first embodiment when viewed with respect to individual converting portions 521 to 52n, so that the explanations thereof will be omitted here.

According to the information processing apparatus 5 and the control method of the information processing apparatus 5 according to the present embodiment, in the same manner as in the above-described embodiments, an electrically conductive path in which the electrical conductivity changes over time can be utilized as a promising core technology for the information processing apparatus 5 such as a neuromorphic apparatus, a reservoir computing apparatus, and the like. Moreover, in the present embodiment, the converting portion 52 includes the plurality of converting portions 521 to 52n, and the medium comprised by some converting portions of the plurality of converting portions 521 to 52n differs from the medium comprised by some other converting portions of the plurality of converting portions 521 to 52n. Therefore, even when the same input signal is input to the some converting portions and to the some other converting portions, mutually different output signals can be obtained in accordance with mutually different media, making it possible to achieve higher dimensionality of data.

Besides, the information processing apparatus 5 shown in FIG. 20B can be configured such that different input signals are input to the plurality of converting portions 521 to 52n, or it can be configured such that the same input signals are input to some of the plurality of converting portions 521 to 52n, and different input signals are input to some other of the plurality of converting portions 521 to 52n. In this case, the some of the plurality of converting portions 521 to 52n and the some other of the plurality of converting portions 521 to 52n are to obtain mutually unrelated output signals from mutually unrelated input signals.

### Ninth to Tenth Examples

The present inventors carried out experiments as follows to confirm whether, in a case that the information processing apparatus 5 includes the plurality of converting portions 521 to 52n, as with the information processing apparatus 5 according to the fifth embodiment, with the plurality of converting portions 521 to 52n comprising the mutually different media 52m1 to 52mn, mutually different output signals could be obtained from the converting portions 521 to 52n even in a case that the same input signals were input to the converting portions 521 to 52n (see ninth to tenth examples).

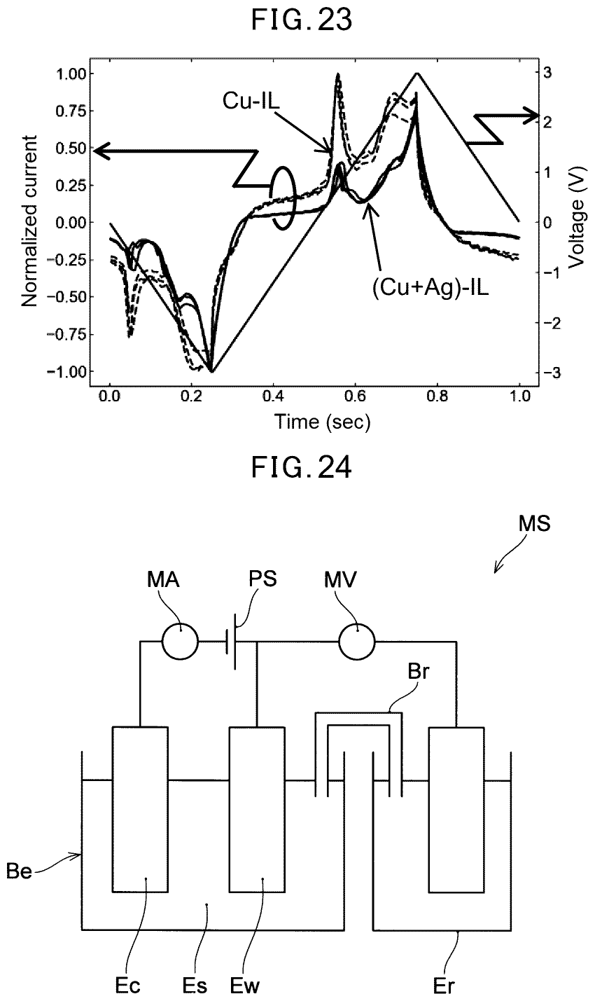

Ninth example: An information processing apparatus 4A having a structure similar to the information processing apparatus 4 having a structure shown in FIGS. 9 and 10 was prepared. A photograph by the optical microscope of the information processing apparatus 4A prepared is shown in FIG. 22. The information processing apparatus 4A according to the present example has a structure which differs from that of the information processing apparatus 4 in that the electrical conductor 42a being separate from the input terminal 41a and the output terminal 43a is provided at a position at a distance of substantially equal intervals from the input terminal 41a and the output terminal 43a so as to deviate from a direction in which the input terminal 41a and the output terminal 43a face each other. The other structures are the same as those for the information processing apparatus 4, so that, in FIG. 22, to the same parts, the same letters as in FIGS. 9 and 10 are affixed. The constituting material of each of the parts is the same as in the fourth example except that the electrical conductor 42a is composed of copper (Cu) and the medium 42m is composed of Ag (TFSA)/[Bmim][TFSA]. Besides, in the prepared information processing apparatus 4A, the interval between the input terminal 41a and the output terminal 43a was 4 μm, the size of the electrical conductor 42a was a 4 μm square, and the thickness of the electrical conductor 42a was 50 nm. To the information processing apparatus 4 prepared, a “01” input signal was input (here, the maximum voltage was set to be 1V and the minimum voltage was set to be −1V), and outputting of the output signal was obtained at the same time as inputting of the input signal. Results of the output signal with respect to the input signal are shown in FIG. 23. Besides, in the present example, besides silver (Ag) ions owning to Ag (TFSA)/[Bmim][TFSA], copper (Cu) ions due to the dissolution of the electrical conductor 42a were contained in the medium 42m. In FIG. 23, the output signal of the ninth example is shown as “(Cu+Ag)-IL”.

Tenth example: In the same manner as in the ninth example, the information processing apparatus 4 having a structure shown in FIGS. 9 and 10 was prepared. Besides, in the present example, unlike in the ninth example, the medium 42m was composed of Cu (II) (TFSA)₂/[Bmim][TFSA]. To the information processing apparatus 4 prepared, in the same manner as in the ninth example, a “01” input signal was input, and outputting of the output signal was obtained at the same time as inputting of the input signal. Results of the output signal with respect to the input signal are shown in FIG. 23. In FIG. 23, the output signal of the tenth example is shown as “Cu-IL”.

As shown in FIG. 23, when the same input signal is input to different media 42m (a medium in which copper (Cu) ions and silver (Ag) ions are contained (ninth example) and a medium in which only copper (Cu) ions are contained (tenth example)), it is seen that output signals having different waveforms are obtained. Based on the above, it is believed that, in a case that the information processing apparatus 5 includes the plurality of converting portions 521 to 52n comprising the mutually different media 52m1 to 52mn as in the fifth embodiment, mutually different output signals are obtained from the converting portions 521 to 52n with inputting of the same input signal.

### Eleventh to Thirteenth Examples

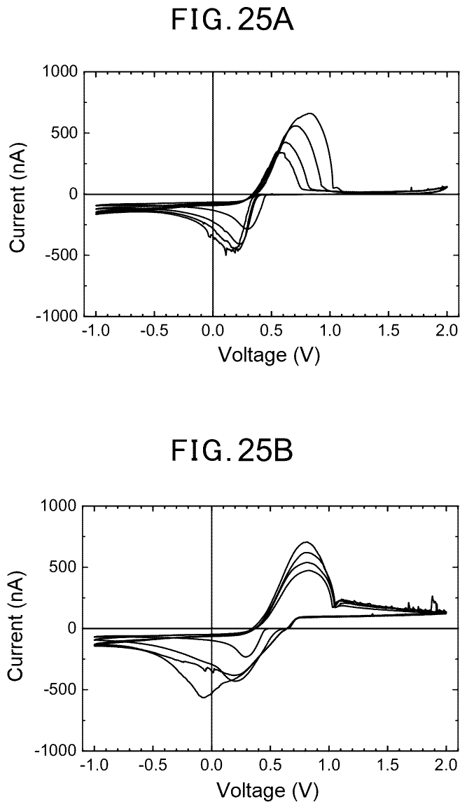

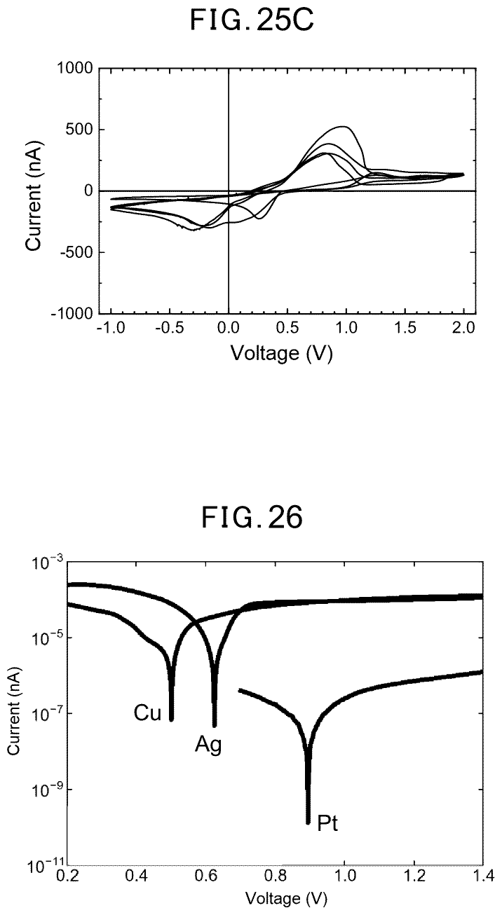

As in the above-described ninth example, the present inventors carried out experiments as follows to confirm the impact on an output signal in a case that the medium 42m of the converting portion 42 contains a plurality of ion species (eleventh to thirteenth examples). FIG. 24 shows a measurement apparatus MS used in measurement of the eleventh to thirteenth examples. The measurement apparatus MS is an apparatus in which a medium Es to be contained in an electrolytic tank Be, a reference electrode Er, and a reference electrode Er are electrically connected by a salt bridge Br, a working electrode Ew and a counter electrode Ec are immersed in the medium Es, and a voltage is applied between the working electrode Ew and the counter electrode Ec by a power source PS to thereby measure a current flowing through the working electrode Ew and a voltage between the working electrode Ew and the reference electrode Er using a three-electrode method (see an ammeter MA and a voltmeter MV in FIG. 24). In the eleventh to thirteenth examples, the counter electrode Ec being platinum (Pt), the reference electrode Er being Ag/AgNO₃, and the medium Es being Ag (TFSA)/[Bmim][TFSA] were not changed in the eleventh to thirteenth example, while metals for the working electrode Ew of platinum (Pt: eleventh example), silver (Ag: twelfth example), and copper (Cu: thirteenth example), respectively, were changed for each of the above-mentioned examples. Measurements were carried out by cyclic voltammetry, and in a case of any one of copper (Cu), silver (Ag), and platinum (Pt) being used as the working electrode Ew, sweeping was repeatedly carried out in a direction in which the potential decreases and in a direction in which the potential increases with the potential sweep speed being set to be 5 mV/sec. Results of measuring a current-voltage characteristic are shown in FIG. 25A (eleventh example), FIG. 25B (twelfth example), and FIG. 25C (thirteenth example), respectively. Besides, in the experiments, in the eleventh and twelfth embodiments, a metal constituting the working electrode Ew (platinum (Pt) or silver (Ag)) was not dissolved in the medium Es, while, in the thirteenth embodiment, a metal constituting the working electrode Ew was dissolved in the medium Es.

As shown in FIGS. 25A to 25C, comparing the eleventh example in which a metal constituting the working electrode Ew (platinum (Pt)) is not dissolved in the medium Es and only one ion species is (silver (At) ions are) present in the medium Es, the twelfth example in which only one ion species is (silver (At) ions are) present in the medium Es even when a metal constituting the working electrode Ew (silver(Ag)) is dissolved in the medium Es, and the thirteenth example in which a metal constituting the working electrode Ew (copper (Cu)) is dissolved in the medium Es and two ion species are (silver (At) ions and copper (Cu) ions are) present in the medium Es, it is seen that waveforms of the current-voltage characteristic substantially differ.

Moreover, in the experimental systems of the eleventh to thirteenth examples, the potential of the working electrode Ew with respect to the reference electrode Er (the voltage between the working electrode Ew and the reference electrode Er) was measured to obtain a polarization curve of the working electrode Ew in the medium Es (Ag (TFSA)/[Bmim][TFSA]). Measurements were carried out by cyclic voltammetry, and the potential sweep speed was set to be +5 mV/sec in a case of using copper (Cu) or silver (Ag) as the working electrode Ew and the potential sweep speed was set to be −5 mV/sec in a case of using platinum (Pt) as the working electrode Ew. FIG. 26 shows the respective results of measuring a polarization curve.

As shown in FIG. 26, in the eleventh to thirteenth examples, it is seen that the polarization characteristics of the working electrode Ew in the medium Es differ among platinum (Pt: eleventh example), silver (Ag: twelfth example), and copper (Cu: thirteenth example).

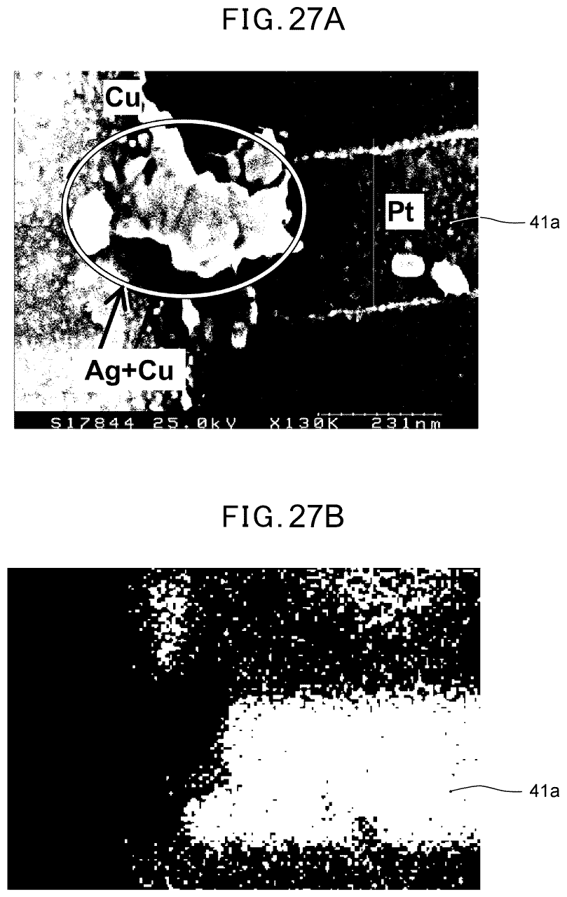

Furthermore, to confirm the behavior of both of the ions (silver (Ag) ions and copper (Cu) ions) present in the medium Es, in correspondence with the experimental systems in the thirteenth example, the information processing apparatus 4 having a structure shown in FIGS. 9 and 10 was prepared, in which information processing apparatus 4 the input terminal 41a and the output terminal 43a were composed of platinum (Pt) and copper (Cu), respectively, and the medium 42m was composed of Ag (TFSA)/[Bmim][TFSA]. After an input signal to be a set voltage and a reset voltage was input to the information processing apparatus 4 prepared, an observation using SEM was carried out, and, in the same area as for the observation using SEM, an elemental mapping using auger electron spectroscopy (below called AES) was carried out. Using a comparison of an obtained observation photograph using SEM and an elemental mapping photograph using AES, an element present in the vicinity of the input terminal 41a was confirmed. The observation photograph using SEM and the elemental mapping photograph are shown in FIGS. 27A and 27B, respectively.

As shown in FIGS. 27A and 27B, it is seen that metals constituting the two ion species being present in the medium Es (removed in FIGS. 26A and 26B) are deposited in the vicinity of the input terminal 41a.

Based on the above, it was confirmed that, even when the polarization characteristics of the metals constituting the ions present in the medium Es differ, both of the ions contributed to the dissolution and deposition reaction (redox reaction).

### Fourteenth Example

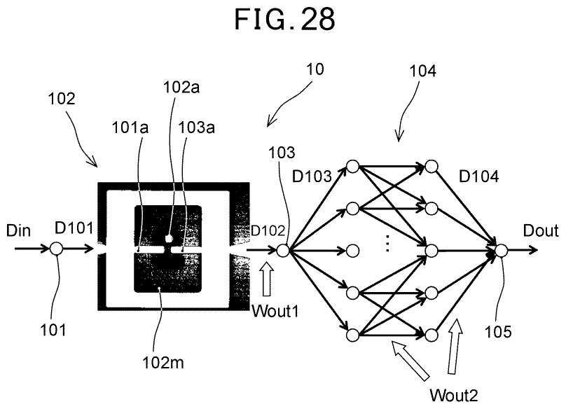

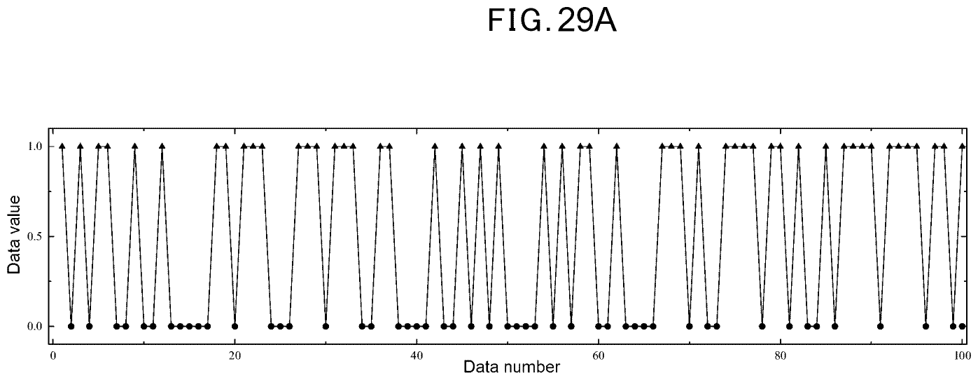

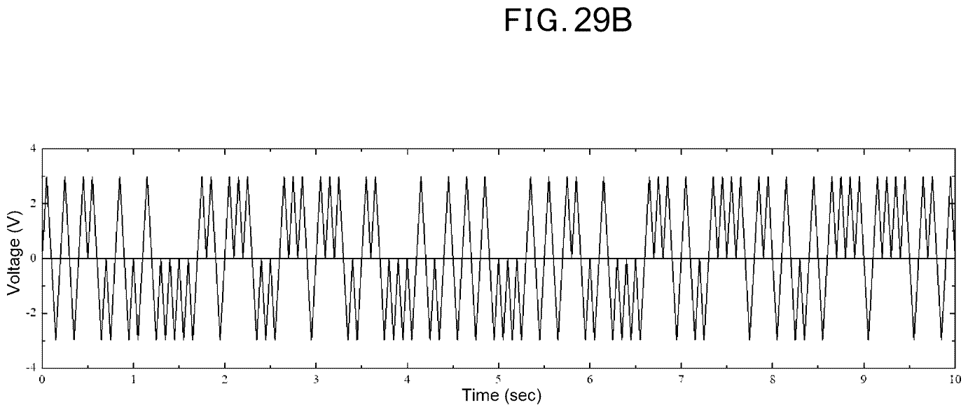

The present inventors carried out experiments as follows to further confirm the characteristic of a signal obtained by an information processing apparatus of the present disclosure. FIG. 28 show an information processing apparatus 10 according to the present example. The information processing apparatus 10 according to the present example has a first converting layer 102 and a second converting layer 104 and serially connects the first converting layer 102 and the second converting layer 104. More specifically, the information processing apparatus 10 comprises a first input portion 101 to transmit, based on an external input Din, a first input signal D101 to the upstream side including the first converting layer 102, a converting portion 102 to convert the first input signal D101 to a first output signal D102, and a first output portion 103 to receive the first output signal D102. In the present embodiment, the first output portion 103 also functions as a second input portion on the downstream side including the second converting layer 104, and the information processing apparatus 10 comprises a second input portion 103 to transmit, based on the first output signal D102, a second input signal D103 to the downstream side, the second converting portion 104 to convert the second input signal D103 to a second output signal D104, and a second output portion 105 to receive the second output signal D104. In the present example, the second output portion 105 compares an external output Dout with a supervisory signal (not shown) and determines a weight Wout2 to be affixed to the second output signal D104 to learn on the determination of the weight Wout2. In this way, the information processing apparatus 10 learns on data related to the external input Din.

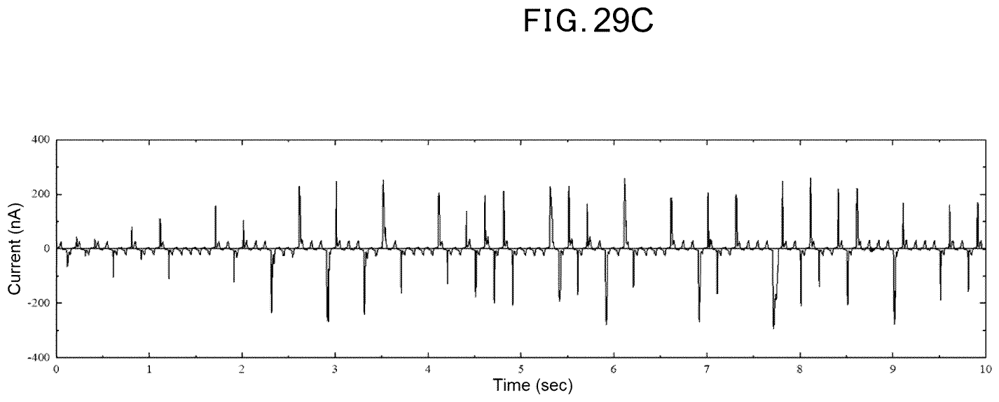

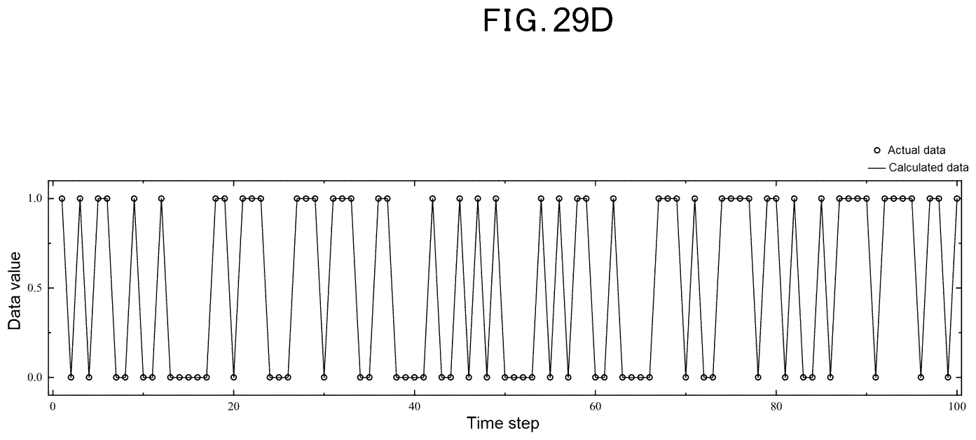

Besides, in the present example, the experiment was carried out under the following conditions:
(1) A structure shown with a photograph by an optical microscope in FIG. 28 was used as the upstream side (from the first input portion 101 to the first output portion 103). Specifically, a signal generator to generate the external input Din (see FIG. 29A; a serial digital signal including 100-bit random information) and a signal converter to convert the external input Din to the first input signal D101 having a predetermined format (see FIG. 29B; a signal composed of first to hundredth time steps corresponding to the 100-bit external input Din) were used as the first input portion 101 on the upstream side of the information processing, the information processing apparatus 4 similar to the one in the tenth example (the medium 42m: Cu (II) (TFSA)₂/[Bmim][TFSA]) was used as the first converting portion 102, and an ammeter to measure the first output signal D102 (see FIG. 29C) from the first converting portion 102 was used as the first output portion 103. Besides, in the present example, a signal converter was set so as to convert the external input Din to a 10 bps triangular wave to decrease a voltage between the input terminal 101a and the output terminal 103a to 0V after increasing the above-mentioned voltage from 0V to 3V in 0.1 sec in a case that the external input Din is “1”, and to convert the external input Din to a 10 bps triangular wave to increase the above-mentioned voltage to 0V after decreasing the above-mentioned voltage from 0V to −3V in 0.1 sec in a case that the external input Din is “0” (see FIGS. 29A and 29B).
(2) Using a neural network on a simulator (a numerical analysis software Matlab by MathWorks, Inc.) as the downstream side (from the second input portion 103 to the second output portion 105), the second input signal D103 based on a current value measured at the first output portion (the second input portion) 103 was input to the above-mentioned neural network. In the above-mentioned neural network, the number of input nodes of the second input portion 103 was set to be one, the number of converting nodes of the second converting portion 104 was set to be 10, and the number of output nodes of the second output portion 105 was set to be one. The external input Din by the first input portion 101 was used as the supervisory signal, the weight Wout2 to be affixed to the second output signal D104 was determined using a Levenberg-Marquardt algorithm, and the external output Dout (see “calculation data” in FIG. 20D) was generated. By sequentially updating the weight Wout2 in accordance with the supervisory signal (external input Din), determination of the weight Wout2 was learned by the information processing apparatus 10.

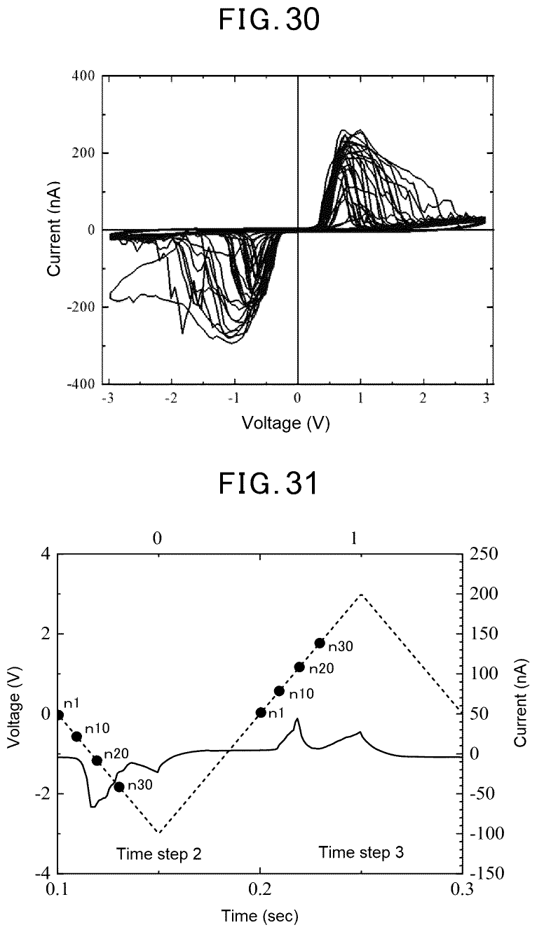

The external input Din, the first input signal D101, the first output signal D102, and the external output Dout are shown in FIGS. 29A to 29C, respectively, and the correlation between the first input signal D101 and the first output signal D102 is shown in FIG. 30. Moreover, results of learning by the information processing apparatus 10 with the external input Din as a supervisory signal are shown in FIG. 29D.

As shown in FIGS. 29A to 29C and 30, also in the present variation, it is seen that an output signal that changes over time can be obtained by outputting (the first) output signal D102 at the same time as inputting of (the first) input signal D101. Moreover, as shown in FIG. 29D, it is seen that the external output Dout reproduces the external input Din well. Based on the above, it was confirmed that the information processing apparatus 10 could learn on the external input Din as a supervisory signal.

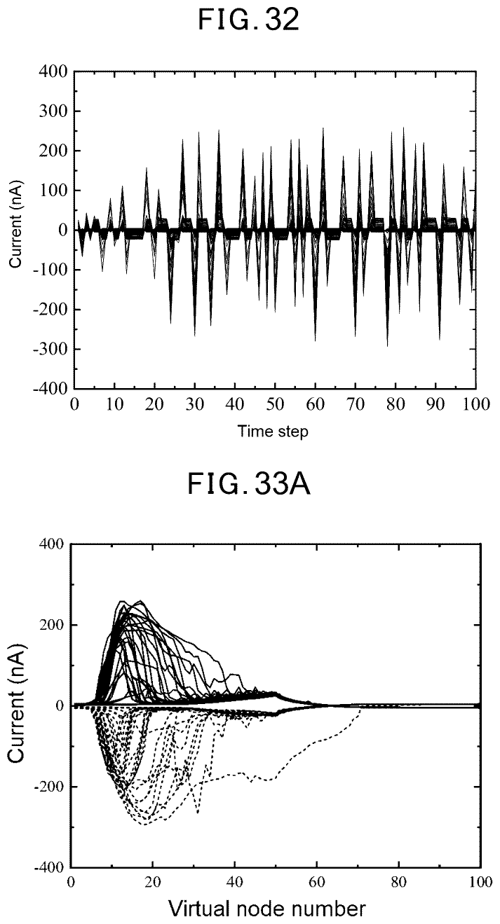

Furthermore, to confirm the learning effect in a case of introducing a virtual node, as shown in FIG. 31, the present inventors set virtual nodes by dividing the input signal D101 obtained in the present example and the output signal D102 corresponding thereto into a plurality at equal time intervals in one time step of the signal (Specifically, 100 virtual nodes are set. In FIG. 31, only first, tenth, twentieth, thirtieth virtual nodes n1, n10, n20, n30 in the second and third steps of the input signal D101 and the output signal D102 are shown.) The output signals D102 obtained from the respective virtual nodes n1 to n100 are shown in FIG. 32. (In FIG. 32, 100 output signals D102 obtained from the 100 virtual nodes n1 to n100 are shown superimposed). As shown in FIG. 32, it is seen that different time series data sets (the output signals D102) are obtained from the respective virtual nodes n1 to n100.

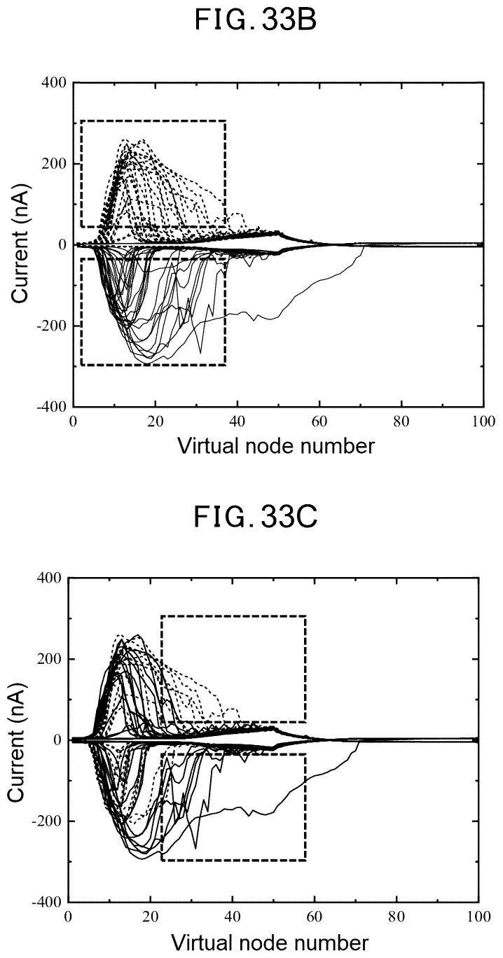

Moreover, to confirm whether the output signal D102 obtained in the present example includes historical information of the input signal D101, the present inventors carried out an STM (short term memory) test. Specifically, using the output signal D102 obtained in the present example and indicating the waveforms of the output signals D102 in the respective first to 100^{th} time steps in a superimposed manner (see FIGS. 33A to 33C. In FIGS. 33A to 33C, Python is used as a programming language), the waveform in a case of the input signal D101 being “1” (see a solid line in FIGS. 33A to 33C) and the waveform in a case of the input signal D101 being “0” (see a broken line in FIGS. 33A to 33C) were observed. FIG. 33A respectively shows, in a solid line, the waveform of the output signal D102 in a case of the input signal D101 input at the same time as outputting of the output signal D102 being “1” and, in a broken line, the waveform of the output signal D102 in a case of the above-mentioned input signal D101 being “0”. In other words, FIG. 33A indicates whether the output signal D102 reflects “1” or “0” of the input signal D101 input at the same time. FIG. 33B respectively shows, in a solid line, the waveform of the output signal D102 in a case of the input signal D101 input at one time step previous to outputting of the output signal D102 being “1” and, in a broken line, the waveform of the output signal D102 in a case of the input signal D101 input at one time step previous thereto being “0”. In other words, FIG. 33B indicates whether the output signal D102 reflects “1” or “0” of the input signal D101 input at one time step previous thereto. FIG. 33C respectively shows, in a solid line, the waveform of the output signal D102 input at two time steps previous to outputting of the output signal D102 and, in a broken line, the waveform of the output signal D102 in a case of the input signal D101 input at two time steps previous thereto being “0”. In other words, FIG. 33C indicates whether the output signal D102 reflects “1” or “0” of the input signal D101 input at two time steps previous thereto.

As shown in FIG. 33A, it is seen that the output signal D102 reflects “1” or “0” of the input signal D101 input at the same time. Moreover, in FIG. 33B, in a virtual node corresponding to the waveform surrounded by a rectangular frame in particular, the output signal D102 (see a broken line in FIG. 33B) is clearly separated into positive and negative currents with respect to “1” (see a solid line in FIG. 33B) and “0” (see a broken line in FIG. 33B) of the input signal D101 at one time step previous thereto, so it is seen that the output signal D102 reflects “1” or “0” of the input signal D101 input at one time step previous thereto. Furthermore, in FIG. 33C, in a virtual node corresponding to the waveform surrounded by a rectangular frame in particular, the output signal D102 (see a broken line in FIG. 33B) is clearly separated into positive and negative currents with respect to “1” (see a solid line in FIG. 33C) and “0” (see a broken line in FIG. 33C) of the input signal D101 at two time steps previous thereto, so it is seen that the output signal D102 reflects “1” or “0” of the input signal D101 input at two time steps previous thereto. Based on the above, it was confirmed that, in the information processing apparatus 10, the output signal D102 included therein not only information of the input signal D101 corresponding to the time step at the time of outputting, but also historical information of the input signal D101 corresponding to the previous time steps.

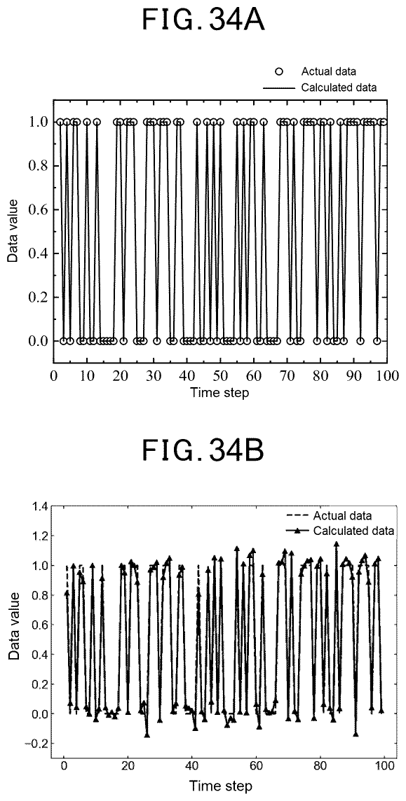

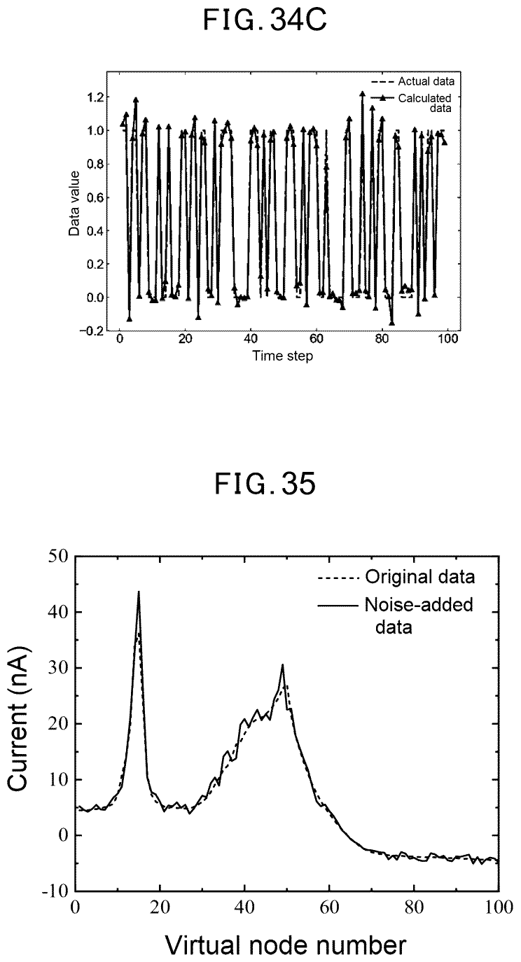

Moreover, the present inventors generated the external output Dout by sequentially updating the weight Wout2 with the supervisory signal as the external input Din at two time steps previous with the same technique as the above-described learning technique to confirm whether the external input Din input previously from the output signal D102 obtained in the present example could be reproduced. Results of learning with the external input Din for the time step two previous as a supervisory signal are shown in FIG. 29D. As shown in FIG. 34A, it is seen that the external output Dout reproduces the external input Din well. Based on the above, it was confirmed that the information processing apparatus 10 including the converting layer 102 and the neural network could learn on the previous supervisory signal.

Besides, in the present example, omitting the downstream side of the information processing apparatus 10 and not using the neural network, the present inventors determined a weight Wout1 of the first output signal D102 using a linear regression method with the supervisory signal as the external input Din for the time step one previous, and generated the external output Dout (a first variation). Results of learning by the first variation are shown in FIG. 34B. Moreover, in the first variation, the present inventors changed the medium 42m from Cu (II) (TFSA)₂/[Bmim][TFSA] to Cu (II)-G3 in the same manner as in the fourth example, and, in the same manner, generated the external output Dout with the supervisory signal as the external input Din for the time step one previous (a second variation). Results of learning by the second variation are shown in FIG. 34C. As shown in FIGS. 34B and 34C, in a case of either one of the first variation and the second variation, it is seen that the external output Dout reproduces the external input Din well. Based on the above, it was confirmed that the external input Din could be learned even with a structure simpler than that of the neural network. Furthermore, it was confirmed that the previous supervisory signal could be learned without using a specific medium.

Moreover, to confirm the impact which noise has on results of learning, as shown in FIG. 35, the present inventors caused the external output Dout to be output from the neural network with noise being added (see a solid line in FIG. 35) to the output signal D102 obtained in the present example (see a broken line in FIG. 35), but the external output Dout reproduced the external input Din well in the same manner as the above-described learning effect (see FIG. 29D).

Moreover, the present inventors obtained the output signal D102 by modulating (time modulating), within a predetermined range, the input signal D101 with respect to a time step time interval to be the reference and inputting the modulated input signal to the converting layer 102. Thereafter, the weight Wout1 of the output signal D102 was determined using a linear regression method with the supervisory signal as the external input Din for the time step one previous, and the external output Dout was generated. The obtained external output Dout reproduced the external input Din well. Furthermore, the present inventors obtained the output signal D102 by modulating (time modulating), within a predetermined range, the input signal D101 with respect to an amplitude to be the reference and inputting the modulated input signal to the converting layer 102. The output signal D102 obtained was normalized for each time step with a maximum value of the output signal D102 for each time step as the reference. Thereafter, the weight Wout1 of the output signal normalized was determined using a linear regression method with the supervisory signal as the external input Din for the time step one previous, and the external output Dout was generated. The obtained external output Dout reproduced the external input Din well.

[Information Processing Apparatus and Control Method of Information Processing Apparatus According to Sixth Embodiment of the Present Disclosure]

Next, with reference to the attached drawings, an information processing apparatus and a control method of an information processing apparatus of the sixth embodiment of the present disclosure will be described. Those points described in the respective features of the first embodiment can also be similarly applied to the information processing apparatus and the control method of an information processing apparatus of the sixth embodiment. In the description below, the points described in the first embodiment will be omitted, so that primarily the differences will be described.

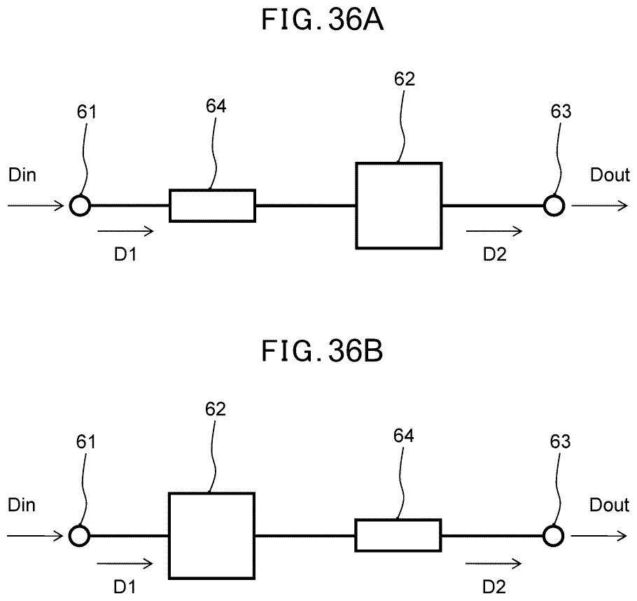

In the above-mentioned embodiment, as shown in FIGS. 25A to 25C (the eleventh to thirteenth examples), for example, the characteristic of signal conversion (current-voltage characteristic) in the converting layer differs between a case in which the external input is “1” (the input signal is a positive voltage) and a case in which the external input is “0” (the input signal is a negative voltage) (below called “asymmetry of the conversion characteristic”). The learning effect of the information processing apparatus is obtained from the above-mentioned asymmetry of the conversion characteristic. In the present embodiment, to further enhance the learning effect of the information processing apparatus, asymmetry being separate from asymmetry of the conversion characteristic is introduced to the information processing apparatus. The above-mentioned separate asymmetry will be described below with reference to (a) and (b) in FIG. 36.

An information processing apparatus 6 according to the present embodiment is configured such that the transmission characteristic of a transmission line passing through a converting portion 62 differs in accordance with an amplitude direction of an input signal D1 (below called “asymmetry of the conversion characteristic”). Here, the “amplitude direction” refers to a direction in which the input signal D1 oscillates (specifically a positive direction and a negative direction) with respect to a reference value of the input signal D1 (for example, 0V in a case that the input signal D1 is a voltage signal). In (a) and (b) in FIG. 36, the information processing apparatus 6 includes an asymmetric device 64 having an electrical characteristic that varies in accordance with the amplitude direction of the input signal D1, and the converting portion 62 is connected to the asymmetric device 64. Specifically, the asymmetric device 64 is connected to the input side (See (a) in FIG. 36. In (a) in FIG. 36, the asymmetric device 64 is directly connected to an input terminal (not shown) of the converting portion 62) of the converting portion 62 or it is connected to the output side of the converting portion 62. (See (b) in FIG. 36. In (b) in FIG. 36, the asymmetric device 64 is directly connected to an output terminal (not shown) of the converting portion 62).

In the present embodiment, the converting portion 62 can be any of the converting portions 12, 22, 32, 42, 52 shown in the first to fifth embodiments. In a case that the converting portion 52 shown in the fifth embodiment is adopted (see FIGS. 20A and 20B), all transmission lines of a plurality of transmission lines connected to the plurality of converting portions 521 to 52n, respectively, can have asymmetry, or some transmission lines of the plurality of transmission lines connected to the plurality of converting portions 521 to 52n, respectively, can have asymmetry. More specifically, an asymmetric device can be connected to all of the input terminals 51a1 to 51an, or an asymmetric device can be connected to some of the input terminals 51a1 to 51an. Moreover, an asymmetric device can be connected to all of the output terminals 53a1 to 53an, or an asymmetric device can be connected to some of the output terminals 53a1 to 53an.

The asymmetric device 64 is not particularly limited as long as it has an electrical characteristic that varies in accordance with the amplitude direction of the input signal D1. As the asymmetric device 64, a diode (more specifically, a Zener diode or a Schottky diode and the like) or a transistor (more specifically, a bipolar transistor or a field effect transistor and the like) can be adopted. In a case of adopting the diode as the asymmetric device 64, asymmetry of the transmission characteristic can be introduced owing to a rectifying action between the anode and the cathode. In a case of adopting the diode, for example, it is possible to connect the anode to the input portion 61 side and the cathode to the input side of the converting portion 62, or to connect the anode to the output side of the converting portion 62 and the cathode to the output portion 63 side. In a case of adopting the transistor as the asymmetric device 64, asymmetry of the transmission characteristic can be introduced owing to a rectifying action between the collector (drain) and the emitter (source), and the rectifying action can be adjusted by adjusting a voltage to be applied to the base (the gate). In a case of adopting the transistor, for example, it is possible to connect the collector (drain) to the input portion 61 side and the emitter (source) to the input side of the converting portion 62, or to connect the emitter (source) to the output side of the converting portion 62 and the collector (drain) to the output portion 63 side of the converting portion 62.

Besides, the asymmetry of the transmission characteristic can be introduced owing to the asymmetry of the physical shape of the converting portion 62. For example, the asymmetry of the transmission characteristic can be introduced by varying at least any one of the size, shape, and arrangement of an electrical conductor of the converting portion 62 between the input side (input terminal side) and the output side (output terminal side). Moreover, the asymmetry of the transmission characteristic can be introduced by varying at least either one of the size and shape of an input terminal and an output terminal.

The control method of the information processing apparatus 6 according to the present embodiment to be configured as described above is similar to the control method of the information processing apparatus 1 according to the first embodiment, so that the explanations thereof will be omitted here.

According to the information processing apparatus 6 and the control method of the information processing apparatus 6 according to the present embodiment, in the same manner as in the above-described embodiments, an electrically conductive path in which the electrical conductivity changes over time can be utilized as a promising core technology for the information processing apparatus such as a neuromorphic apparatus, a reservoir computing apparatus, and the like. Moreover, in the present embodiment, by introducing the asymmetry of the transmission characteristic, the change in the characteristics of the signal conversion for the input signal D1 increases in accordance with the amplitude direction, making it possible to further enhance the learning effect of the information processing apparatus 6. Furthermore, it is believed that the learning effect of the information processing apparatus 6 can also be controlled in accordance with the degree of asymmetry of the above-mentioned transmission characteristic.

### Fifteenth to Seventeenth Examples

As in the above-described sixth embodiment, the present inventors carried out experiments as follows to confirm the effect of introducing the asymmetry of the transmission characteristic.

Fifteenth example: A sample was prepared with the first converting portion 102 being replaced by the same information processing apparatus as the information processing apparatus 4 of the fourth example (see FIG. 14A) except for the input terminal 41a and the output terminal 43a being set to be spaced 6 μm apart in the configuration of the fourteenth example (see FIG. 28).

Sixteenth example: A sample was prepared having a configuration similar to that of the fifteenth example except for a Zener diode being inserted between the first input portion 101 and the second input portion 102. The Zener diode was inserted between the first input portion 101 and the second input portion 102 with the anode being connected to the first input portion 101 and the cathode being connected to the input terminal 101a of the first converting portion 102, respectively. As the Zener diode, one having a Zenor voltage of 3.6V was selected.

Seventeenth example: A sample having a configuration similar to that of the sixteenth example except for a Zener diode having a Zenor voltage of 4.2V being selected was prepared.

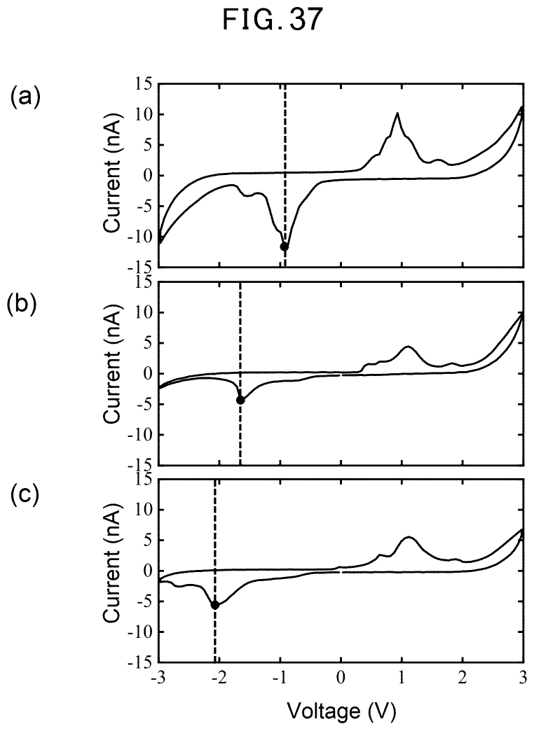

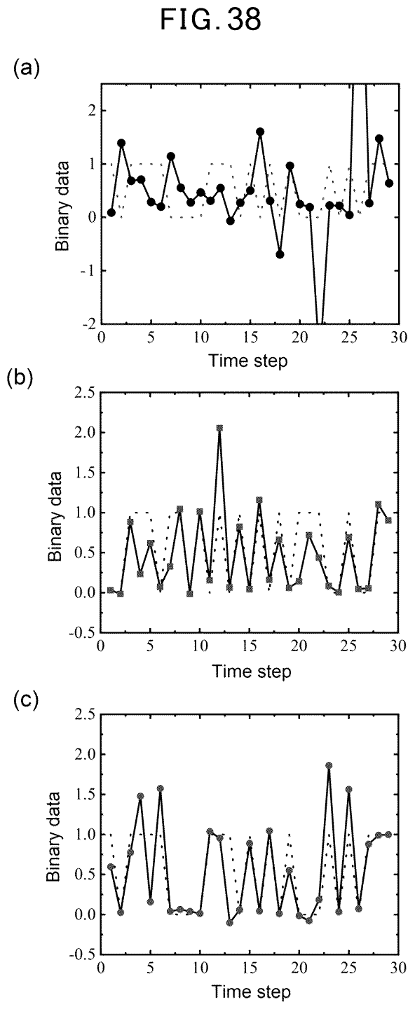

In the above-described fifteenth to seventeenth examples, in the same manner as in the fourteenth example, a serial digital signal including 100-bit random information corresponding to first to hundredth time steps as the external input Din from the first input portion 101 was generated, and, by sequentially updating the weight Wout2 in accordance with the external output Dout with the external input Din being used as a supervisory signal, determination of the weight Wout2 was learned by the information processing apparatus 10. In a series of external input Din information sets corresponding to hundred time steps, those information sets corresponding to 70 time steps were used for learning by the information processing apparatus 10, while those information sets corresponding to the remaining 30 time steps were used for validation of learning. Current-voltage characteristics in fifteenth to seventeenth examples are shown in (a) to (c) in FIG. 37, respectively, and the external input Din and the external output Dout in 30 time steps for validation of learning are shown in (a) to (c) in FIG. 38.

As shown in (a) to (c) in FIG. 37, it is seen that, in a case in which the asymmetry of transmission characteristic is introduced (see (b) and (c) in FIG. 37), the current-voltage characteristic changes so as to increase the asymmetry between the time of applying a positive voltage and the time of applying a negative voltage with respect to a case in which the asymmetry of transmission characteristic is not introduced (see (a) in FIG. 37). More specifically, it is seen that the current-voltage characteristic changes the position of the peak at the time of application of the negative voltage (see broken lines in (a) to (c) in FIG. 37), and the characteristic around the maximum value (−3V) of the negative voltage changes, causing the asymmetry to change such that the asymmetry increases between the time of application of the positive voltage and the time of application of the negative voltage. As shown in (b) and (c) in FIG. 37, it is seen that the above-mentioned asymmetry of the current-voltage characteristic increases as the Zener voltage increases.

Moreover, as shown in (a) to (c) in FIG. 38, it is seen, in a case in which the asymmetry of the transmission characteristic is introduced (see (b) and (c) in FIG. 38), the followability of the external output Dout to the external input Din changes with respect to a case in which the asymmetry of the transmission characteristic is not introduced (see (a) in FIG. 38). As shown in FIGS. (b) and (c) in FIG. 38, it is seen that the above-mentioned followability of the external output Dout to the external input Din also changes according to the magnitude of the Zener voltage.

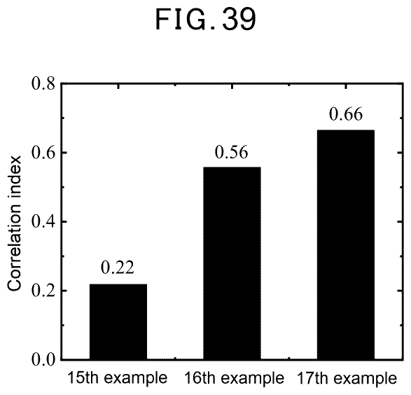

To quantify the followability of external output Dout to the external input Din in fifteenth to seventeenth examples, in the respective configurations of fifteenth to seventeenth examples, the above-mentioned series of external input Din information sets corresponding to hundred time steps were repeatedly input five times to the first converting portion 102, and the correlation indices for each of the five inputs were calculated. The average value of the correlation indices for the five times is shown in FIG. 39. As shown in FIG. 39, in a case in which the asymmetry of the transmission characteristic is introduced (seventeenth example) in comparison to a case in which the asymmetry of the transmission characteristic is not introduced (fifteenth example), the correlation indices increase approximately three fold. In this way, it was confirmed that, in a case of the asymmetry of the transmission characteristic being introduced, the learning effect of the external output Dout with respect to the external input Din could improve. Moreover, it is seen that the correlation indices vary according to the magnitude of the Zener voltage. (sixteenth to seventeenth examples). In this way, it was confirmed that the learning effect could be controlled in accordance with the degree of the above-mentioned asymmetry of transmission characteristic.

[Conclusion]

An information processing apparatus according to one embodiment of the present disclosure includes a converting portion comprising a plurality of electrical conductors to be arranged in separation with each other and a medium to be arranged so as to mutually connect the plurality of electrical conductors, which converting portion is an information processing apparatus to convert an input signal to an output signal, wherein the medium contains an electrolyte that can form an electrically conductive path mutually electrically connecting the plurality of electrical conductors and is configured to be capable of controlling an electrical conductivity of the electrically conductive path based on the input signal, and the medium is selected such that the electrical conductivity of the electrically conductive path changes over time with the input signal not being present.

According to the information processing apparatus according to one embodiment of the present disclosure, focusing on the characteristic in which the electrical conductivity of the electrically conductive path to be formed in an electrolyte changes over time, the electrically conductive path can be utilized as a promising core technology for the information processing apparatus.

The converting portion can generate the output signal in accordance with a change over time of a resistance value. According to such a configuration, the information processing apparatus can be utilized as a neuromorphic apparatus or a reservoir computing apparatus.

An insulator can be interposed in a part between the plurality of electrical conductors and the medium. In this case, in a portion in which the insulator is interposed, no reaction occurs between the electrical conductors and the medium, making it possible to cause a reaction to occur only in a desired portion between the electrical conductors and the medium. In this way, the controllability of the information processing apparatus increases.

The plurality of electrical conductors can include an input terminal to transmit the input signal and an output terminal to receive the output signal. Such a configuration makes it possible to simplify the structure of the information processing apparatus.

The converting portion can further comprise, separately from the plurality of electrical conductors, an input terminal to transmit the input signal and an output terminal to receive the output signal, and the input terminal and the output terminal can be arranged in separation from the plurality of electrical conductors. Such a configuration makes it easier to apply an input voltage and the like to a converter comprising a plurality of electrical conductors.

The transmission characteristic of a transmission line passing through the converting portion can be configured to vary in accordance with the amplitude direction of the input signal. According to such a configuration, the change in the characteristics of the signal conversion for the input signal increases in accordance with the amplitude direction, making it possible to further enhance the learning effect of the information processing apparatus.

The converting portion can be configured such that the converting portion includes a plurality of converting portions, a medium comprised by a converting portion of a part of the plurality of converting portions is different from a medium comprised by a converting portion of a different part of the plurality of converting portions, and an identical signal is input to the converting portion of the part and the converting portion of the different part. According to such a configuration, various output signals can be obtained from one input signal, making it possible to achieve higher dimensionality of data.

The output signal can be output with a time interval from inputting of the input signal, or the output signal can be output simultaneously with inputting of the input signal. According to such a configuration, the timing of outputting of the output signal can be varied.

The medium can be selected such that the admittance of the electrically conductive path decreases over time by the electrically conductive path dissolving in the medium with the input signal not being present. Such a configuration makes it easier to decrease the admittance of the electrically conductive path over time.

An 80% attenuation time of the admittance of the electrically conductive path can be set so as to be within a range of 10⁻⁶ sec to 10⁷ sec in the initial period of attenuation. According to such a configuration, an information processing apparatus having a good consistency with the processing speed of an existing electronic device can be obtained.

The medium can be selected such that the impedance of the electrically conductive path decreases over time by the electrically conductive path being deposited with the input signal not being present. Such a configuration makes it easier to decrease the impedance of the electrically conductive path over time.

An 80% attenuation time of the impedance of the electrically conductive path can be set so as to be within a range of 10⁻⁶ sec to 10⁷ sec in the initial period of attenuation. According to such a configuration, an information processing apparatus having a good consistency with the processing speed of an existing electronic device can be obtained.

The medium can contain an ionic liquid. Such a configuration is suitable for a medium in which the electrical conductivity of an electrically conductive path changes over time.

A metal constituting the electrical conductors can have a higher electrode potential with respect to the medium than that of a metal constituting ions contained in the medium. According to such a configuration, disruption of the electrical conductor to the medium is suppressed.

A control method of an information processing apparatus according to one embodiment of the present disclosure is a control method of an information processing apparatus including a converting portion comprising a plurality of electrical conductors to be arranged in separation with each other and a medium to be arranged so as to mutually connect the plurality of electrical conductors, in which information processing apparatus the converting portion is to convert an input signal to an output signal, wherein the medium contains an electrolyte that can form an electrically conductive path mutually electrically connecting the plurality of electrical conductors, the method including the step of controlling the admittance of the electrically conductive path by selecting the medium such that the admittance of the electrically conductive path is increased based on the input signal and the admittance of the electrically conductive path is decreased over time with the input signal not being present.

According to the information processing apparatus according to one embodiment of the present disclosure, focusing on the characteristic in which the admittance of the electrically conductive path to be formed in an electrolyte decreases over time, the electrically conductive path can be utilized as a promising core technology for the information processing apparatus.

The admittance of the electrically conductive path can be decreased, and the output signal according to the decrease in the admittance of the electrically conductive path can be generated. According to such a configuration, the information processing apparatus can be used for a neuromorphic apparatus, a reservoir computing apparatus, and the like.

The electrically conductive path can be deposited from the medium to generate the electrically conductive path; and the electrically conductive path can be dissolved in the medium to disrupt the electrically conductive path. Such a configuration makes it possible to easily increase/decrease the admittance of the electrically conductive path.

The medium can contain an ionic liquid, and at least one of a type of the ionic liquid and a type and a concentration of ions being dissolved in the ionic liquid can be selected such that an 80% attenuation time of the admittance of the electrically conductive path falls within a range of 10⁻⁶ sec to 10⁷ sec in the initial period of attenuation with the input signal not being present. According to such a configuration, the ionic liquid can be selected to allow a good consistency of the processing speed of an existing electronic device and change over time of the admittance of the electrically conductive path.

A control method of an information processing apparatus according to one embodiment of the present disclosure is a control method of an information processing apparatus including a converting portion comprising a plurality of electrical conductors to be arranged in separation with each other and a medium to be arranged so as to mutually connect the plurality of electrical conductors, in which information processing apparatus the converting portion is to convert an input signal to an output signal, wherein the medium contains an electrolyte that can form an electrically conductive path mutually electrically connecting the plurality of electrical conductors, the method including the step of controlling the impedance of the electrically conductive path by selecting the medium such that the impedance of the electrically conductive path is increased based on the input signal and the impedance of the electrically conductive path is decreased over time with the input signal not being present.

According to the information processing apparatus according to one embodiment of the present disclosure, focusing on the characteristic in which the impedance of the electrically conductive path to be formed in an electrolyte decreases over time, the electrically conductive path can be utilized as a promising core technology for the information processing apparatus.

The impedance of the electrically conductive path can be decreased and the output signal according to the decrease in the impedance of the electrically conductive path can be generated. According to such a configuration, the information processing apparatus can be utilized as a neuromorphic apparatus or a reservoir computing apparatus.

The electrically conductive path can be dissolved in the medium to disrupt the electrically conductive path; and the electrically conductive path can be deposited from the medium to generate the electrically conductive path. Such a configuration makes it possible to easily increase/decrease the impedance of the electrically conductive path.

The medium can contain an ionic liquid, and at least one of a type of the ionic liquid and a type and a concentration of ions being dissolved in the ionic liquid can be selected such that an 80% attenuation time of the impedance of the electrically conductive path falls within a range of 10⁻⁶ sec to 10⁷ sec in the initial period of attenuation with the input signal not being present. Such a configuration allows a good consistency of the processing speed of an existing electronic device and change over time of the impedance of the electrically conductive path.

### REFERENCE SIGNS LIST

1 to 5, 4A, 10 INFORMATION PROCESSING APPARATUS
11, 21, 31, 41, 61, 101, 103 INPUT PORTION
11a, 11a1 to 11a3, 21a, 31a, 41a, 51a, 51a1 to 51an, 101a INPUT TERMINAL
12, 22, 32, 42, 52, 521 to 52n, 62, 102, 104 CONVERTING PORTION
12a, 22a, 32a, 42a, 52a, 102a ELECTRICAL CONDUCTOR
12m, 22m, 32m, 42m, 52m, 52m1 to 52mn, 102m, Es MEDIUM
13, 23, 33, 43, 63, 103, 105 OUTPUT PORTION
13a, 13a1 to 13a3, 23a, 33a, 43a, 53a, 53a1 to 53an, 103a OUTPUT TERMINAL
22b, 42b, 42b1, 42b2 INSULATOR
22p COLUMNAR BODY
41at, 43at TIP (OF INPUT/OUTPUT TERMINAL)
42c COVERING BODY
64 ASYMMETRICAL DEVICE
A1, Ab AREA
Am MEDIUM ARRANGEMENT AREA
B SUBSTRATE
Be ELECTROLYTIC TANK
Br SALT BRIDGE
CP ELECTRICALLY CONDUCTIVE PATH
D1, D101, D103 INPUT SIGNAL
D2, D102, D104 OUTPUT SIGNAL
Din EXTERNAL INPUT
Dout EXTERNAL OUTPUT
Ec COUNTER ELECTRODE
Er REFERENCE ELECTRODE
Ew WORKING ELECTRODE
M BASE MATERIAL
MS MEASUREMENT APPARATUS
MA AMMETER
MV VOLTMETER
n1 to n100 VIRTUAL NODE (READ TIME)
PB POROUS BODY
PS POWER SOURCE
R, Ra, Rb, Rc CONCAVE PORTION
R1 OPENING DIRECTION
S SURFACE
S11, S21, S31, S41 STEP OF SELECTING ELECTRICAL CONDUCTOR
S12, S22, S32, S42 STEP OF SELECTING MEDIUM
S13, S33 STEP OF INCREASING ADMITTANCE OF ELECTRICALLY CONDUCTIVE PATH
S14, S35 STEP OF DECREASING ADMITTANCE OF ELECTRICALLY CONDUCTIVE PATH
S15, S25, S34, S44 STEP OF GENERATING OUTPUT SIGNAL
S23, S43 STEP OF INCREASING IMPEDANCE OF ELECTRICALLY CONDUCTIVE PATH
S24, S45 STEP OF DECREASING IMPEDANCE OF ELECTRICALLY CONDUCTIVE PATH
T1 SAMPLE
V1 INPUT NODE
V2 CONVERTING NODE
V3 OUTPUT NODE
VC VACANCY
WB PLATE-SHAPED BODY
WP WALL PARTITION
Wr ELECTRICALLY CONDUCTIVE WIRE
Win, Wres, Wout, Wout1, Wout2 WEIGHT

1. An information processing apparatus including a converting portion comprising
a plurality of electrical conductors to be arranged in separation with each other and
a medium to be arranged so as to mutually connect the plurality of electrical conductors, which converting portion is an information processing apparatus to convert an input signal to an output signal, wherein
the medium contains an electrolyte that can form an electrically conductive path mutually electrically connecting the plurality of electrical conductors and is configured to be capable of controlling an electrical conductivity of the electrically conductive path based on the input signal, and
the medium is selected such that the electrical conductivity of the electrically conductive path changes over time with the input signal not being present.

2. The information processing apparatus according to claim 1, wherein the converting portion generates the output signal in accordance with a change over time of the electrical conductivity.

3. The information processing apparatus according to claim 1, wherein an insulator is interposed in a part between the plurality of electrical conductors and the medium.

4. The information processing apparatus according to claim 1, wherein the plurality of electrical conductors include
an input terminal to transmit the input signal and
an output terminal to receive the output signal.

5. The information processing apparatus according to claim 1, wherein the converting portion further comprises, separately from the plurality of electrical conductors,
an input terminal to transmit the input signal and
an output terminal to receive the output signal, and
the input terminal and the output terminal are arranged in separation from the plurality of electrical conductors.

6. The information processing apparatus according to claim 1, wherein the transmission characteristic of a transmission line passing through the converting portion is configured to vary in accordance with the amplitude direction of the input signal.

7. The information processing apparatus according to claim 1, wherein the converting portion is configured such that
the converting portion includes a plurality of converting portions, a medium comprised by a converting portion of a part of the plurality of converting portions is different from a medium comprised by a converting portion of a different part of the plurality of converting portions, and
an identical input signal is input to the converting portion of the part and the converting portion of the different part.

8. The information processing apparatus according to claim 1, wherein the output signal is output with a time interval from inputting of the input signal.

9. The information processing apparatus according to claim 1, wherein the output signal is output simultaneously with inputting of the input signal.

10. The information processing apparatus according to claim 1, wherein the medium is selected such that the admittance of the electrically conductive path decreases over time by the electrically conductive path dissolving in the medium with the input signal not being present.

11. The information processing apparatus according to claim 10, wherein an 80% attenuation time of the admittance of the electrically conductive path is set so as to be within a range of 10⁻⁶ sec to 10⁷ sec in the initial period of attenuation.

12. The information processing apparatus according to claim 1, wherein the medium is selected such that the impedance of the electrically conductive path decreases over time by the electrically conductive path being deposited with the input signal not being present.

13. The information processing apparatus according to claim 12, wherein an 80% attenuation time of the impedance of the electrically conductive path is set so as to be within a range of 10⁻⁶ sec to 10⁷ sec in the initial period of attenuation.

14. The information processing apparatus according to claim 1, wherein the medium contains an ionic liquid.

15. The information processing apparatus according to claim 1, wherein a metal constituting the electrical conductors has a higher electrode potential with respect to the medium than that of a metal constituting ions contained in the medium.

16. A control method of an information processing apparatus including a converting portion comprising
a plurality of electrical conductors to be arranged in separation with each other and
a medium to be arranged so as to mutually connect the plurality of electrical conductors, in which information processing apparatus the converting portion is to convert an input signal to an output signal, wherein
the medium contains an electrolyte that can form an electrically conductive path mutually electrically connecting the plurality of electrical conductors, the method including the step of
controlling the admittance of the electrically conductive path by selecting the medium such that the admittance of the electrically conductive path is increased based on the input signal and the admittance of the electrically conductive path is decreased over time with the input signal not being present.

17. The control method of an information processing apparatus, according to claim 16, the method including the step of
decreasing the admittance of the electrically conductive path and generating the output signal according to the decrease in the admittance of the electrically conductive path.

18. The control method of an information processing apparatus, according to claim 16, the method including the steps of:
depositing the electrically conductive path from the medium to generate the electrically conductive path; and
dissolving the electrically conductive path in the medium to disrupt the electrically conductive path.

19. The control method of an information processing apparatus, according to claim 16, wherein
the medium contains an ionic liquid, and the control method includes the step of
selecting at least one of a type of the ionic liquid and a type and a concentration of ions being dissolved in the ionic liquid such that an 80% attenuation time of the admittance of the electrically conductive path falls within a range of 10⁻⁶ sec to 10⁷ sec in the initial period of attenuation with the input signal not being present.

20. A control method of an information processing apparatus including a converting portion comprising
a plurality of electrical conductors to be arranged in separation with each other and
a medium to be arranged so as to mutually connect the plurality of electrical conductors, in which information processing apparatus the converting portion is to convert an input signal to an output signal, wherein
the medium contains an electrolyte that can form an electrically conductive path mutually electrically connecting the plurality of electrical conductors, the method including the step of
controlling the impedance of the electrically conductive path by selecting the medium such that the impedance of the electrically conductive path is increased based on the input signal and the impedance of the electrically conductive path is decreased over time with the input signal not being present.

21. The control method of an information processing apparatus, according to claim 20, the method including the step of
decreasing the impedance of the electrically conductive path and generating the output signal according to the decrease in the impedance of the electrically conductive path.

22. The control method of an information processing apparatus, according to claim 20, the method including the steps of:
dissolving the electrically conductive path in the medium to disrupt the electrically conductive path; and
depositing the electrically conductive path from the medium to generate the electrically conductive path.

23. The control method of an information processing apparatus, according to claim 20, wherein
the medium contains an ionic liquid, and the control method includes the step of
selecting at least one of a type of the ionic liquid and a type and a concentration of ions being dissolved in the ionic liquid such that an 80% attenuation time of the impedance of the electrically conductive path falls within a range of 10⁻⁶ sec to 10⁷ sec in the initial period of attenuation with the input signal not being present.
